(19) United States
(12) Patent Application Publication
(10) Pub. No.: US 2011/0189811 A1
(43) Pub. Date: Aug. 4, 2011

(54) PHOTOVOLTAIC DEVICE AND METHOD OF MANUFACTURING PHOTOVOLTAIC DEVICES

(75) Inventors: Jason M. Stephens, Mountain View, CA (US); Kevin Michael Coakley, Mountain View, CA (US); Guleid Hussen, Mountain View, CA (US)

(73) Assignee: THINSILICON CORPORATION, Mountain View, CA (US)

(21) Appl. No.: 13/083,084

(22) Filed: Apr. 8, 2011

Related U.S. Application Data
(63) Continuation of application No. 12/127,141, filed on May 27, 2008.
(60) Provisional application No. 61/039,043, filed on Mar. 24, 2008.
(60) Provisional application No. 60/932,374, filed on May 31, 2007.
(60) Provisional application No. 60/932,389, filed on May 31, 2007.
(60) Provisional application No. 60/932,395, filed on May 31, 2007.

(51) Int. Cl. H01L 31/0232; H01L 31/0376

(52) U.S. Cl. 438/72; 438/96; 257/E31.127; 257/E31.047

(57) ABSTRACT

A photovoltaic device includes a supporting layer, a semiconductor layer stack, and a conductive and light transmissive layer. The supporting layer is proximate to a bottom surface of the device. The semiconductor layer stack includes first and second semiconductor sub-layers, with the second sub-layer having a crystalline fraction of at least approximately 85%. A conductive and light transmissive layer between the supporting layer and the semiconductor layer stack, where an Ohmic contact exists between the first semiconductor sub-layer and the conductive and light transmissive layer.

### CROSS-REFERENCE TO RELATED APPLICATIONS

This application is a continuation of co-pending U.S. patent application Ser. No. 12/127,141, which was filed on May 27, 2008, and is entitled “Photovoltaic Device And Method Of Manufacturing Photovoltaic Devices” (the “'141 Application”). The '141 Application relates and claims priority to U.S. Provisional Patent Application Ser. Nos. 61/039,043 (the “'043 application”), 60/932,374 (the “'374 application”), 60/932,389 (the “'389 application”) and 60/932,395 (the “'395 application”). The '043 application was filed on Mar. 24, 2008, and is entitled “Photovoltaic Device and Method of Manufacturing Photovoltaic Devices.” The '374 application was filed on May 31, 2007, and is entitled “Method of Annealing a Large Area Semiconductor Film Using Electron Beams.” The '389 application was filed on May 31, 2007, and is entitled “Method of Producing a Microcrystalline Silicon Film for Photovoltaic Cells.” The '395 application was filed on May 31, 2007, and is entitled “Method of Producing a Photovoltaic Module.” The complete subject matter of the '141, '043, '375, '389 and '395 applications is incorporated by reference herein in its entirety.

This application also is related to co-pending U.S. patent application Ser. No. 11/903,787 (the “'787 Application”) and U.S. Provisional Patent Application Ser. No. 60/847,475 (the “'475 application). The '787 Application was filed on Sep. 25, 2007, and is entitled “Back Contact Device For Photovoltaic Cells And Method Of Manufacturing A Back Contact Device.” The '475 application was filed on Sep. 27, 2006, and is entitled “Back Contact Device for Photovoltaic Cells.” The complete subject matter of the '787 and '475 applications is incorporated by reference herein in its entirety.

### BACKGROUND OF THE INVENTION

The presently described technology generally relates to photovoltaic (“PV”) devices. More particularly, the presently described technology relates to an improved photovoltaic device and an improved method for fabricating a photovoltaic device.

In order for a significant fraction of the world's electricity to be produced by photovoltaics (“PV”), the cost of producing PV devices must be reduced in order to become cost-competitive with other forms and sources of electricity. At present, many PV devices are made from silicon wafers. While these devices may be capable of producing relatively high conversion efficiencies, at present the panels suffer from two drawbacks that may prevent silicon wafer-based panels from being economically viable.

First, the purity and thickness requirements of silicon wafers may be relatively high, which can significantly add to the cost of producing silicon wafer-based panels. In some current applications, silicon wafers used in PV panels may need to be purified to the parts per billion level and be 200 to 675 micrometers thick for mechanical handling. The increased purity and thickness requirements can result in a relatively large cost for silicon raw materials and processing costs.

Second, the method and manner of fabricating the silicon wafer-based PV panels may require complex and impractical methods of connecting multiple silicon wafers. For example, existing silicon wafer-based PV panels may require that the silicon wafers be connected in series using an impractical soldering process in order to produce sufficiently high module output voltages.

In contrast, other PV panels include thin film solar cells made using thin films of amorphous silicon. For example, some PV panels include a film of amorphous silicon that is approximately 100 to 1000 nanometers thick. These PV panels use much less raw semiconductor material than the PV panels that include silicon wafers. Additionally, the amorphous semiconductor PV cells in the thin film PV panel may be more easily connected with one another. For example, amorphous silicon films can be deposited on carrier substrates and then be converted into series-connected PV cells using a laser scribing process, for example.

PV panels made from thin films of amorphous silicon also face significant drawbacks. For example, the efficiency of the solar modules may be relatively low. Some solar modules made from thin films of amorphous silicon may have conversion efficiencies on the order of 5 to 7%. This relatively low conversion efficiency may offset the cost advantage gained by using inexpensive carrier substrates. In another example, the stability of the amorphous silicon thin films in the modules is relatively poor. The output of PV modules that have thin films of amorphous silicon may degrade on the order of 15 to 25% within the first several months of operation in the field.

In consideration of these factors, a need thus exists for a semiconductor-based PV technology that includes solar panels having improved conversion efficiency and stability while lowering the materials and processing costs. For example, thin film crystalline silicon PV panels may be able to combine the efficiency and stability of crystalline silicon wafer-based PV panels with the lower cost, improved manufacturing scale and throughput advantages of PV panels made from thin films of amorphous silicon. With a combination of these attributes, PV panels having thin films of crystalline silicon may be able to be produced at a manufacturing cost well below $1 per peak watt. Such a decreased manufacturing cost may permit the cost of power produced by these panels to directly compete with the cost of traditional grid electricity.

PV modules made from thin films of microcrystalline silicon have been one attempt to meet some of the above needs. One method for creating thin film microcrystalline silicon PV modules is to directly deposit microcrystalline silicon films using plasma-enhanced chemical vapor deposition (“PECVD”). Yet, such directly deposited microcrystalline silicon films deposited using PECVD may suffer from one or more drawbacks. First, directly-deposited microcrystalline silicon films typically require very slow deposition rates. The slow deposition rates may be necessary to produce a sufficiently high-quality microcrystalline film. In addition, it can be difficult to deposit microcrystalline films on large substrates because the process window for producing high-quality material is very narrow. Second, directly deposited microcrystalline films tend to contain relatively small crystalline grains of semiconductor material. For example, directly deposited microcrystalline silicon can include crystalline grains on the order of 10 to 20 nanometers. These smaller crystalline grains can have large grain boundary areas. The grain boundary areas can act as surfaces for the recombination of charge carriers in the semiconductor material. Additionally, such small crystalline grains may require a substantial fraction of the semiconductor material to be amorphous in order to adequately passivate the microcrystalline material electrically.

Moreover, in thin film crystalline polysilicon PV cells, two desirable features are 1) increasing the crystalline grain size in the silicon layers of the PV cell to reduce recombination losses of the electrons and hole generated in the silicon layers by incident light and 2) including a series of semiconductor layers that include a relatively thin bottom n+ (or p+) silicon layer, a thicker middle intrinsic polysilicon layer, and a relatively thin p+ (or n+) top silicon layer. However, increasing the crystalline grain sizes in the silicon layers of the PV cells using existing systems and methods often requires the layers to be fully melted and recrystallized. As a result of the melting of these layers, it can be very difficult to maintain a dopant junction between one or more of the top and bottom silicon layers and the middle lightly doped or intrinsic silicon layer. If the dopant junction between two layers is not maintained, it can be very difficult to establish or maintain an Ohmic contact between the bottom silicon layer and an adjacent electrode, for example. Additionally, if the dopant junction between two adjacent layers is not maintained, it can be very difficult to form a selective contact that captures only one carrier type at the bottom of the silicon layer and transfers those carrier types to an adjacent electrode.

The difficulty in maintaining a junction profile between the bottom and middle silicon layers arises because the two layers may melt at approximately the same temperature and the dopants in the bottom silicon layer may have a strong tendency to rapidly interdiffuse into the middle silicon layer during the melting process. Unacceptable levels of interdiffusion may occur even with short melt durations, such as 50 nanoseconds, for example. This time, however, is approximately the minimum time that is required for a full melting process in thin films of silicon.

Thus, a need exists for PV cells and devices and a method for manufacturing PV cells and devices that addresses one or more of the shortcomings described above. For example, needs exist for PV cells and devices that may be manufactured more quickly and at a lower cost, while increasing the levels of crystallinity in the semiconductor layers and maintaining dopant junctions within the semiconductor layers. Meeting one or more of the above shortcomings and needs may enable production of lower cost solar panels of a larger surface area, with higher stability and higher efficiency than many existing solar panels.

### BRIEF SUMMARY OF THE INVENTION

In one embodiment, a photovoltaic device includes a supporting layer, a semiconductor layer stack, and a conductive and light transmissive layer. The supporting layer is proximate to a bottom surface of the device. The semiconductor layer stack includes first and second semiconductor sub-layers, with the second sub-layer having a crystalline fraction of at least approximately 85%. A conductive and light transmissive layer is located between the supporting layer and the semiconductor layer stack, where an Ohmic contact exists between the first semiconductor sub-layer and the conductive and light transmissive layer.

In another embodiment, another photovoltaic device includes a substrate, a reflective electrode, a light transmissive electrode, a semiconductor layer stack and an optical spacer layer. The reflective electrode is located above the substrate. The light transmissive electrode is located above the reflective electrode. The semiconductor layer stack is between the reflective electrode and the light transmissive electrode and includes first and second sub-layers. The second sub-layer includes a polycrystalline semiconductor material having a crystalline fraction of at least approximately 85%. The optical spacer layer is between the reflective electrode and the semiconductor layer stack and includes a conductive and light transmissive material.

In another embodiment, another photovoltaic device includes a light transmissive superstrate, a light transmissive electrode, a reflective electrode, a semiconductor layer stack, and an optical spacer layer. The light transmissive electrode is located above the superstrate. The reflective electrode is located above the light transmissive electrode. The semiconductor layer stack is between the reflective electrode and the light transmissive electrode and includes first and second sub-layers. The second sub-layer includes a polycrystalline semiconductor material having a crystalline fraction of at least approximately 85%. The optical spacer layer is between the reflective electrode and the semiconductor layer stack and includes a conductive and light transmissive material.

In another embodiment, a method for manufacturing a photovoltaic device includes providing a supporting layer proximate to a bottom surface of the device, depositing a conductive and light transmissive layer above the supporting layer, depositing a semiconductor layer stack in an amorphous state above the conductive and light transmissive layer, where the semiconductor layer stack includes first and second sub-layers, and increasing a level of crystallinity in the second sub-layer so that the second sub-layer has a crystalline fraction of at least approximately 85%.

In another embodiment, a method for manufacturing a photovoltaic device includes providing a substrate, depositing a reflective electrode above the substrate, depositing an optical spacer layer above the reflective electrode, the optical spacer layer including a conductive and light transmissive material, depositing a semiconductor layer stack above the optical spacer layer, the semiconductor layer stack being deposited in an amorphous state and including first and second sub-layers, increasing a level of crystallinity in the second sub-layer so that the second sub-layer has a crystalline fraction of at least 85%, and depositing a light transmissive electrode above the semiconductor layer stack.

In another embodiment, a method for manufacturing a photovoltaic device includes providing a light transmissive superstrate, depositing a light transmissive electrode above the superstrate, depositing a semiconductor layer stack above the light transmissive electrode, where the semiconductor layer stack is deposited in an amorphous state and includes first and second sub-layers, increasing a level of crystallinity in the second sub-layer so that the second sub-layer has a crystalline fraction of at least 85%, depositing an optical spacer layer above the semiconductor layer stack, the optical spacer layer comprising a conductive and light transmissive material, and depositing a reflective electrode above the optical spacer layer.

In another embodiment, another photovoltaic device includes a first electrode, a second electrode and a semiconductor layer stack. The first electrode includes a light transmissive material. The second electrode includes a reflective material. The semiconductor layer is between the first electrode and the second electrode and includes at least three sub-layers, including a first sub-layer, a second sub-layer and a third sub-layer. The semiconductor layer also includes a first junction between the first and second sub-layers and a second junction between the second and third sub-layers. The second sub-layer includes a polycrystalline semiconductor material having a crystalline fraction of at least approximately 85%.

### BRIEF DESCRIPTION OF THE SEVERAL VIEWS OF THE DRAWINGS

FIG. 1 is a perspective view of a schematic diagram of a PV device and a magnified view of a cross-sectional portion of the PV device according to some embodiments.

FIG. 2 is a cross-sectional view of the PV cell shown in FIG. 1 taken along line 2-2 in FIG. 1.

FIG. 3 is a graphical representation of a dopant profile in locations that are proximate to the first or second interface shown in FIG. 2.

FIG. 4 is a schematic diagram of a cross-sectional view of a portion of a PV cell with a semiconductor layer stack that is directly deposited in a microcrystalline state.

FIG. 5 is a schematic diagram of a cross-sectional view of a portion of a PV cell with a semiconductor layer stack that is deposited in an amorphous state and then crystallized in accordance with some embodiments.

FIG. 6 is a schematic diagram of a cross-sectional view of a portion of a PV cell with a semiconductor layer stack that is deposited in an amorphous state and then crystallized in accordance with another embodiment.

FIG. 7 is a schematic view of a layer with the crystalline fraction of the layer measured at a plurality of depths.

FIG. 8 is a flowchart of a method for manufacturing the PV device shown in FIG. 1.

FIG. 9 is a schematic cross-sectional view of a portion of the PV cell shown in FIGS. 1 and 2.

FIG. 10 is a schematic cross-sectional view of another portion of the PV cell shown in FIGS. 1 and 2.

FIG. 11 is a schematic cross-sectional view of another portion of the PV cell shown in FIGS. 1 and 2.

FIG. 12 is a schematic cross-sectional view of another portion of the PV cell shown in FIGS. 1 and 2.

FIG. 13 is a schematic cross-sectional view of another portion of the PV cell shown in FIGS. 1 and 2.

FIG. 14 is a schematic cross-sectional view of another portion of the PV cell shown in FIGS. 1 and 2.

FIG. 15 is a schematic cross-sectional view of another portion of the PV cell shown in FIGS. 1 and 2.

FIG. 16 is a schematic cross-sectional view of another portion of the PV cell shown in FIGS. 1 and 2.

FIG. 17 is a cross-sectional schematic view of a tandem PV cell in accordance with some embodiments.

FIG. 18 is a perspective view of a schematic diagram of a PV device and a magnified view of a cross-sectional portion of the PV device according to another embodiment.

FIG. 19 is a cross-sectional view of the PV cell shown in FIG. 18 taken along line 19-19 in FIG. 18.

FIG. 20 illustrates a flowchart for a method for manufacturing the PV device shown in FIGS. 18 and 19.

FIG. 21 is a schematic cross-sectional view of a portion of the PV cell shown in FIGS. 18 and 19.

FIG. 22 is a schematic cross-sectional view of another portion of the PV cell shown in FIGS. 18 and 19.

FIG. 23 is a schematic cross-sectional view of another portion of the PV cell shown in FIGS. 18 and 19.

FIG. 24 is a schematic cross-sectional view of another portion of the PV cell shown in FIGS. 18 and 19.

FIG. 25 is a schematic cross-sectional view of another portion of the PV cell shown in FIGS. 18 and 19.

FIG. 26 is a schematic cross-sectional view of another portion of the PV cell shown in FIGS. 18 and 19.

FIG. 27 is a schematic cross-sectional view of another portion of the PV cell shown in FIGS. 18 and 19.

FIG. 28 is a schematic cross-sectional view of another portion of the PV cell shown in FIGS. 18 and 19.

FIG. 29 is a top schematic view of a system in which a plurality of e-beam sources scans a large area panel in accordance with some embodiments.

FIG. 30 is a top schematic view of another system in which a plurality of e-beam sources scans a large area panel in accordance with another embodiment.

FIG. 31 is a top schematic view of a system in which a plurality of e-beam sources scans a large area panel in accordance with an embodiment.

The foregoing summary, as well as the following detailed description of certain embodiments of the presently described technology, will be better understood when read in conjunction with the appended drawings. For the purpose of illustrating the presently described technology, certain embodiments are shown in the drawings. It should be understood, however, that the presently described technology is not limited to the arrangements and instrumentality shown in the attached drawings. Moreover, it should be understood that the components in the drawings are not to scale and the relative sizes of one component to another should not be construed or interpreted to require such relative sizes.

### DETAILED DESCRIPTION OF THE INVENTION

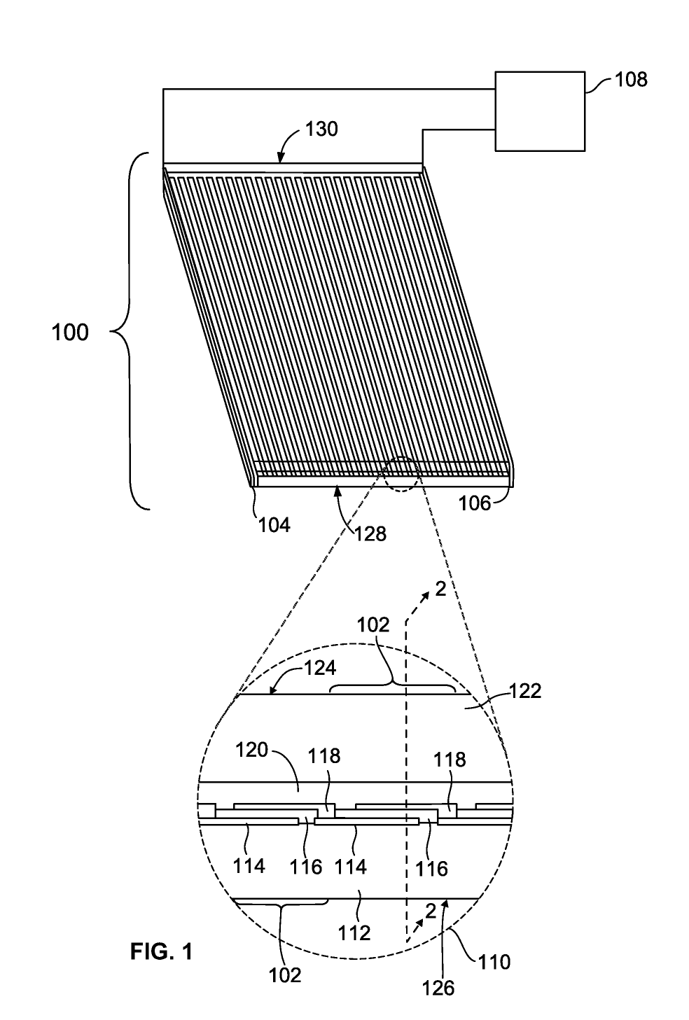

FIG. 1 is a perspective view of a schematic diagram of a PV device 100 and a magnified view 110 of a cross-sectional portion of the PV device 100 according to some embodiments. The PV device 100 includes a plurality of PV cells 102 electrically connected in series with one another. For example, the PV device 100 may have one hundred or more PV cells 102 connected with one another in series. Each of the outermost PV cells 102 also may be electrically connected with one of a plurality of leads 104, 106. The leads 104, 106 extend between opposing ends 128, 130 of the PV device 100. The leads 104, 106 are connected with a circuit 108. The circuit 108 is a load to which the current generated by the PV device 100 is collected or applied.

Each of the PV cells 102 includes a stack of multiple layers. In some embodiments, each PV cell 102 includes a substrate 112, a bottom electrode 114, a semiconductor layer stack 116, a top electrode 118, a top adhesive 120 and a cover sheet 122. The top electrode 118 of one PV cell 102 is electrically connected with the bottom electrode 114 in a neighboring PV cell 102. By connecting the top and bottom electrodes 118, 114 of neighboring PV cells 102 in this way, the PV cells 102 in the PV device 100 may be connected in series.

The PV device 100 generates electric current from light that is incident on a top surface 124. The light passes through the cover sheet 122, the top adhesive 120 and the top electrode 118. The light is absorbed by the semiconductor layer stack 116. Some of the light may pass through the semiconductor layer stack 116. This light may be reflected back into the semiconductor layer stack 116 by the bottom electrode 114.

Photons in the light excite electrons and cause the electrons to separate from atoms in the semiconductor layer stack 116. Complementary positive charges, or holes, are created when the electrons separate from the atoms. The electrons drift or diffuse through the semiconductor layer stack 116 and are collected at one of the top and bottom electrodes 118, 114. The holes drift or diffuse through the semiconductor layer stack 116 and are collected at the other of the top and bottom electrodes 118, 114. The collection of the electrons and holes at the top and bottom electrodes 118, 114 generates a voltage difference in each of the PV cells 102. The voltage difference in the PV cells 102 may be additive across the entire PV device 100. For example, the voltage difference in each of the PV cells 102 is added together. As the number of PV cells 102 increases, the additive voltage difference across the series of PV cells 102 also may increase.

The electrons and holes flow through the top and bottom electrodes 118, 114 in one PV cell 102 to the opposite electrode 114, 118 in a neighboring PV cell 102. For example, if the electrons flow to the bottom electrode 114 in a first PV cell 102 when light strikes the semiconductor layer stack 116, then the electrons flow through the bottom electrode 114 to the top electrode 118 in the neighboring PV cell 102. Similarly, if the holes flow to the top electrode 118 in the first PV cell 102, then the holes flow through the top electrode 118 to the bottom electrode 114 in the neighboring PV cell 102.

Electric current and voltage is generated by the flow of electrons and holes through the top and bottom electrodes 118, 114 and between neighboring PV cells 102. The voltage generated by each PV cell 102 is added in series across the plurality of PV cells 102. The current is then drawn to the circuit 108 through the connection of the leads 104, 106 to the top and bottom electrodes 118, 114 in the outermost PV cells 102. For example, a first lead 104 may be electrically connected to the top electrode 118 in the left-most PV cell 102 while a second lead 106 is electrically connected to the bottom electrode 114 in the right-most PV cell 102.

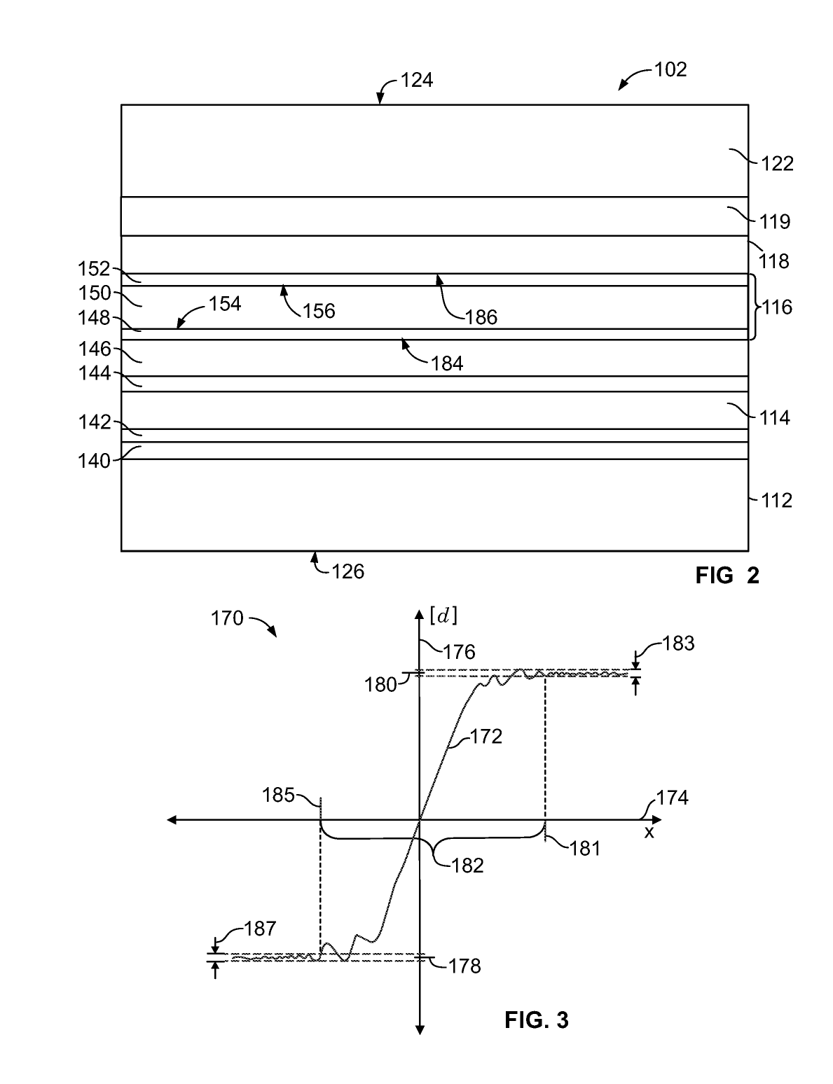

FIG. 2 is a cross-sectional view of the PV cell 102 taken along line 2-2 shown in FIG. 1. In some embodiments, the PV cell 102 includes layers in addition to those shown in FIG. 1. For example, the PV cell 102 may include a barrier layer 140, a bottom adhesive layer 142, a passivation layer 144 and an optical spacer layer 146. The barrier layer 140 may be located above the substrate 112. The bottom adhesive layer 142 may be provided on the barrier layer 140 between the barrier layer 140 and the bottom electrode 114. The passivation layer 144 may be provided on the bottom electrode 114. The optical spacer layer 146 is between the bottom electrode 114 and the semiconductor layer stack 116. For example, the optical spacer layer 146 may be on the passivation layer 144 between the passivation layer 144 and the semiconductor layer stack 116.

When compared to many existing PV devices, the PV cells 102 in the PV device 100 (shown in FIG. 1) may provide a greater efficiency in converting incident light into electric current while lowering the cost of manufacturing the PV cells 102. In addition, as described below, the PV cell 102 includes a polycrystalline semiconductor material in the semiconductor layer stack 116 that may be deposited in an amorphous state in a relatively rapid manner, followed by crystallization of the semiconductor material in a relatively rapid fashion to produce high-electronic quality material. By reducing the amount of time required to deposit and crystallize the semiconductor layer stack 116, the throughput of manufacturing PV cells 102 and PV devices 100 may increase. Furthermore, since the process window for producing uniform amorphous silicon films can be wider than the window for producing uniform directly-deposited microcrystalline silicon films, the large-area uniformity of polycrystalline silicon films 116 produced from amorphous silicon precursor films can be much greater than the uniformity of directly-deposited microcrystalline silicon films.

The crystallization of the semiconductor material in the semiconductor layer stack 116 may occur at lower temperatures and/or more rapidly than those temperatures and crystallization times used in manufacturing many existing PV devices. For example, the crystallization of the semiconductor material in the semiconductor layer stack 116 may occur at a low enough temperature and/or short enough time so as to avoid damage to other layers in the PV cell 102. In one example, the crystallization temperature and/or time may be sufficiently low and/or short so that less expensive materials may be used in other components of the PV cell 102. These less expensive materials tend to have lower melting or softening temperatures. By keeping the temperature and/or time duration of the crystallization of the semiconductor layer stack 116 low and/or short, these less expensive materials are not melted or softened. In another example, the crystallization temperature and/or time may be sufficiently low and/or short so that a larger variety of materials may be included in the various layers of the PV cell 102. For example, the optical spacer layer 146 may include a transparent conductive material between the bottom electrode 114 and the semiconductor layer stack 116. The electronic properties of transparent conductive materials tend to degrade significantly if the transparent conductive materials are subject to the crystallization temperatures and time durations used in known methods for manufacturing PV devices.

In another example, the crystallization temperature and/or time may be sufficiently low and/or fast to decrease the interdiffusion of impurities in the various layers of the PV cell 102. In one example, the temperature is low enough and/or the time is short enough to decrease the diffusion of impurities from the substrate 112 into adjacent layers. Additionally, by decreasing the diffusion of impurities in the substrate 112, materials having a greater concentration per unit volume of impurities may be used in the substrate 112. These types of materials tend to be less expensive than the materials used in the substrates for some known PV cells and modules.

In another example, the diffusion of dopants in the semiconductor layer stack 116 is decreased by keeping the crystallization temperature lower and/or time shorter than many known methods of crystallizing semiconductor layers. By decreasing the diffusion of dopants in the semiconductor layer stack 116, one or more dopant junctions in the semiconductor layer stack 116 may be maintained during crystallization of the semiconductor layer stack 116. Maintaining dopant junctions in the semiconductor layer stack 116 permits the semiconductor layer stack 116 to have a middle layer of an intrinsic semiconductor material with highly doped layers of semiconductor material on opposing sides of the middle layer in one embodiment. The inclusion of an intrinsic middle layer may reduce the number of electrons and holes that recombine in the semiconductor layer stack 116. The inclusion of the highly doped top and bottom layers may permit Ohmic contacts to be formed between the semiconductor layer stack 116 and the bottom and top electrodes 114, 118. Additionally, the top and bottom semiconductor layers in the semiconductor layer stack 116 can form selective contacts for carrier collection, thereby facilitating the collection of one carrier type at the bottom electrode 114 and the collection of the opposite carrier type at the top electrode 118.

Turning to the structure of the PV cells 102, the substrate 112 is located at the bottom of the PV cell 102 proximate to the bottom surface 126 of the PV device 100. The substrate 112 provides mechanical support to the other layers in the PV cell 102. For example, the substrate 112 is a supporting layer supports the other layers in the PV cells 102 during handling, installation and operation of the PV device 100 (shown in FIG. 1). The substrate 112 may be continuous across the bottom of the PV device 100. For example, a single substrate 112 may support all of the other layers in all of the PV cells 102 in the PV device 100. In some embodiments, the substrate 112 has a surface area of at least approximately 5.72 square meters. For example, the substrate 112 may have a surface with dimensions of at least approximately 2.2 meters by approximately 2.6 meters. In another embodiment, the substrate 112 has a surface area of at least four square meters. In another embodiment, the substrate 112 has a different surface area or a surface with different dimensions.

In some embodiments, the substrate 112 is formed from a dielectric material. For example, the substrate 112 may be formed from a glass such as float glass or borosilicate glass. In another example, the substrate 112 may be formed from soda-lime float glass, low iron float glass or a glass that includes at least 10 percent by weight of sodium oxide (Na₂O). In another embodiment, the substrate 112 is formed from another ceramic such as silicon nitride (Si₃N₄) or aluminum oxide (alumina, or Al₂O₃). In another embodiment, the substrate 112 is formed from a conductive material such as a metal. For example, the substrate 112 may be formed from stainless steel, aluminum, or titanium.

The substrate 112 may be formed from materials having a relatively low softening point. For example, the substrate 112 may be formed from materials having a relatively low temperature at which the substrate 112 starts to soften and bend when unsupported. In some embodiments, the substrate 112 is formed from one or more materials having a softening point below about 750 degrees Celsius.

The substrate 112 may be provided in a variety of thicknesses. For example, the substrate 112 may be any thickness sufficient to support the remaining layers of the PV cell 102 while providing mechanical and thermal stability to the PV cell 102 during manufacturing and handling of the PV cell 102. By way of example only, the substrate 112 may be at least approximately 0.7 to 5.0 millimeters thick. In some embodiments, the substrate 112 includes an approximately 1.1 millimeter thick layer of borosilicate glass. In another embodiment, the substrate 112 includes an approximately 3.3 millimeter thick layer of low iron or standard float glass. Other thicknesses of the substrate 112 also may be used.

The barrier layer 140 is deposited on the substrate 112 between the substrate 112 and the semiconductor layer stack 116. In some embodiments, the barrier layer 140 is deposited directly on top of the substrate 112. The barrier layer 140 may be provided as a diffusion barrier. For example, the barrier layer 140 may be a layer that impedes the diffusion of impurities from the substrate 112 up into other layers in the PV cell 102. In one example, the barrier layer 140 impedes diffusion of sodium (Na) from the substrate 112 up into the semiconductor layer stack 116. As described above, the substrate 112 may include a material such as float glass. Float glass may include a significant amount of impurities per unit volume. These impurities can include Na₂O₃ or CaO, for example. The substrate 112 may be heated during the manufacture of the PV device 100 (shown in FIG. 1). Sodium in the substrate 112 may diffuse out of the substrate 112 when the substrate 112 is heated. The barrier layer 140 can prevent the sodium from diffusing out of the substrate 112 or reduce the amount of sodium that would otherwise diffuse out of the substrate 112 into the semiconductor layer stack 116.

The barrier layer 140 may be provided as a thermal barrier. For example, the barrier layer 140 may be a layer that does not strongly conduct heat from the semiconductor layer stack 116 to the substrate 112 in order to reduce the risk of damaging the substrate 112 during processing steps where the semiconductor layer stack 116 is heated. In one example, the barrier layer 140 may have a thermal conductivity of approximately 30 W/(m*degrees Kelvin) or less. In another example, the barrier layer 140 has a thermal conductivity of approximately 1.10 W/(m*degrees Kelvin) or less. As described below, the semiconductor layer stack 116 may be heated during crystallization of at least a portion of the semiconductor layer stack 116. Without the barrier layer 140, the substrate 112 may soften or be damaged by the heat emanating out of the semiconductor layer stack 116 during crystallization of the semiconductor layer stack 116.

The barrier layer 140 may be formed from or include a dielectric material. For example, the barrier layer 140 may be formed from alumina (Al₂O₃), silicon nitride (Si₃N₄) and/or SiO₂. The barrier layer 140 may include fewer impurities per unit volume than the substrate 112 in some embodiments. This increased purity of the barrier layer 140 may provide the barrier layer 140 with a higher melting temperature than the substrate 112.

The barrier layer 140 can be deposited in a variety of thicknesses. For example, the barrier layer 140 may be deposited in a thickness that is less than the thickness of the substrate 112. By way of example only, the barrier layer 140 can be deposited in a layer that is approximately 0.05 to 1 micrometers thick. In some embodiments, the barrier layer 140 is approximately 150 nanometers thick. The thickness of the barrier layer 140 may be varied from these embodiments. For example, a variance of +/−10% or less of the thickness of the barrier layer 140 in these embodiments may be acceptable.

The bottom adhesive layer 142 is deposited on the barrier layer 140. In some embodiments, the bottom adhesive layer 142 is deposited directly on top of the barrier layer 140. The bottom adhesive layer 142 assists in securing the bottom electrode 114 to the barrier layer 140. The bottom adhesive layer 142 can include a material that adheres the bottom electrode 114 to the barrier layer 140. Examples of materials that may be used in the bottom adhesive layer 142 include titanium (Ti), chromium (Cr), nichrome (NiCr) and zinc oxide (ZnO). The bottom adhesive layer 142 may be deposited in a variety of thicknesses. For example, the bottom adhesive layer 142 may be deposited in a thickness that is sufficient to prevent the bottom electrode 114 from separating from the barrier layer 140 or substrate 112. In some embodiments, the bottom adhesive layer 142 is deposited in a thickness that is less than the thickness of the substrate 112 and the thickness of the barrier layer 140. By way of example only, the bottom adhesive layer 142 may be deposited in a layer that is approximately 1 to 100 nanometers thick. In another example, the bottom adhesive layer 142 may be deposited to be approximately 30 nanometers thick. The thickness of the bottom adhesive layer 142 may be varied from these embodiments. For example, a variance of +/−10% or less of the thickness of the bottom adhesive layer 142 in these embodiments may be acceptable.

In another embodiment, one or more of the barrier layer 140 and the bottom adhesive layer 142 is omitted from the PV cell 102. In embodiments where the barrier layer 140 is not included in the PV cell 102, the bottom adhesive layer 142 may be deposited directly on the substrate 112 and the bottom electrode 114 may be deposited on the bottom adhesive layer 142. In embodiments where the bottom adhesive layer 142 is not included in the PV cell 102, the bottom electrode 114 may be deposited on the barrier layer 140. In embodiments where neither the barrier layer 140 nor the bottom adhesive layer 142 is included in the PV cell 102, the bottom electrode 114 is deposited directly on the substrate 112.

The bottom electrode 114 is deposited on the bottom adhesive layer 142. In some embodiments, the bottom electrode 114 is deposited directly on top of the bottom adhesive layer 142. As described above, electrons or holes in the semiconductor layer stack 116 drift to the bottom electrode 114. The bottom electrode 114 in one PV cell 102 is electrically connected to the top electrode 118 in a neighboring PV cell 102. The bottom electrode 114 includes a conductive material. In some embodiments, the bottom electrode 114 is formed from a reflective conductive material. For example, the bottom electrode 114 may be formed from a metal such as silver (Ag), molybdenum (Mo), titanium (Ti), nickel (Ni), tantalum (Ta), aluminum (Al) or tungsten (W). In another embodiment, the bottom electrode 114 is formed from an alloy that includes one or more of silver (Ag), molybdenum (Mo), titanium (Ti), nickel (Ni), tantalum (Ta), aluminum (Al) and tungsten (W). One example of such an alloy is a silver-tungsten alloy.

The bottom electrode 114 may reflect light into the semiconductor layer stack 116. For example, a portion of the light that is incident on a top surface 124 of the PV cell 102 may pass through the semiconductor layer stack 116. At least some of this light may be reflected by the bottom electrode 114 back up into the semiconductor layer stack 116.

The bottom electrode 114 may be deposited in a variety of thicknesses. For example, the bottom electrode 114 may be deposited in a thickness that is sufficient to permit the conduction of current generated by the flow of electrons or holes through the bottom electrode 114 without significant resistance. In some embodiments, the bottom electrode 114 is deposited in a thickness that is less than the substrate 112 but greater than the barrier layer 140 and greater than the bottom adhesive layer 142. By way of example only, the bottom electrode 114 may be approximately 50 to 500 nanometers thick. In another embodiment, the bottom electrode 114 may be approximately 200 nanometers thick. The thickness of the bottom electrode 114 may be varied from these embodiments. For example, a variance of +/−10% or less of the thickness of the bottom electrode 114 in these embodiments may be acceptable.

The passivation layer 144 may be deposited on the bottom electrode 114 in some embodiments. In some embodiments, the passivation layer 144 is deposited directly on top of the substrate bottom electrode 114. The passivation layer 144 may impede corrosion of the bottom electrode 114. For example, the passivation layer 144 may prevent corrosion of the bottom electrode 114 that is caused by a chemical reaction between the bottom electrode 114 and one or more other layers in the PV cell 102. The passivation layer 144 may be formed from a material such as nichrome (NiCr). The passivation layer 144 may be deposited in a variety of thicknesses. For example, the passivation layer 144 may be approximately 0.5 to 5 nanometers thick. In another embodiment, the passivation layer 144 is omitted from the PV cell 102. In such an embodiment, the optical spacer layer 146 may be deposited on the bottom electrode 114.

The optical spacer layer 146 is located between the bottom electrode 114 and the semiconductor layer stack 116. The optical spacer layer 146 may assist in stabilizing the bottom electrode 114 and assisting in preventing chemical attack on the semiconductor layer stack 116 by the bottom electrode 114. The optical spacer layer 146 may be similar to a buffer layer that impedes or prevents contamination of the semiconductor layer stack 116 by the bottom electrode 114 in some embodiments. The optical spacer layer 146 reduces plasmon absorption losses in the semiconductor layer stack 116 in some embodiments.

The optical spacer layer 146 may be deposited on the passivation layer 144. In another embodiment, the optical spacer layer 146 is deposited on the bottom electrode 114. By way of example only, the optical spacer layer 146 may be deposited directly on top of the passivation layer 144 or the bottom electrode 114.

In some embodiments, the optical spacer layer 146 includes or is formed from a light transmissive material such as an optically clear or light-scattering layer of material. For example, the optical spacer layer 146 may be formed from a transparent material. In another example, the optical spacer layer 146 may be formed from a translucent material. One example of a material for the optical spacer layer 146 is a transparent conductive oxide (“TCO”) material. For example, the optical spacer layer 146 may include zinc oxide (ZnO), aluminum-doped zinc oxide (Al:ZnO), tin oxide (SnO₂), Indium Tin Oxide (“ITO”), fluorine doped tin oxide (SnO₂:F), and/or titanium dioxide (TiO₂). TCO materials may tend to have softening and/or melting temperatures that cannot withstand the processing temperatures used in the manufacture of many existing PV devices. By keeping the temperature and/or time duration at which the semiconductor layer stack 116 in the PV cell 102 is crystallized relatively low and/or short, TCO materials may be included in the optical spacer layer 146 and the optical spacer layer 146 may be deposited before and below the semiconductor layer stack 116.

The optical spacer layer 146 may include or be formed of a material that is at least partially conductive. For example, the optical spacer layer 146 may include a conductive material that assists in forming Ohmic contacts between the semiconductor layer stack 116 and the bottom electrode 114.

The optical spacer layer 146 may assist in the reflection of certain wavelengths of light off of the bottom electrode 114. For example, the optical spacer layer 146 may be deposited in a thickness that permits certain wavelengths of light that pass through the semiconductor layer stack 116 to pass through the optical spacer layer 146, reflect off of the top of the bottom electrode 114, pass through the optical spacer layer 146 again and strike the semiconductor layer stack 116. In doing so, the optical spacer layer 146 may increase the efficiency of the PV cell 102 by increasing the amount of light that strikes the semiconductor layer stack 116 and generates electrons and holes.

While the thickness of the optical spacer layer 146 may be varied to adjust which wavelengths of light are reflected off of the bottom electrode 114 up into the semiconductor layer stack 116, the optical spacer layer 146 may be a thickness that is less than the thickness of the substrate 112, the thickness of the bottom electrode 114, or the thickness of a combination of the substrate 112 and the bottom electrode 114. The optical spacer layer 146 also may be a thickness that is less than the thickness of the bottom adhesive layer 142. By way of example only, the optical spacer layer 146 may be approximately 10 to 200 nanometers thick. In some embodiments, the thickness of the optical spacer layer 146 is related to the wavelength of light that is sought to be reflected off of the bottom electrode 114 back up into the semiconductor layer stack 114. For example, the thickness of the optical spacer layer 146 may be approximately ¼ of the wavelength of light sought to be reflected off of the bottom electrode 114, divided by the index of refraction of the material used in the optical spacer layer 146. By way of example only, if the wavelength of light sought to be reflected from the bottom electrode 114 into the semiconductor layer stack 116 is approximately 700 nm and the index of refraction of the optical spacer layer 146 is approximately 2, then the thickness of the optical spacer layer 146 may be approximately 87.5 nanometers. The thickness of the optical spacer layer 146 may be varied from these embodiments. For example, a variance of +/−10% or less of the thickness of the optical spacer layer 146 in these embodiments may be acceptable.

The semiconductor layer stack 116 is located above the optical spacer layer 146. In some embodiments, the semiconductor layer stack 116 is deposited directly on the optical spacer layer 146. The semiconductor layer stack 116 may include a plurality of sub-layers of semiconductor material. For example, in one embodiment, the semiconductor layer stack 116 includes three semiconductor sub-layers 148, 150, 152. The first semiconductor sub-layer 148 is deposited on the optical spacer layer 146. The second semiconductor sub-layer 150 is deposited on the first semiconductor sub-layer 146. The third semiconductor sub-layer 152 is deposited on the second semiconductor sub-layer 150. In some embodiments, the first, second and third sub-layers 148, 150, 152 are deposited directly on one another. While three semiconductor sub-layers 148, 150, 152 are shown in FIG. 2, a different number of semiconductor sub-layers may be provided.

The semiconductor layer stack 116 includes a semiconductor material. For example, the semiconductor layer stack 116 may be formed from silicon (Si). In another example, the semiconductor layer stack 116 may be formed from one or more of germanium (Ge) and gallium arsenide (GaAs). Other compound semiconductors may be used in the semiconductor layer stack 116. In some embodiments, all of the first, second and third semiconductor sub-layers 148, 150, 152 are formed from the same semiconductor material. For example, all of the first, second and third semiconductor sub-layers 148, 150, 152 may be formed from silicon.

In some embodiments, the first semiconductor sub-layer 148 includes or is formed of silicon carbide. For example, the first semiconductor sub-layer 148 may be formed of SiC, non-stoichiometric SiₓC₁₋ₓ, phosphorus-doped n+ SiC, phosphorus-doped SiₓC₁₋ₓ, boron-doped p+ SiC, boron-doped p+ SiₓC₁₋ₓ, unintentionally doped or intrinsic SiC, or unintentionally doped or intrinsic SiₓC₁₋ₓ. In such an embodiment, the first semiconductor sub-layer 148 may have a higher melting temperature than a similar sub-layer formed of silicon. For example, the first semiconductor sub-layer 148 may have a melting temperature of at least approximately 2000 degrees Celsius. In another example, the first semiconductor sub-layer 148 may have a melting temperature of at least approximately 2730 degrees Celsius.

The total thickness of the semiconductor layer stack 116 may vary. In some embodiments, the semiconductor layer stack 116 is deposited in a total thickness that is sufficiently small that the minority carrier diffusion or drift length in the semiconductor layer stack 116 is larger than the thickness of the semiconductor layer stack 116. For example, the diffusion or drift length of electrons and holes generated in the semiconductor layer stack 116 by incident light can be at least two to four times longer than the thickness of the semiconductor layer stack 116. In another example, the minority carrier diffusion or drift length can be at least five to ten times longer than the thickness of the semiconductor layer stack 116. In some embodiments, the thickness of the semiconductor layer stack 116 is less than the thickness of an electronic grade silicon or multicrystalline silicon wafer. The semiconductor layer stack 116 may have sufficient thickness to absorb enough light to generate a desired level of power from the PV cell 102.

Each of the semiconductor sub-layers 148, 150, 152 may be deposited in a variety of thicknesses. By way of example only, the first sub-layer 148 may be deposited to be approximately 10 to 100 nanometers thick. In another example, the first sub-layer 148 is approximately 5 to 30 nanometers thick. In another example, the first sub-layer 148 may be approximately 10 to 20 nanometers thick. The second sub-layer 150 may be deposited to be approximately 1 to 10 micrometers thick. In another example, the second sub-layer 150 may be approximately 1 to 2 micrometers thick. The third sub-layer 152 may be deposited to be approximately 10 to 100 nanometers thick. In another example, the third sub-layer 152 may be approximately 5 to 30 nanometers thick. In another example, the third sub-layer 152 may be approximately 10 to 20 nanometers thick. The thicknesses of the semiconductor layer stack 116 and any of the first, second and third sub-layers 148, 150, 152 may be varied from these embodiments. For example, a variance of +1-10% or less of the thickness of the semiconductor layer stack 116 and any of the first, second and third sub-layers 148, 150, 152 in these embodiments may be acceptable.

In some embodiments, dopant junctions exist at interfaces 154, 156 between the first, second and third sub-layers 148, 150, 152. For example, a first dopant junction may exist at the first interface 154 between the first and second semiconductor sub-layers 148, 150. A second dopant junction may exist at the second interface 156 between the second and third semiconductor sub-layers 150, 152. The first and second dopant junctions may be created by doping the semiconductor sub-layers on opposing sides of each of the interfaces 154, 156 with oppositely charged dopants and/or with different concentrations of dopants.

With respect to the oppositely charged dopants, each of the first and third semiconductor sub-layers 148, 152 are doped with n-type or p-type dopants. One example of an n-type dopant is phosphorus (P) while an example of a p-type dopant is boron (B). The second semiconductor sub-layer 150 may be an intrinsic or lightly doped semiconductor in some embodiments. For example, the second semiconductor sub-layer 150 may not be intentionally doped or may have a dopant concentration that less than 10¹⁸/cm³. In another embodiment, the second semiconductor sub-layer 150 is doped with an n-type or p-type dopant.

FIG. 3 is a graphical representation 170 of a dopant profile 172 in locations that are proximate to the first or second interface 154, 156 (shown in FIG. 2). The dopant profile 172 represented in FIG. 3 may be provided at the first or second interfaces 154, 156. An x-axis 174 represents the distances into the two semiconductor sub-layers 148, 150, 152 that meet at one of the interfaces 154, 156. For example, the right side of the x-axis 174 may represent the depth into the first semiconductor sub-layer 148 from the first interface 154. Increasing distances along the x-axis 174 towards the right side of FIG. 3 indicates a greater depth into the first semiconductor sub-layer 148 from the first interface 154. The left side of the x-axis 174 may represent the depth into the second semiconductor sub-layer 150 from the first interface 154. Increasing distances along the x-axis 174 towards the left side of FIG. 3 indicates a greater depth into the second semiconductor sub-layer 150 from the first interface 154. The location of the first interface 154 may therefore be represented by the location of a y-axis 176 on the x-axis 174.

In another example, the right side of the x-axis 174 may represent the depth into the third semiconductor sub-layer 152 from the second interface 156. Increasing distances along the x-axis 174 towards the right side of FIG. 3 (referred to as the “positive x-direction”) indicates a greater depth into the third semiconductor sub-layer 152 from the second interface 156. The left side of the x-axis 174 may represent the depth into the second semiconductor sub-layer 150 from the second interface 156. Increasing distances along the x-axis 174 towards the left side of FIG. 3 (referred to as the “negative x-direction”) indicates a greater depth into the second semiconductor sub-layer 150 from the second interface 156. The location of the second interface 156 may therefore be represented by the location of a y-axis 176 on the x-axis 174.

A y-axis 176 represents the concentration of a dopant in the two semiconductor sub-layers 148, 150, 152 that meet at the first or second interface 154, 156. Increasing distances along the y-axis 176 in an upward direction of FIG. 3 (referred to as the “positive y-direction”) indicates a greater concentration of the dopant type. Conversely, increasing distances along the y-axis 176 in a downward direction of FIG. 3 (referred to as the “negative y-direction”) indicates a smaller concentration of the dopant type.

As shown in FIG. 3, the dopant profile 172 includes a larger dopant concentration in the positive x-direction along the x-axis 174 than the concentration in the negative x-direction along the x-axis 174. For example, the dopant profile 172 increases from a first dopant concentration 178 in the negative x-direction to a second dopant concentration 180 in the positive x-direction. In some embodiments, the first dopant concentration 178 may be approximately zero. For example, the first dopant concentration 178 may indicate that there is no dopant or that the material is an intrinsic material. In another embodiment, the first dopant concentration 178 is at least one order of magnitude smaller than the second dopant concentration 180. For example, the second dopant concentration 180 may be ten times larger than the first dopant concentration 178. The increase in dopant concentration along the x-axis 174 indicates that the dopant concentration on one side of the interface 154, 156 is significantly greater than the dopant concentration on the other side of the same interface 154, 156. For example, the dopant concentration on the positive x-direction is greater than the dopant concentration in the negative x-direction.

In some embodiments, if the first interface 154 is represented in FIG. 3, then the dopant concentration in the first semiconductor sub-layer 148 may increase from a concentration between first and second dopant concentrations 178, 180 at the first interface 154 to the second dopant concentration 180 with increasing depth into the first semiconductor sub-layer 148 from the first interface 154. Moreover, the dopant concentration in the second semiconductor sub-layer 150 decreases with increasing depth into the second semiconductor sub-layer 150 from the first interface 154. For example, the dopant concentration in the second semiconductor sub-layer 150 may decrease from a dopant concentration between the first and second dopant concentrations 178, 180 at the first interface 154 to the second dopant concentration 178.

In some embodiments, the distance along the x-axis 174 between the first and second dopant concentrations 178, 180 is a junction diffusion width 182. The junction diffusion width 182 may be the thickness of a dopant junction at an interface between two semiconductor materials. For example, the junction diffusion width 182 may be the thickness of the dopant junction between the first and second semiconductor sub-layers 148, 150 at the first interface 154 or between the second and third semiconductor sub-layers 150, 152 at the second interface 156. In one embodiment, the junction diffusion width 182 is the distance between the depths into the sub-layers 148, 150, 152 at the interface 154, 156 at which each of the first and second dopant concentrations 178, 180 are within 5% of the concentrations 178, 180. In another embodiment, the junction diffusion width 182 is the distance between the points at which each of the first and second dopant concentrations 178, 180 are within 10% of the concentrations 178, 180. For example, the first dopant concentration 178 may slightly vary throughout all or a part of the thickness of the first sub-layer 148. The depth in the first sub-layer 148 at which the dopant concentration is considered to be at the first dopant concentration 178 may be the depth at which the dopant concentration becomes approximately constant, or does not vary by more than 5% from the first dopant concentration 178. In another example, the second dopant concentration 180 may slightly vary throughout the thickness of the second sub-layer 150. The depth in the second sub-layer 150 at which the dopant concentration is considered to be at the second dopant concentration 180 may be the depth at which the dopant concentration becomes approximately constant, or does not vary by more than 5% from the second dopant concentration 180.

With respect to the different dopant concentrations, one or more of the first, second and third semiconductor sub-layers 148, 150, 152 may be doped with an n-type or p-type dopant. For example, the first, second and/or third semiconductor sub-layers 148, 150, 152 may be doped at a concentration of approximately 1×10¹⁴ per cubic centimeter to 1×10²⁰ per cubic centimeter. Alternatively, one or more of the first, second and third semiconductor sub-layers 148, 150, 152 is an intrinsic or lightly doped material.

The first, second and/or third semiconductor sub-layers 148, 150, 152 may be referred to as a p, p+, n, n+ or i material. A p-type material is a semiconductor material that is doped with a p-type dopant at a concentration that is at least approximately 1×10¹⁶ per cubic centimeter but less than approximately 1×10¹⁸ per cubic centimeter. A p+ type material is a semiconductor material that is doped with a p-type dopant at a concentration that is at least 1×10¹⁸ per cubic centimeter. An n-type material is a semiconductor material that is doped with an n-type dopant at a concentration that is at least approximately 1×10¹⁶ per cubic centimeter but less than approximately 1×10¹⁸ per cubic centimeter. An n+ type material is a semiconductor material that is doped with an n-type dopant at a concentration that is at least 1×10¹⁸ per cubic centimeter. An intrinsic, or i-type, material is a material that is not intentionally doped or that is doped at a concentration of less than 1×10¹⁶ per cubic centimeter.

In some embodiments, the semiconductor sub-layers 148, 150, 152 that are doped are uniformly doped materials. For example, the dopant concentrations in the doped ones of the semiconductor sub-layers 148, 150, 152 are doped throughout the respective sub-layer so that no dopant junction is created within that sub-layer. For example, one or more of the semiconductor sub-layers 148, 150, 152 can be uniformly doped so that no dopant junction is created within the doped semiconductor sub-layer 148, 150, 152.

A variety of dopant type and dopant concentrations may be used among the first, second and third semiconductor sub-layers 148, 150, 152. In some embodiments, the first semiconductor sub-layer 148 is an n+ type material, the second semiconductor sub-layer 150 is an intrinsic material and the third semiconductor sub-layer 152 is a p+ type material. In another embodiment, the first semiconductor sub-layer 148 is a p+ type material, the second semiconductor sub-layer 150 is an intrinsic material and the third semiconductor sub-layer 152 is an n+ type material. Additional combinations of various dopant types and concentrations among the first, second and third semiconductor sub-layers 148, 150, 152 are shown in the table below:

| Sub-layer 148 | Sub-layer 150 | Sub-layer 152 |
|---|---|---|
| n+ | i | p |
| n | i | p+ |
| n | i | p |
| p+ | i | n |
| p | i | n+ |
| p | i | n |

In one embodiment, the second sub-layer 150 may be an n- or p-type material in one or more of the combinations shown in the above table.

In one example embodiment, Ohmic contacts may exist at interfaces 184, 186 (shown in FIG. 2) between the first semiconductor sub-layer 148 and the optical spacer layer 146, and between the third semiconductor sub-layer 152 and the light transmissive top electrode 118, respectively. For example, an Ohmic contact may exist between the first semiconductor sub-layer 148 and the optical spacer layer 146 at the interface 184 when the first semiconductor sub-layer 148 is an n+ or p+ type material. In another example, an Ohmic contact may exist between the third semiconductor sub-layer 152 and the top electrode 118 when the third semiconductor sub-layer 152 is a p+ or n+ type material.

In order to increase the manufacturing throughput of the PV devices 100 (shown in FIG. 1), the semiconductor layer stack 116 may be deposited in an amorphous state followed by crystallization of one or more of the semiconductor sub-layers 148, 150, 152 in the semiconductor layer stack 116. Depositing the semiconductor sub-layers 148, 150, 152 in an amorphous state can be faster than directly depositing the semiconductor sub-layers 148, 150, 152 in a high-quality microcrystalline state. Moreover, the semiconductor sub-layers 148, 150, 152 may be uniformly deposited over a larger surface area when the semiconductor sub-layers 148, 150, 152 are deposited in an amorphous state than if the semiconductor sub-layers 148, 150, 152 were directly deposited in a high quality microcrystalline state.

As described below, after depositing the semiconductor sub-layers 148, 150, 152 in an amorphous state, one or more of the sub-layers 148, 150, 152 may be converted into a polycrystalline material, or crystallized. In some embodiments, a level of crystallinity in the sub-layers 148, 150, and/or 152 may be increased by crystallizing the sub-layers 148, 150 and/or 152 in the solid state, as described below. In another embodiment, a level of crystallinity in the sub-layers 148, 150 and/or 152 is increased by melting the sub-layers 148, 150, and/or 152, as described below.

In some embodiments, only the first and second semiconductor sub-layers 148, 150 are crystallized while the third semiconductor sub-layer 152 remains in an amorphous state. For example, the third semiconductor sub-layer 152 may be deposited after the first and second semiconductor sub-layers 148, 150 are crystallized. In another embodiment, all three of the semiconductor sub-layers 148, 150, 152 are crystallized after being deposited in an amorphous state.

The semiconductor sub-layers 148, 150, 152 that are crystallized after being deposited in an amorphous state may have larger crystalline grains than those present in semiconductor layers that are directly deposited in a microcrystalline state. For example, one or more of the semiconductor sub-layers 148, 150, 152 may have crystalline grains with an average crystalline grain size of at least approximately 50 nanometers. In another embodiment, the average crystalline grain size is at least approximately 100 nanometers. In another embodiment, the average crystalline grain size is at least approximately 20 nanometers. In yet another embodiment, the average crystalline grain size is at least approximately 10 nanometers. Alternatively, the average crystalline grain size may be approximately 1 micrometer or larger.

The average grain sizes in one or more of the semiconductor sub-layers 148, 150, 152 may be determined by a variety of methods. For example, the average grain size can be determined using Transmission Electron Microscopy (“TEM”). In such an example, a thin sample of the semiconductor sub-layer 148, 150, 152 sought to be analyzed is obtained. For example, a sample of one of the semiconductor sub-layers 148, 150, 152 having a thickness of approximately 1 micrometer or less is obtained.

A beam of electrons is transmitted through the sample. The beam of electrons may be rastered across all or a portion of the sample. As the electrons pass through the sample, the electrons interact with the crystalline structure of the sample. The path of transmission of the electrons may be altered by the sample. The electrons are collected after the electrons pass through the sample and an image is generated based on the collected electrons. The image provides a two-dimensional representation of the sample. The crystalline grains in the sample may appear different from the amorphous portions of the sample. Based on this image, the size of crystalline grains in the sample may be measured. For example, the surface area of several crystalline grains appearing in the image can be measured and averaged. This average is the average crystalline grain size in the sample in the location where the sample was obtained. For example, the average may be the average crystalline grain size in the semiconductor sub-layer 148, 150, 152 from which the sample was obtained.

One or more of the semiconductor sub-layers 148, 150, 152 that are crystallized may have a volume fraction of crystalline material, or crystalline fraction, that is at least approximately 98% in one embodiment. For example, the percentage of the total volume of one or more of the semiconductor sub-layers 148, 150, 152 that are crystallized may be at least approximately 98%. In another embodiment, the crystalline fraction is at least approximately 95%. In another embodiment, the crystalline fraction is at least approximately 85%. In another embodiment, the crystalline fraction is greater than approximately 80%. Conversely, the crystalline fraction of semiconductor layers that are directly deposited in a microcrystalline state may not exceed 40 to 80%.

The crystalline fraction of a semiconductor sub-layer 148, 150, 152 can be determined by a number of methods. For example, Raman spectroscopy can be used to obtain a comparison of the relative volume of noncrystalline material to crystalline material in one or more of the semiconductor sub-layers 148, 150, 152. One or more of the sub-layers 148, 150, 152 sought to be examined can be exposed to monochromatic light from a laser, for example. Based on the chemical content and crystal structure of the semiconductor sub-layers 148, 150, 152, the monochromatic light may be scattered. As the light is scattered, the frequency (and wavelength) of the light changes. For example, the frequency of the scattered light can shift. The frequency of the scattered light is measured and analyzed. Based on the intensity and/or shift in the frequency of the scattered light, the relative volumes of amorphous and crystalline material of the semiconductor sub-layers 148, 150, 152 being examined can be determined. Based on these relative volumes, the crystalline fraction in the semiconductor sub-layers 148, 150, 152 being examined may be measured. If several samples of the semiconductor sub-layers 148, 150, 152 are examined, the crystalline fraction may be an average of the several measured crystalline fractions.

In another example, one or more TEM images can be obtained of the semiconductor sub-layers 148, 150, 152 to determine the crystalline fraction. In some embodiments, one or more slices of a semiconductor sub-layer 148, 150, 152 being examined are obtained in a plane that is substantially perpendicular to the interfaces 154, 156. Alternatively, the slices of the semiconductor sub-layers 148, 150, 152 being examined are obtained from a plane that is substantially parallel to the interfaces 154, 156. For example, several slices of semiconductor sub-layers 148, 150, 152 being examined may be obtained at different depths in the semiconductor sub-layers 148, 150, 152. By way of example only, the slices may be approximately 1 micrometer or less thick. The percentage of surface area in each TEM image that represents crystalline material is measured for each TEM image. The percentages of crystalline material in the TEM images can then be averaged to determine the crystalline fraction in the semiconductor sub-layer(s) 148, 150, 152 being examined.

The semiconductor sub-layers 148, 150, 152 that are crystallized may have a final hydrogen concentration that is less than a final hydrogen concentration in a similar semiconductor layer that is directly deposited in a microcrystalline state. For example, the semiconductor sub-layers 148, 150, 152 that are deposited in an amorphous state and then crystallized as described below may have a lower final hydrogen concentration after the last crystallization processing step than similar semiconductor layers of the same semiconductor and approximately the same thickness that are directly deposited in a microcrystalline state.

In general, the final hydrogen concentration in a semiconductor material can be inversely related to the amount of crystalline material in the material and proportional to the grain boundary area in the material. As the area of grain boundaries increases for a semiconductor sample, the volume of the crystalline grains in the sample may decrease. Typically, as long as there has not been any intentional attempt to remove hydrogen from the material other than crystallizing the material as described below, a sample with a smaller hydrogen concentration than a second sample may have larger crystalline grains or a larger crystalline fraction than the second sample.

In some embodiments, the final hydrogen concentration of the semiconductor sub-layers 148, 150, 152 that are deposited in an amorphous state and then crystallized as described below is less than approximately 3 atomic percent. In another embodiment, the final hydrogen concentration is less than or equal to approximately 2 atomic percent. In yet another embodiment, the final hydrogen concentration is less than or equal to approximately 1 atomic percent. Typically, the final hydrogen concentration for semiconductor materials that are directly deposited in a microcrystalline state is greater. For example, the final hydrogen concentration for silicon that is directly deposited in a microcrystalline state typically exceeds 3 atomic percent and may range from 3 to 15 atomic percent.

The final hydrogen concentration in the semiconductor sub-layers 148, 150, 152 may be measured using Secondary Ion Mass Spectrometer (“SIMS”). A sample of the semiconductor sub-layers 148, 150, 152 sought to be measured is placed into the SIMS. The sample is then sputtered with an ion beam. The ion beam causes secondary ions to be ejected from the sample. The secondary ions are collected and analyzed using a mass spectrometer. The mass spectrometer then determines the molecular composition of the sample. The mass spectrometer can determine the atomic percentage of hydrogen in the sample.

Alternatively, the final hydrogen concentration in one or more of the semiconductor sub-layers 148, 150, 152 may be measured using Fourier Transform Infrared spectroscopy (“FTIR”). In FTIR, a beam of infrared light is then sent through a sample of the semiconductor sub-layers 148, 150, 152 sought to be measured. Different molecular structures and species in the sample may absorb the infrared light differently. Based on the relative concentrations of the different molecular species in the sample, a spectrum of the molecular species in the sample is obtained. The atomic percentage of hydrogen in the sample can be determined from this spectrum. Alternatively, several spectra are obtained and the atomic percentage of hydrogen in the sample is determined from the group of spectra.

The crystalline fraction of the semiconductor sub-layers 148, 150 and/or 152 that are crystallized may be uniform throughout the thickness of the semiconductor sub-layers 148, 150 and/or 152. For example, the semiconductor sub-layers 148, 150, 152 that are crystallized may have a crystalline fraction uniformity that does not vary more than approximately 15% throughout a total thickness of one or more of the sub-layers 148, 150, 152. For example, the crystalline fraction of the sub-layer 150 may not vary more than approximately 15% throughout the thickness of the sub-layer 150 in a direction extending between the first and third sub-layers 148, 150 that is substantially perpendicular to the interfaces 154, 156. In another embodiment, the crystalline fraction may not vary more than approximately 10% throughout the thickness of one or more of the sub-layers 148, 150, 152 that are crystallized. In another embodiment, the crystalline fraction of may not vary more than approximately 5% throughout the thickness of the sub-layers 148, 150, 152 that are crystallized. Conversely, the crystalline fraction of semiconductor layers that are directly deposited in a microcrystalline state may vary significantly more throughout the thickness of the semiconductor layers.

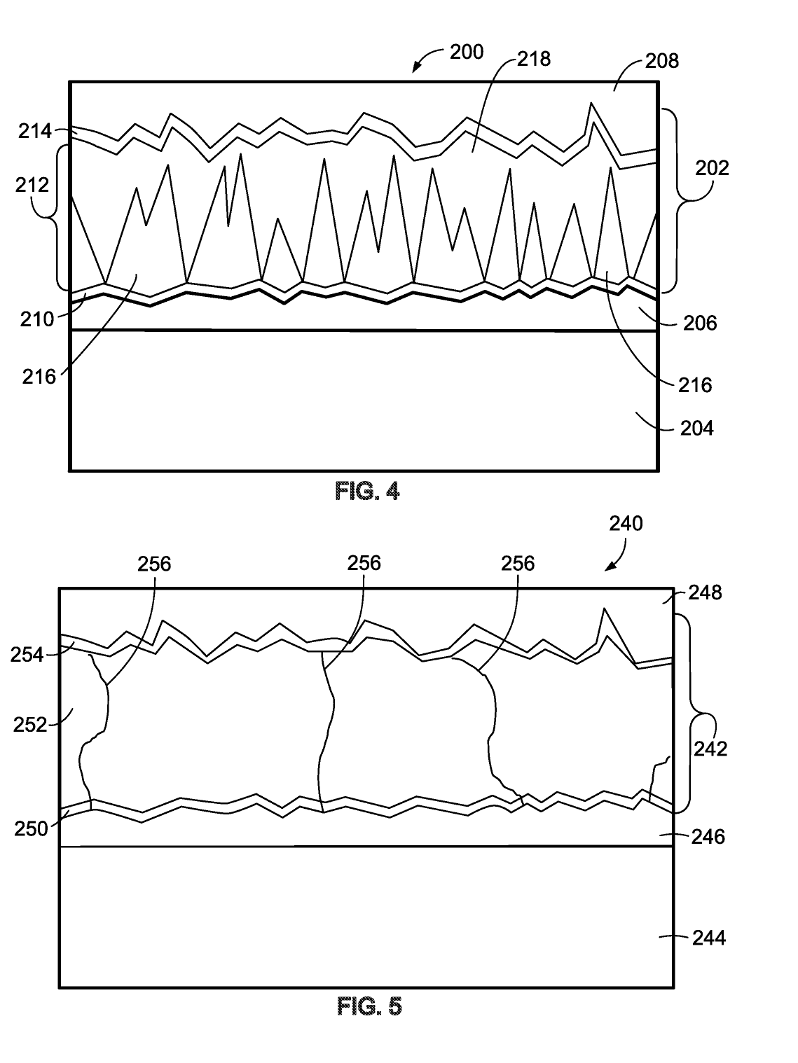

FIG. 4 is a schematic diagram of a cross-sectional view of a portion of a PV cell 200 with a semiconductor layer stack 202 that is directly deposited in a microcrystalline state. FIG. 4 is representative of the distribution of crystalline semiconductor material in many existing PV cells that have semiconductor material that is directly deposited in a microcrystalline state. The portion of the PV cell 200 that is shown in FIG. 4 includes a substrate 204, a bottom electrode 206, the semiconductor layer stack 202, and the top electrode 208. The semiconductor layer stack 202 is directly deposited as a microcrystalline semiconductor material. The semiconductor layer stack 202 may be approximately 2 micrometers thick, for example. The crystalline grains (not shown) in the semiconductor layer stack 202 may have an average diameter of approximately 10 to 20 nanometers.

The semiconductor layer stack 202 includes three sub-layers 210, 212, 214. The first sub-layer 210 may be a highly doped mixed-phase amorphous and microcrystalline silicon material. For example, the first sub-layer 210 may include n+ or p+ type mixed phase amorphous and microcrystalline silicon. The third sub-layer 214 may be a highly doped amorphous semiconductor material. For example, the third sub-layer 214 may include n+ or p+ type amorphous silicon. The second sub-layer 212 may be an intrinsic semiconductor that includes an amorphous portion 216 and a microcrystalline portion 218. The amorphous portion 216 includes amorphous semiconductor material. The microcrystalline portion 218 includes a plurality of silicon grains which may range from approximately 10 to 20 nanometers in diameter.

As shown in FIG. 4, the crystalline portions of the semiconductor layer stack 202 are not uniform throughout the semiconductor layer stack 202. For example, the amorphous portion 216 of the second sub-layer 212 extends upwards into the crystalline portion 218 of the second sub-layer 212. The semiconductor layer stack 202 has a much larger volume of amorphous material near the bottom of the semiconductor layer stack 202 than near the top of the semiconductor layer stack 202. As a result, the semiconductor layer stack 202 is not uniformly crystallized and may have a crystalline fraction that varies more than 15% throughout the thickness of the semiconductor layer stack 202. For example, the crystalline fraction of the semiconductor layer stack 202 in areas near the top electrode 208 may vary from the crystalline fraction of the semiconductor layer stack 202 in areas near the bottom electrode 206 by more than 15%.

FIG. 5 is a schematic diagram of a cross-sectional view of a portion of a PV cell 240 with a semiconductor layer stack 242 that is deposited in an amorphous state and then crystallized in accordance with one or more embodiments. The PV cell 240 includes a substrate 244, a bottom electrode 246, the semiconductor layer stack 242, and a top electrode 248. The substrate 244, bottom electrode 246, semiconductor layer stack 242, and top electrode 248 may be similar to the substrate 112, bottom electrode 114, semiconductor layer stack 116 and top electrode 118 of the PV cell 102 (shown in FIG. 1). The semiconductor layer stack 242 includes first, second and third sub-layers 250, 252, 254. The first, second and third sub-layers 250, 252, 254 of the PV cell 240 may be similar to the first, second and third sub-layers 148, 150, 152. One or more of the first, second and third sub-layers 250, 252, 254 may be deposited in an amorphous state and then crystallized in accordance with one or more embodiments, as described below.

In some embodiments, one or more of the first, second and third sub-layers 250, 252, 254 include polycrystalline semiconductor material with crystalline grains having an average diameter of at least approximately 1 to 5 micrometers. One or more grain boundaries 256 may be located between adjacent crystalline grains. As shown in FIG. 5, the first, second and third sub-layers 250, 252, 254 are crystallized so that substantially all of the first, second and third sub-layers 250, 252, 254 is polycrystalline. As a result, the crystalline portion of the first, second and third sub-layers 250, 252, 254 is uniformly distributed throughout the thickness of the semiconductor layer stack 242. The crystalline portion of one or more of the first, second and third sub-layers 250, 252, 254 thus does not vary by more than approximately 15%, by more than approximately 10% or by more than approximately 5% throughout the thickness of the semiconductor layer stack 242 or through one or more of the first, second and third sub-layers 250, 252, 254.

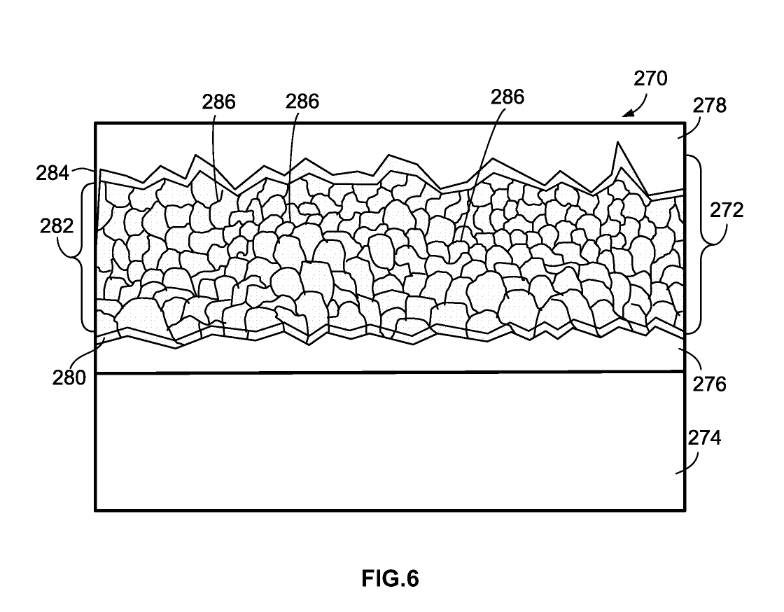

FIG. 6 is a schematic diagram of a cross-sectional view of a portion of a PV cell 270 with a semiconductor layer stack 272 that is deposited in an amorphous state and then crystallized in accordance with another embodiment. The PV cell 270 includes a substrate 274, a bottom electrode 276, the semiconductor layer stack 272, and a top electrode 278. The substrate 274, bottom electrode 276, semiconductor layer stack 272, and top electrode 278 may be similar to the substrate 112, bottom electrode 114, semiconductor layer stack 116 and top electrode 118 of the PV cell 102 (shown in FIG. 1). The semiconductor layer stack 272 includes first, second and third sub-layers 280, 282, 284. The first, second and third sub-layers 280, 282, 284 of the PV cell 270 may be similar to the first, second and third sub-layers 148, 150, 152. One or more of the first, second and third sub-layers 280, 282, 284 may be deposited in an amorphous state and then crystallized in accordance with one or more embodiments, as described below.

In some embodiments, the first, second and third sub-layers 280, 282, 284 include polycrystalline semiconductor material with crystalline grains having an average diameter of at least approximately 100 to 500 nanometers. One or more grain boundaries 286 may be located between adjacent crystalline grains. As shown in FIG. 6, the first, second and third sub-layers 280, 282, 284 are crystallized so that substantially all of the first, second and third sub-layers 280, 282, 284. As a result, the crystalline portion of the first, second and third sub-layers 280, 282, 284 is uniformly distributed throughout the thickness of the semiconductor layer stack 272. The crystalline portion of the first, second and third sub-layers 280, 282, 284 thus does not vary by more than approximately 15%, by more than approximately 10% or by more than approximately 5% throughout the thickness of the semiconductor layer stack 272.

The uniformity of the crystalline material in the semiconductor layer stack 116 (shown in FIGS. 1 and 2) may be measured in a variety of methods. In one example, the uniformity of the crystalline fraction throughout the thickness of the semiconductor layer stack 116 may be measured by determining the crystalline fraction of the semiconductor layer stack 116 at a plurality of depths in the thickness of the semiconductor layer stack 116. This same method may be used to calculate the uniformity of the crystalline fraction throughout the thickness of one or more of the sub-layers 148, 150, 152 in the semiconductor layer stack 116.

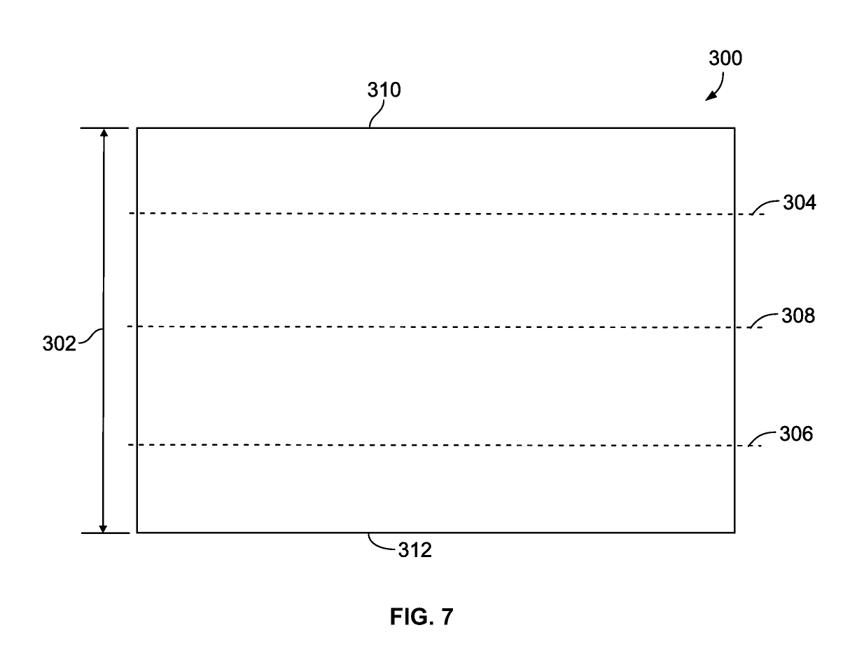

FIG. 7 is a schematic view of a layer 520 with the crystalline fraction of the layer 520 measured at a plurality of depths 304, 306. The layer 520 may represent the semiconductor layer stack 116 of the PV cell 102 (shown in FIG. 2). Alternatively, the layer 520 may represent any of the first, second and third sub-layers 148, 150, 152 (shown in FIG. 2) of the semiconductor layer stack 116. In another example, the layer 520 may represent a combination of two or more of the first, second and third sub-layers 148, 150, 152.

The layer 520 has a thickness 302. The thickness 302 may be the same as the thickness of the semiconductor layer stack 116, any of the first, second and third sub-layers 148, 150, 152, or the total thickness of a combination of two or more of the first, second and third sub-layers 148, 150, 152. The uniformity of the crystalline fraction throughout the layer 520 may be measured by measuring the crystalline fraction of the layer 520 at a plurality of depths 304, 306, 308. In one example, the crystalline fraction of the layer 520 is measured at a first depth 304 and a second depth 306. The first depth 304 may be approximately 25% of the thickness 302. For example, the first depth 304 may be located at a distance that is 25% of the thickness 302 away from a top surface 310 of the layer 520. The second depth 306 may be approximately 75% of the thickness 302. For example, the second depth 306 may be located at a distance that is 75% of the thickness 302 away from the top surface 310 of the layer 520, or 25% of the thickness 302 away from a bottom surface 312 of the layer 520. The first and second depths 304, 306 may be located at other distances away from the top and bottom surfaces 310, 312. For example, the first depth 304 may be a distance that is 10% of the thickness 302 away from the top surface 310 and the second depth 306 may be a distance that is 10% of the thickness 302 away from the bottom surface 312.

The crystalline fraction of the layer 520 may be measured at the depths 304, 306 by obtaining samples of the layer 520 at the depths 304, 306 and then measuring the crystalline fraction of the samples using TEM or Raman scattering, as described above. Using TEM or Raman scattering, the percentage of crystalline material in each sample can be calculated. Alternatively, additional samples of the layer 520 may be obtained at other depths. For example, an additional sample of the layer 520 may be obtained from a depth 308. The crystalline fraction of the sample from the layer 520 at the depth 308 is then compared to the crystalline fraction of other samples from the layer 520. In another embodiment, the samples of the layer 520 are obtained at regular, increasing depths of the thickness 302 of the layer 520. For example, a sample may be obtained at depths of 10%, 20%, 30%, and so on, of the thickness 302 of the layer 520. These samples can then be analyzed using TEM or Raman scattering, for example, to calculate the crystalline fraction in each sample. The crystalline fraction of the various samples can then be compared with each other to determine if the crystalline fraction of the layer 520 varies throughout the thickness 302 of the layer 520. In some embodiments, the layer 520 has a uniformly distributed crystalline portion if the crystalline fraction of the samples does not vary more than approximately 15% across the samples. In another embodiment, the layer 520 has a uniformly distributed crystalline portion if the crystalline fraction of the samples does not change more than approximately 10% across the samples. In another embodiment, the layer 520 has a uniformly distributed crystalline portion if the crystalline fraction of the samples does not change more than approximately 5% across the samples.

Returning to FIG. 2 and the structure of the PV cell 102, the top electrode 118 is deposited above the semiconductor layer stack 116. For example, the top electrode 118 may be deposited directly on the semiconductor layer stack 116. In one embodiment, the top electrode 118 includes, or is formed from, a conductive and light transmissive material, or a transparent or translucent material capable of conducting electricity. For example, the top electrode 118 may be formed from a transparent conductive oxide. Examples of such materials include zinc oxide (ZnO), tin oxide (SnO₂), fluorine doped tin oxide (SnO₂:F), ITO, titanium dioxide (TiO₂), and/or aluminum-doped zinc oxide (Al:ZnO).

The top electrode 118 can be deposited in a variety of thicknesses. In some embodiments, the top electrode 118 is deposited in a thickness that is less than the substrate 112 and/or the semiconductor layer stack 116 but greater than the barrier layer 140 and/or the bottom adhesive layer 142. For example, the top electrode 118 can be approximately 250 nanometers to 2 micrometers thick. In some embodiments, the top electrode 118 is approximately 1 micrometer thick. The thickness of the top electrode 118 may be varied from these embodiments. For example, a variance of +/−10% or less of the thickness of the top electrode 118 in these embodiments may be acceptable.

In some embodiments, the top adhesive 120 is deposited on the top electrode 118. For example, the top adhesive 120 may be deposited directly on the top electrode 118. Alternatively, the top adhesive 120 is omitted from the PV cell 102. The top adhesive 120 can be provided to assist with adhering the top electrode 118 to the cover sheet 122. The top adhesive 120 may prevent moisture ingress into the layers of the PV cell 102 from one or more edges of the PV device 100 (shown in FIG. 1). The top adhesive 120 may include a material such as a polyvinyl butyral (“PVB”), surlyn, or ethylene-vinyl acetate (“EVA”) copolymer, for example.

The cover sheet 122 may be provided on the top adhesive 120. For example, the cover sheet 122 may be provided directly on top of the top adhesive 120. In embodiments where the top adhesive 120 is omitted from the PV cell 102, the cover sheet 122 is placed on the top electrode 118. The cover sheet 122 includes or is formed from a light transmissive material, or a transparent or translucent material such as glass. For example, the cover sheet 122 can include soda-lime glass, low-iron tempered glass, or low-iron annealed glass. In some embodiments, the cover sheet 122 is formed from or includes tempered glass. The use of tempered glass in the cover sheet 122 may help to protect the PV device 100 from physical damage. For example, a tempered glass cover sheet 122 may help protect the PV device 100 from hailstones and other environmental damage. The cover sheet 122 can be provided in a variety of thicknesses. By way of example only, the cover sheet 122 can be approximately 1 to 5 millimeters thick. In another example, the cover sheet 122 may be approximately 3 to 3.3 millimeters thick. The thickness of the cover sheet 122 may be varied from these embodiments. For example, a variance of +/−10% or less of the thickness of the cover sheet 122 in these embodiments may be acceptable.

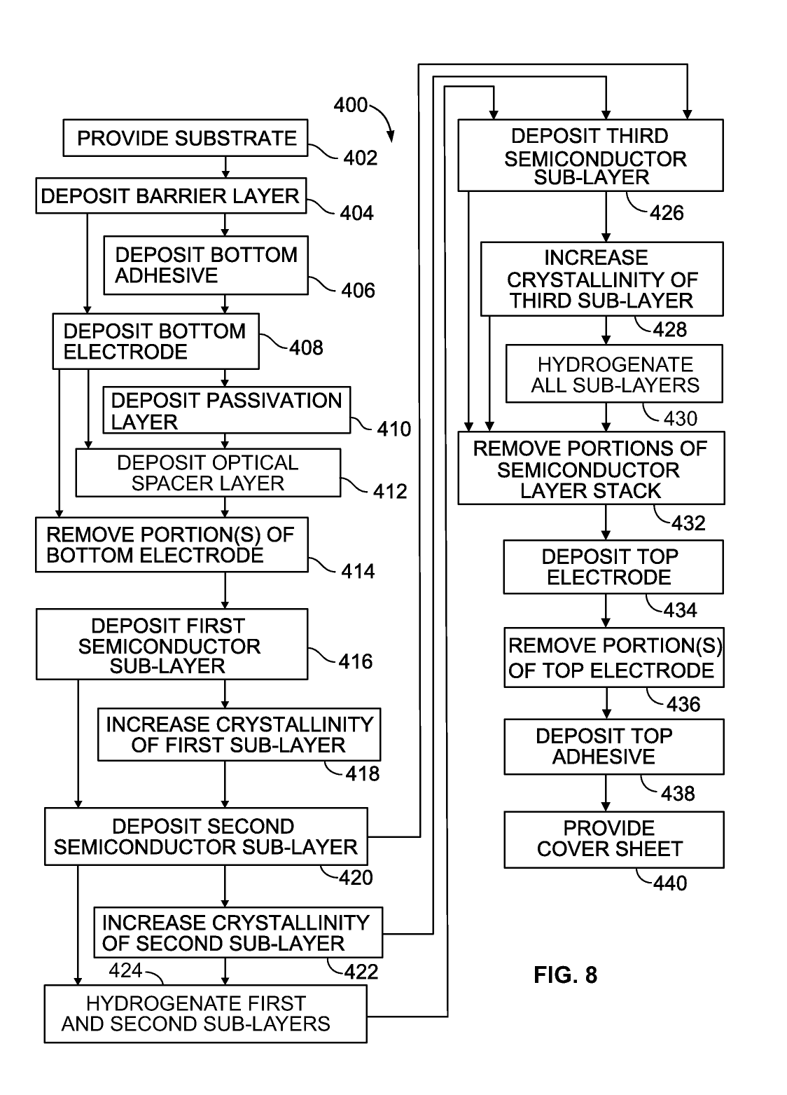

FIG. 8 is a flowchart of a method 400 for manufacturing the PV device 100 shown in FIG. 1. At block 402, a substrate is provided. For example, the substrate 112 can be provided. At block 404, a barrier layer is deposited on the substrate. For example, the barrier layer 140 can be deposited on the substrate 112. The barrier layer can be deposited by sputtering the material of the barrier layer onto the substrate, for example. Other methods of depositing the barrier layer include but are not limited to chemical vapor deposition (“CVD”), low pressure CVD, metal-organic CVD, PECVD, or hot wire CVD. In some embodiments, the method 400 proceeds between blocks 404, 406 and 408. In another embodiment, the method 400 proceeds between block 404 and block 408.

At block 406, an adhesive layer is deposited on the barrier layer. For example, the bottom adhesive layer 142 can be deposited adjacent to the barrier layer 140. The bottom adhesive layer can be deposited by sputtering the material of the bottom adhesive onto the barrier layer, for example. Other methods of depositing the bottom adhesive layer include but are not limited to CVD, low pressure CVD, metal-organic CVD, PECVD, or hot wire CVD. At block 408, a bottom electrode is deposited on the bottom adhesive layer. For example, the bottom electrode 114 may be deposited on the bottom adhesive layer 142. The bottom adhesive layer can be deposited by sputtering the material of the bottom electrode, for example. Other methods of depositing the bottom electrode include but are not limited to CVD, low pressure CVD, metal-organic CVD, PECVD, or hot wire CVD. In some embodiments, the bottom electrode is deposited at an elevated temperature to roughen the surface of the bottom electrode. For example, the bottom electrode can be deposited at a temperature between 200 to 400 degrees Celsius in order to roughen the surface of the bottom electrode.

In some embodiments, the method 400 proceeds between blocks 408, 410, 412 and 414. In another embodiment, the method 600 proceeds between blocks 408, 412 and 414. In another embodiment, the method 600 proceeds between blocks 410 and 414. At block 410, a passivation layer is deposited on the bottom electrode. For example, the passivation layer 144 can be sputtered on the bottom electrode 114. Other methods of depositing the passivation layer 144 include but are not limited to CVD, low pressure CVD, metal-organic CVD, PECVD, or hot wire CVD. At block 412, an optical spacer layer is deposited on the bottom electrode. For example, the optical spacer layer 146 can be deposited on the bottom electrode 114 by sputtering the material of the optical spacer layer 146 on the bottom electrode 114, for example. Other methods of depositing the optical spacer layer include but are not limited to CVD, low pressure CVD, metal-organic CVD, PECVD, or hot wire CVD. At block 414, one or more portions of the bottom electrode is removed. In some embodiments, one or more portions of the optical spacer layer deposited at block 412, the passivation layer deposited at block 410, and/or the barrier layer deposited at block 404 also are removed at block 414. The portions of the bottom electrode, optical spacer layer, passivation layer, and/or barrier layer are removed using laser or mechanical scribing in some embodiments. The portions that are removed may be linear strips that extend between the opposing ends 128, 130 (shown in FIG. 1) of the PV device 100. Once these portions of the bottom electrode are removed from the PV cell 102, the remaining portions of the bottom electrode also may extend in linear strips between the opposing ends 128, 130 of the PV device 100. In some embodiments, the removal of the bottom electrode in this manner causes the remaining strips of the bottom electrode to be electrically isolated from one another.

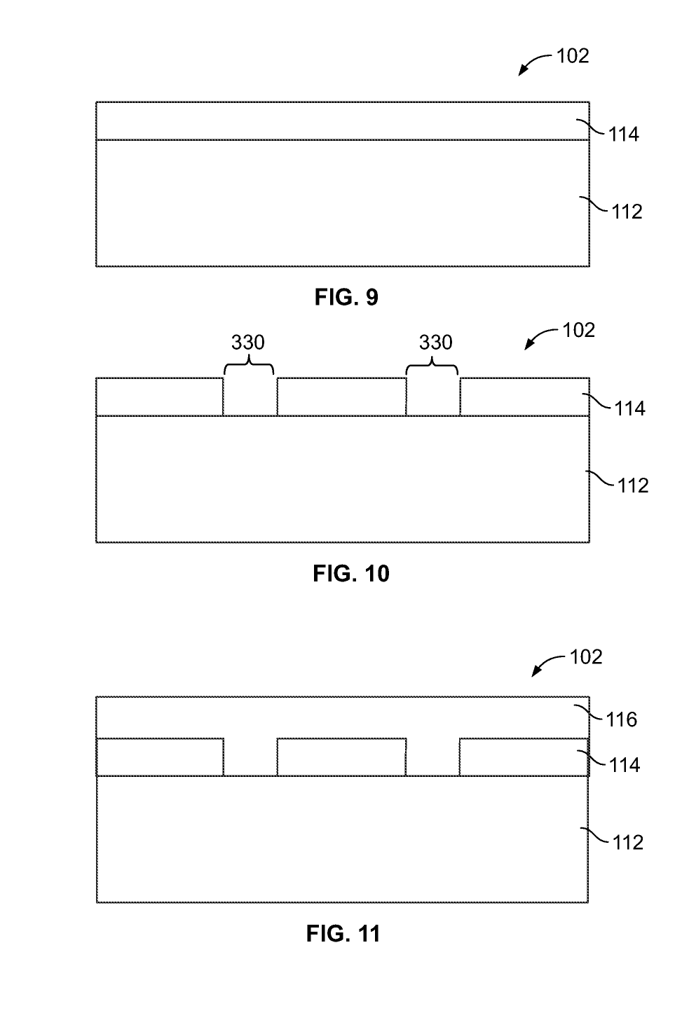

FIG. 9 is a schematic cross-sectional view of the PV cell 102 before block 414 of the method 400 according to some embodiments. Although not shown in FIGS. 9 through 16, the barrier layer 140 and the bottom adhesive layer 142 may be located between the substrate 112 and the bottom electrode 114, and the passivation layer 144 and the optical spacer layer 146 may be on top of the bottom electrode 114, as shown in FIG. 2. Prior to block 414, the barrier layer 140, bottom adhesive layer 142, bottom electrode 114, passivation layer 144 and the optical spacer layer 146 may extend over all or substantially all of the substrate 112, for example.

FIG. 10 is a schematic cross-sectional view of the PV cell 102 after block 414 of the method 400 according to some embodiments. At block 414, the optical spacer layer 146, passivation layer 144, bottom electrode 114, and the bottom adhesive layer 142 may be removed in first areas 330 to expose corresponding areas of the substrate 112 and the barrier layer 140. In another embodiment, the barrier layer 140 also is removed in the first areas 330. The first areas 330 may extend between opposing ends 128, 130 of the PV device 100 (shown in FIG. 1). Returning to FIG. 8, a semiconductor layer stack is deposited above the bottom electrode at blocks 416 through 426. For example, the semiconductor layer stack 116 may be deposited on the existing layers of the PV cell 102 after block 414.

FIG. 11 is a schematic cross-sectional view of the PV cell 102 following blocks 416 through 426 of the method 400 according to some embodiments. As shown in FIG. 11, the semiconductor layer stack 116 is deposited so as to cover the bottom electrode 114 and to fill the gaps in the first areas 330 shown in FIG. 10. In embodiments where the optical spacer layer 146 is not removed from the bottom electrode 114, the semiconductor layer stack 116 is deposited on the optical spacer layer 146. In embodiments where the barrier layer 140 is not removed in the first areas 330, the semiconductor layer stack 116 is deposited on the barrier layer 140 in the first areas 330.

Returning to FIG. 8, at block 416 a first semiconductor sub-layer is deposited. For example, the first semiconductor sub-layer 148 may be deposited on the existing layers of the PV cell 102. The first semiconductor sub-layer may be deposited using a method such as PECVD, for example. In some embodiments, the first semiconductor sub-layer is deposited in an amorphous state. In another embodiment, the first semiconductor sub-layer is deposited in a microcrystalline state. In a third embodiment, the first semiconductor sub-layer is deposited in a transition region of growth between amorphous and microcrystalline silicon such that the density of grains is reduced but nonzero.

The method 400 next proceeds between block 416 and block 418, and between block 418 and block 420. In another embodiment, the method 400 proceeds between block 416 and block 420. At block 418, a level of crystallinity in the first semiconductor sub-layer is increased. For example, the level of crystallinity in the first semiconductor sub-layer 148 can be increased by increasing the average crystalline grain size in the sub-layer 148, by increasing the crystalline fraction in the sub-layer 148, and/or by increasing the uniformity of the crystalline grain distribution in the sub-layer 148. In some embodiments, the level of crystallinity in the first semiconductor sub-layer is increased while keeping the first semiconductor sub-layer in the solid state. For example, the first semiconductor sub-layer 148 may be exposed to electron beams (“e-beams”) so that the temperature of the sub-layer 148 increases enough to cause crystallization of the sub-layer 148 but low enough to avoid melting the sub-layer 148. Alternatively, instead of exposing the first semiconductor sub-layer 148 to e-beams, the first semiconductor sub-layer 148 can be crystallized by heating the first semiconductor sub-layer 148 with a focused continuous wave (“CW”) line-shaped laser beam, for example. In another alternative embodiment, the first semiconductor sub-layer 148 may be crystallized by rapidly heating the first semiconductor sub-layer 148 in a flash anneal system.

At block 420, a second semiconductor sub-layer is deposited on the first semiconductor sub-layer. For example, the second semiconductor sub-layer 150 can be directly deposited on the first semiconductor sub-layer 148. The second semiconductor sub-layer 150 can be deposited using a method such as PECVD. In an embodiment, the second semiconductor sub-layer 150 is deposited in an amorphous state. In another embodiment, the second semiconductor sub-layer 150 is deposited in a microcrystalline state. In a third embodiment, the second semiconductor sub-layer is deposited in a transition region of growth between amorphous and microcrystalline silicon such that the density of microcrystalline grains is minimized but nonzero.

In some embodiments, the method 400 proceeds between blocks 420, 422, 424 and 426. In another embodiment, the method 400 proceeds between blocks 420, 424 and 426. In another embodiment, the method 400 proceeds between blocks 420 and 426. At block 422, a level of crystallinity in the second semiconductor sub-layer is increased. For example, the level of crystallinity in the second semiconductor sub-layer 150 can be increased by increasing the average crystalline grain size in the second semiconductor sub-layer 150, by increasing the crystalline fraction in the second semiconductor sub-layer 150, and/or by increasing the uniformity of the crystalline grain distribution in the second semiconductor sub-layer 150. In another embodiment, a level of crystallinity in the first and second semiconductor sub-layers is increased at block 422. For example, the level of crystallinity in the first and second semiconductor sub-layers 148, 150 can be increased by increasing the average crystalline grain size in the first and second semiconductor sub-layers 148, 150, by increasing the crystalline fraction in the first and second semiconductor sub-layers 148, 150, and/or by increasing the uniformity of the crystalline grain distribution in the first and second semiconductor sub-layers 148, 150. As described above, in order to increase the level of crystallinity of the second semiconductor sub-layer, or the first and second semiconductor sub-layers, the sub-layer(s) may be exposed to a focused line-shaped e-beam. In some embodiments, the level of crystallinity in the sub-layers is increased by exposing the second semiconductor sub-layer 150, or the first and second semiconductor sub-layers 148, 150, to e-beams without melting or liquefying the semiconductor material in the sub-layers. For example, the level of crystallinity in the second semiconductor sub-layer 150, or the first and second semiconductor sub-layers 148, 150, may be increased while the second semiconductor sub-layer 150, or the first and second semiconductor sub-layers 148, 150, remains in the solid state.

By crystallizing the second semiconductor sub-layer 150, or the first and second semiconductor sub-layers 148, 150, in the solid state, a dopant junction between the first and second semiconductor sub-layers 148, 150 may be maintained. For example, in one embodiment, crystallizing the second semiconductor sub-layer 150, or the first and second semiconductor sub-layers 148, 150, in the solid state prevents dopants in the first sub-layer 148 from diffusing more than approximately 250 nanometers across the dopant junction at the interface 154. In another embodiment, the dopants do not diffuse across the junction by more than approximately 100 nanometers. In another embodiment, the dopants do not diffuse across the junction by more than approximately 50 nanometers. In another embodiment, the dopants do not diffuse across the junction by more than approximately 25 nanometers.

In another embodiment, crystallizing the second semiconductor sub-layer 150, or the first and second semiconductor sub-layers 148, 150, in the solid state prevents the junction diffusion width 182 (shown in FIG. 3) between the first and second semiconductor sub-layers 148, 150 from increasing by more than approximately 250 nanometers. In another embodiment, the junction diffusion width 182 does not increase by more than approximately 100 nanometers. In another embodiment, the junction diffusion width 182 does not increase by more than approximately 50 nanometers. In another embodiment, the junction diffusion width 182 does not increase by more than approximately 25 nanometers.

Alternatively, instead of exposing the second semiconductor sub-layer 150, or the first and second semiconductor sub-layers 148, 150, to e-beams, the second semiconductor sub-layer 150, or the first and second semiconductor sub-layers 148, 150, can be crystallized by heating the second semiconductor sub-layer 150, or the first and second semiconductor sub-layers 148, 150, using a focused CW line-shaped laser beam, as described above. Alternatively, the second semiconductor sub-layer 150, or the first and second semiconductor sub-layers 148, 150, may be exposed to a CW laser beam that is rapidly scanned across the first and second sub-layers 148, 150. The laser beam may have a wavelength that is approximately the same as the absorption coefficient of the semiconductor material in the sub-layers 148, 150.

In another alternative embodiment, the second semiconductor sub-layer 150, or the first and second semiconductor sub-layers 148, 150, is rapidly heated in a flash anneal system, as described above. In some embodiments, the dwell time is short enough to avoid melting the first and second semiconductor sub-layers 148, 150. For example, the dwell time may be 10 seconds or less.

Instead of crystallizing the second semiconductor sub-layer 150 in the solid state, the sub-layers 148, 150 may be heated so that the second sub-layer 150 melts and solidifies in another embodiment. For example, the first and second semiconductor sub-layers 148, 150 may be heated to a sufficiently high temperature so that the second sub-layer 150 melts and crystallizes upon solidification. In such an embodiment, the first semiconductor sub-layer 148 may include or be formed of silicon carbide, non-stoichiometric silicon carbide, doped silicon carbide, or unintentionally doped or intrinsic silicon carbide. Such materials may have a sufficiently high melting temperature that the first semiconductor sub-layer 148 does not melt when the second semiconductor sub-layer 150 is heated at block 422.

The second semiconductor sub-layer 150 may be melted by heating the second semiconductor sub-layer 150 with e-beams, CW laser beams or a flash anneal system for a sufficiently long dwell time so as to melt the sub-layer 150. For example, the second semiconductor sub-layer 150 may be heated with e-beams, laser beams or a flash anneal system for at least approximately 100 nanoseconds. In another embodiment, the second semiconductor sub-layer 150 is heated for approximately 100 nanoseconds to approximately 100 milliseconds.

In some embodiments, the first and second semiconductor sub-layers 148, 150 are heated to a temperature of at least approximately 1300 degrees Celsius. In another embodiment, the first and second semiconductor sub-layers 148, 150 are heated to a temperature between approximately 1300 and 1600 degrees Celsius. At such temperatures, the second semiconductor sub-layer 150 may melt. If the first semiconductor sub-layer 148 includes or is formed of silicon carbide, non-stoichiometric silicon carbide, doped silicon carbide, or unintentionally doped or intrinsic silicon carbide, then the first semiconductor sub-layer 148 may not melt. By including a silicon carbide layer as the first semiconductor sub-layer 148 and crystallizing the second semiconductor sub-layer 150 by melting the sub-layer 150, a dopant junction between the first and second sub-layers 148, 150 may be maintained, as described above.

For example, by melting the second semiconductor sub-layer 150 while keeping the first semiconductor sub-layer 148 in the solid state during crystallization of the second semiconductor sub-layer 150, a dopant junction between the first and second semiconductor sub-layers 148, 150 may be maintained, as described above. In some embodiments, melting the second semiconductor sub-layer 150 while keeping the first semiconductor sub-layer 148 in the solid state prevents dopants in the first sub-layer 148 from diffusing more than approximately 250 nanometers across the dopant junction, also as described above. In another embodiment, the dopants do not diffuse across the junction by more than approximately 100 nanometers. In another embodiment, the dopants do not diffuse across the junction by more than approximately 50 nanometers. In another embodiment, the dopants do not diffuse across the junction by more than approximately 25 nanometers.

In another embodiment, melting the second semiconductor sub-layer 150 while keeping the first semiconductor sub-layer 148 in the solid state prevents the junction diffusion width 182 (shown in FIG. 3) between the first and second semiconductor sub-layers 148, 150 from increasing by more than approximately 250 nanometers. In another embodiment, the junction diffusion width 182 does not increase by more than approximately 100 nanometers. In another embodiment, the junction diffusion width 182 does not increase by more than approximately 50 nanometers. In another embodiment, the junction diffusion width 182 does not increase by more than approximately 25 nanometers.

At block 424, the first and second semiconductor sub-layers are hydrogenated. For example, the first and second semiconductor sub-layers 148, 150 may be exposed to an atomic source of hydrogen. The sub-layers 148, 150 may be exposed to the hydrogen in the same chamber that the sub-layers 148, 150 are exposed to e-beams at block 418, for example. Alternatively, the sub-layers 148, 150 may be exposed to the hydrogen in a secondary chamber that is connected to the e-beam chamber without a vacuum break between the two chambers. The source of hydrogen may be a hydrogen plasma, for example. In some embodiments, the atomic hydrogen is generated from H₂ by exposing the H₂ to a remote plasma source. The hydrogen may be applied to the first and second sub-layers 148, 150 by placing the sub-layers 148, 150 (and the layers between the sub-layers 148, 150 and the substrate 112) into a chamber, generating a vacuum in the chamber, and then opening the chamber to the hydrogen and flooding the chamber with the hydrogen. The vacuum may be established in the chamber by lowering the pressure in the chamber to approximately 10⁻³ ton or less. The hydrogen may be added to the chamber until the pressure in the chamber increases to approximately 0.1 to 10 ton. Alternatively, the hydrogen may be applied to the first and second sub-layers 148, 150 by distributing the hydrogen onto the sub-layers 148, 150 through a diffusing apparatus. The flow rate for the hydrogen may be related to the total surface area of the substrate 112 that supports the first and second sub-layers 148, 150. For example, as the total surface area of the substrate 112 increases, the flow rate for the hydrogen may increase a proportional amount. In some embodiments, the flow rate is approximately 2000 to 5200 standard cubic centimeters per minute (“sccm”) for a substrate 112 that is 55 centimeters by 65 centimeters. In some embodiments, the first and second sub-layers 148, 150 are heated when exposed to the hydrogen. For example, the sub-layers 148, 150 may be heated to a temperature of approximately 250 to 600 degrees Celsius. In another example, the sub-layers 148, 150 may be heated to approximately 400 to 450 degrees Celsius.

At block 426, a third semiconductor sub-layer is provided. For example, the sub-layer 152 can be deposited directly on the second sub-layer 150. The third semiconductor sub-layer may be deposited using a method such as PECVD, for example. In some embodiments, the third semiconductor sub-layer is deposited in an amorphous state. In another embodiment, the third semiconductor sub-layer is deposited in a microcrystalline state. In a third embodiment, the third semiconductor sub-layer is deposited in a transition region of growth between amorphous and microcrystalline silicon such that the density of grains is minimized but nonzero.

In some embodiments, the method 400 proceeds between blocks 426, 428, 430 and 432. In another embodiment, the method 400 proceeds between blocks 426, 428 and 432. In another embodiment, the method 400 proceeds between blocks 426 and 432. At block 428, a level of crystallinity in the third semiconductor sub-layer is increased. Alternatively, a level of crystallinity is increased in the first, second and/or third semiconductor sub-layers. For example, the level of crystallinity in the first, second and third sub-layers 148, 150, 152 may be increased using one or more embodiments described above. As described above, the level of crystallinity in the sub-layers 148, 150, 152 may be increased while maintaining the sub-layers 148, 150, 152 in the solid state. The level of crystallinity in the first, second and/or third sub-layers 148, 150, 152 may be increased by increasing the average crystalline grain size in the first, second and/or third sub-layers 148, 150, 152, by increasing the crystalline fraction in the first, second and/or third sub-layers 148, 150, 152, and/or by increasing the uniformity of the crystalline grain distribution in the first, second and/or third sub-layers 148, 150, 152, for example. In one embodiment, the method 400 does not include block 428 when the first and second semiconductor sub-layers are crystallized at block 418 and/or 422. For example, where the first and second semiconductor sub-layers 148, 150 already have been crystallized, the third semiconductor sub-layer 152 is not crystallized. By crystallizing the sub-layers 148, 150 and/or 152 in the solid state, a dopant junction between the first and second sub-layers 148, 150 may be maintained, as described above. Additionally, a dopant junction between the second and third sub-layers 150, 152 may be maintained. Crystallizing the first, second and/or third sub-layers 148, 150, 152 in the solid state also may prevent the junction diffusion width 182 (shown in FIG. 3) between the first and second sub-layers 148, 150 and/or between the second and third sub-layers 150, 152 from increasing by more than approximately 250 nanometers. In another embodiment, the junction widths 182 do not increase by more than approximately 100 nanometers. In another embodiment, the junction widths 182 do not increase by more than approximately 50 nanometers. In another embodiment, the junction widths 182 do not increase by more than approximately 25 nanometers.

At block 430, the first, second and third semiconductor sub-layers are hydrogenated. For example, the first, second and third semiconductor sub-layers 148, 150, 152 may be exposed to a source of hydrogen as described above at block 424, while also exposing the third sub-layer 152 to the hydrogen. At block 432, one or more portions of the semiconductor layer stack is removed to expose corresponding areas of the bottom electrode. In some embodiments, one or more corresponding portions of the optical spacer layer and/or passivation layer also are removed at block 432. For example, the semiconductor layer stack 116, the optical spacer layer 146, and the passivation layer 144 can be laser or mechanically scribed to remove these layers in selected areas. The portions that are removed may be linear strips that extend between the opposing ends 128, 130 of the PV device 100 (shown in FIG. 1). Once these portions of the layers are removed, the portions of the bottom electrode that remain also extend in linear strips that extend between the opposing ends 128, 130 of the PV device 100. The removal of the bottom electrode in this manner may cause the remaining strips of the bottom electrode to be electrically isolated from one another.

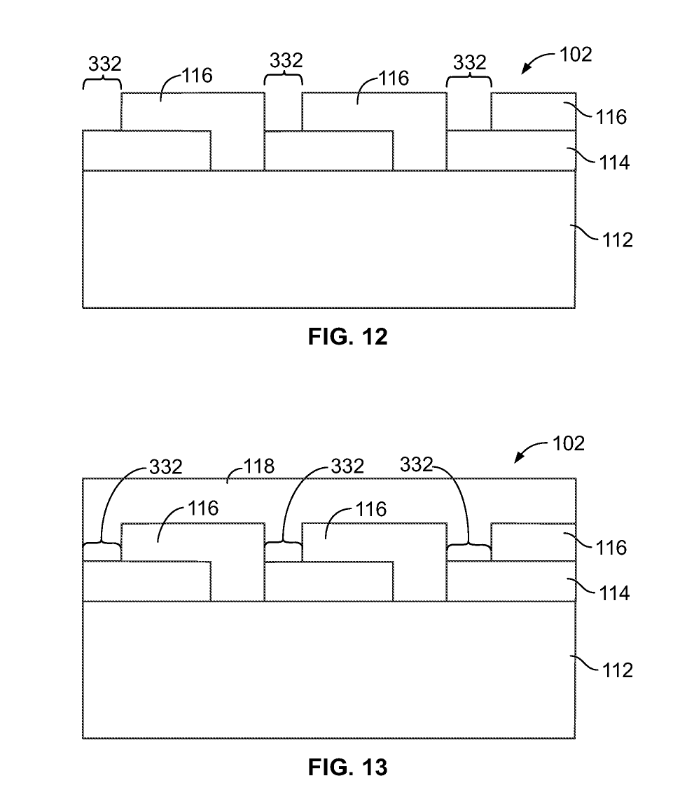

FIG. 12 is a schematic cross-sectional view of the PV cell 102 after block 460 according to some embodiments. As shown in FIG. 12, selected areas of the semiconductor layer stack 116, the optical spacer layer 146 (shown in FIG. 1), and the passivation layer 144 (shown in FIG. 1) may be removed at block 432. These layers may be removed at second areas 332. Removing these layers may expose the bottom electrode 114 at corresponding areas. The second areas 332 may extend between the opposing ends 128, 130 of the PV device (shown in FIG. 1). Removal of the semiconductor layer stack 116, the optical spacer layer 146 and the passivation layer 144 at the second areas 332 may cause the cross-section of the semiconductor layer stack 116 to have a stair-step, or “L” shape in the cross-sectional view shown in FIG. 1. Returning to FIG. 8, the method 400 proceeds between blocks 432 and 434. At block 434, the top electrode is deposited. For example, the top electrode 118 may be deposited by sputtering the material of the top electrode 118 onto the PV cell 102 after block 432. Alternatively, the top electrode can be deposited by using CVD, low pressure CVD, metal-organic CVD, PECVD, or hot wire CVD. The top electrode may be deposited on the semiconductor layer stack in the areas where the semiconductor layer stack was not removed at block 432. The top electrode also may be deposited on the optical spacer layer in the areas where the semiconductor layer stack was removed at block 432. The top electrode may be electrically connected to the bottom electrode after block 434.

FIG. 13 is a schematic cross-sectional view of the PV cell 102 after block 434 according to some embodiments. As shown in FIG. 13, the top electrode 118 is deposited on the optical spacer layer 146 (shown in FIG. 2) in the second areas 332 where the semiconductor layer stack 116 was removed at block 432. The top electrode 118 also is deposited on the semiconductor layer stack 116 in the areas where the semiconductor layer stack 116 was not removed at block 432. In some embodiments, the top electrode 118 and bottom electrode 114 are electrically connected in the second areas 332.

Returning to FIG. 8, at block 436, one or more portions of the top electrode may be removed to expose one or more areas of the underlying semiconductor layer stack. For example, one or more portions of the top electrode 118 can be removed using laser or mechanical scribing to expose one or more areas of the semiconductor layer stack 116.

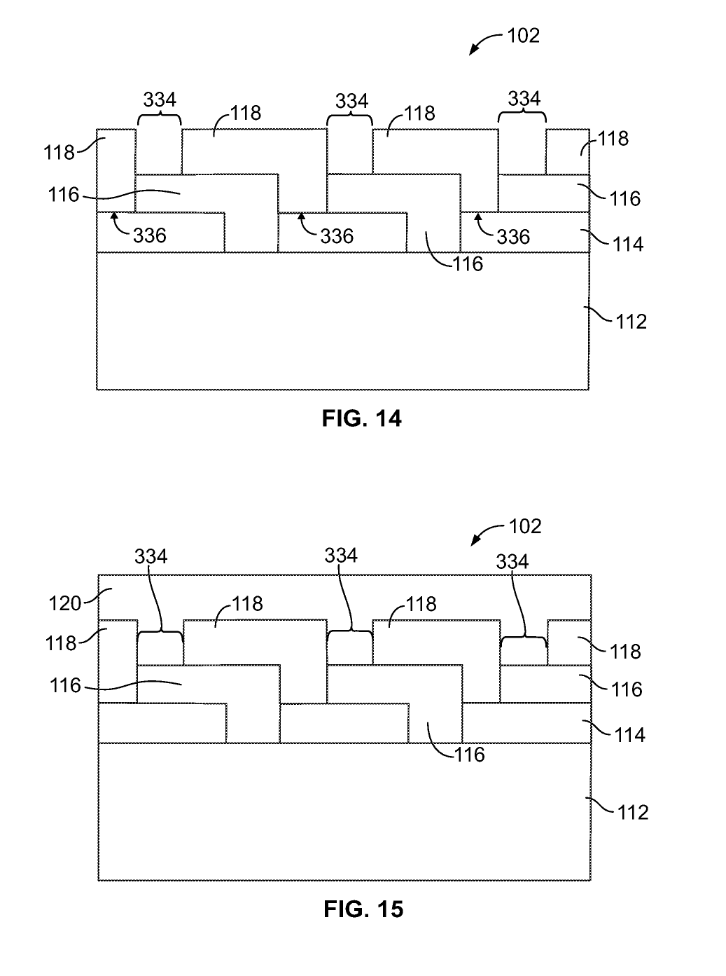

FIG. 14 is a schematic cross-sectional view of the PV cell 102 after block 436 according to some embodiments. As shown in FIG. 14, the top electrode 118 is removed at one or more areas. The areas can include a plurality of third areas 334. The third areas 334 may extend between opposing ends 128, 130 of the PV device 100 (shown in FIG. 1). In such an embodiment, the top electrode 118 extends as strips of material that extend between opposing ends 128, 130 of the PV device 100. As shown in FIG. 14, corresponding areas of the semiconductor layer stack 116 may be exposed when the top electrode 118 is removed at the third areas 334. The top electrode 118 is electrically connected to the bottom electrode 114 at a plurality of interfaces 336. The interfaces 336 may correspond to the third areas 334.

Returning to FIG. 8, the method 400 proceeds between blocks 436 and 438. At block 438 a top adhesive is deposited on the top electrode and on the semiconductor layer stack. For example, the top adhesive 120 may be deposited on the top electrode 118 in areas where the top electrode 118 is not removed at block 436. The top adhesive 120 also may be deposited on the semiconductor layer stack 116 in the third areas 334 where the top electrode 118 was removed at block 436.

FIG. 15 is a schematic cross-sectional view of the PV cell 102 after block 438 according to some embodiments. As shown in FIG. 15, the top adhesive 120 may be deposited on the top electrode 118. The top adhesive 120 also may be deposited on the semiconductor layer stack 116 in areas corresponding to the third areas 334.

Returning to FIG. 8, the method 400 proceeds between blocks 438 and 440. At block 438, a cover sheet is provided on the top adhesive. For example, the cover sheet 122 may be laminated over the top adhesive 120. The top adhesive 120 may assist in securing the cover sheet 122 to the PV device 100 (shown in FIG. 1).

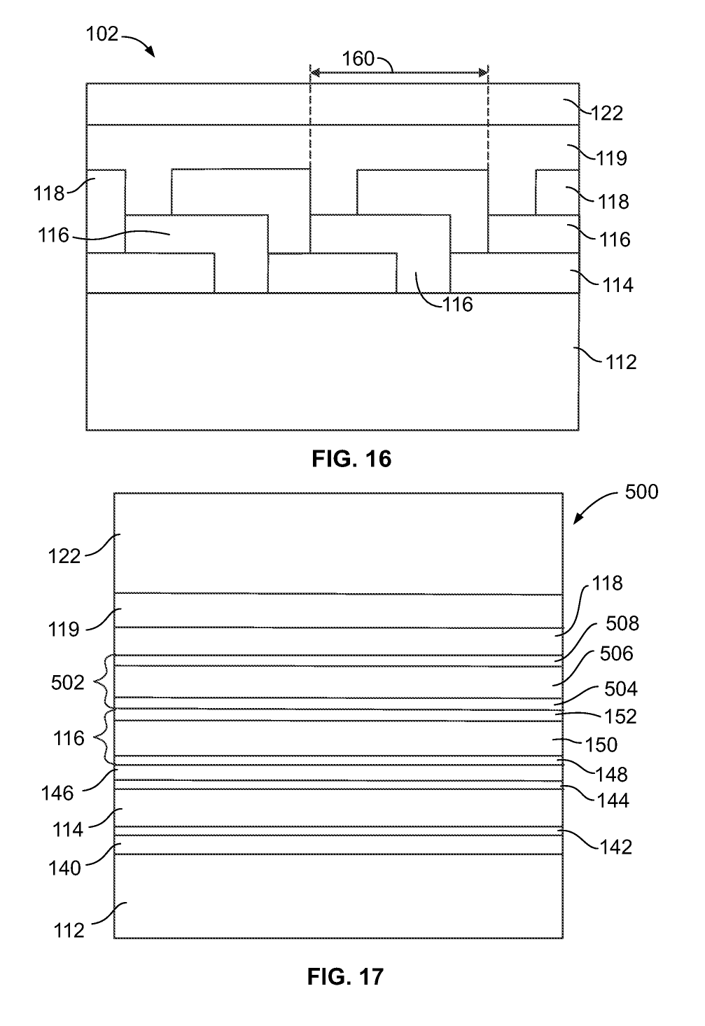

FIG. 16 is a schematic cross-sectional view of the PV cell 102 after block 440 according to some embodiments. As shown in FIG. 16, the cover sheet 122 may be placed over the top adhesive 120 to complete the manufacture of the PV cells 102. After block 440, several PV cells 102 of the PV device 100 (shown in FIG. 1) are completed. In some embodiments, the lead 104 (shown in FIG. 1) may be electrically connected to the top electrode layer 118 in the left-most PV cell 102 in the PV device 100 while the other lead 106 (shown in FIG. 1) may be electrically connected to the bottom electrode layer 114 in the right-most PV cell 102 in the PV device 100. Light that is incident on the PV cells 102 through the cover sheet 122 may be converted into electricity by the PV cells 102, as described above.

As described above, the PV cells 102 may be formed in a wide variety of embodiments using a variety of methods. In one embodiment, the PV cells 102 include soda-lime glass as the substrate 112. The barrier layer 140 is then deposited on the substrate 112. The barrier layer 140 includes an approximately 100 nanometer thick layer of Si₃N₄. An approximately 30 nanometer thick layer of NiCr is then provided on the barrier layer 140 as the bottom adhesive layer 142. The bottom electrode 114 is then provided on the bottom adhesive layer 142 and includes an approximately 150 nanometer thick layer of Ag. The use of Ag as the bottom electrode 114 may provide a reflective surface below the semiconductor layer stack 116. An approximately 1 nanometer thick layer of NiCr is provided on the bottom electrode 114 as the passivation layer 144. The optical spacer layer 146 is then provided on the bottom electrode 114 and includes an approximately 90 nanometer thick layer of Al:ZnO. After the optical spacer layer 146 is provided, the bottom electrode 114, the bottom adhesive layer 142, the passivation layer 144 and the optical spacer layer 146 may be removed using laser scribing in one or more areas to expose one or more areas of the substrate 112.

An approximately 20 nanometer thick first semiconductor sub-layer 148 is then deposited. The first sub-layer 148 includes amorphous silicon that is doped so as to be an n+ silicon material. The second sub-layer 150 is then deposited on the first sub-layer 148. The second sub-layer 150 includes an approximately 2 micrometer thick layer of intrinsic silicon. Next, the first and second sub-layers 148, 150 may be crystallized in the solid state and then hydrogenated. The third sub-layer 152 is then deposited on the second sub-layer 150. The third sub-layer 152 includes an approximately 10 nanometer thick layer of silicon. The third sub-layer 152 is deposited as a microcrystalline layer that is doped so as to be a p+ layer. Next, the semiconductor layer stack 116 is laser scribed to remove one or more areas of the semiconductor layer stack 116 and expose one or more areas of the optical spacer layer 146 and the bottom electrode 114. An approximately 1 micrometer thick layer of Al:ZnO is then provided as the top electrode 118. The top electrode 118 is then laser scribed to expose one or more areas of the semiconductor layer stack 116, as described below. The top adhesive 120 is then provided, and the cover sheet 122 is then placed on the top adhesive 120. The cover sheet 122 includes low-iron tempered glass. While the above description provides some embodiments, various other embodiments are within the scope of the presently described subject matter.

FIG. 17 is a cross-sectional schematic view of a tandem PV cell 500 in accordance with some embodiments. The tandem PV cell 500 is similar to the PV cell 102 in FIGS. 1 and 2 with the addition of a second semiconductor layer stack 502. The tandem PV cell 500 may be used in place of the PV cell 102 in the PV device 100 (shown in FIG. 1). For example, the PV device 100 may include tandem PV cells 500 instead of the PV cells 102. The second semiconductor layer stack 502 may be similar to the semiconductor layer stack 116 (shown in FIG. 2). The second semiconductor layer stack 502 includes three semiconductor sub-layers 504, 506, 508. In some embodiments, the semiconductor sub-layers 504, 506, 506 may be similar to the semiconductor sub-layers 148, 150, 152. The semiconductor sub-layers 504, 506, 506 may be deposited, doped and/or crystallized similar to the semiconductor sub-layers 148, 150, 152. For example, if the semiconductor sub-layers 148, 150, 152 are deposited, doped and/or crystallized to form an n-i-p layer stack, then the semiconductor sub-layers 504, 506, 506 may be deposited and/or doped to form an n-i-p layer stack on the semiconductor layer stack 116. In another embodiment, if the semiconductor sub-layers 148, 150, 152 are deposited, doped and crystallized for form an n+-i-p+ layer stack, then the semiconductor sub-layers 504, 506, 506 may be deposited and/or doped to form an n+-i-p+ layer stack on the semiconductor layer stack 116.

In some embodiments, the first semiconductor sub-layer 504 is deposited in a thickness of approximately 10 to 30 nanometers, the second semiconductor sub-layer 506 is deposited in a thickness of approximately 200 to 400 nanometers and the third semiconductor sub-layer 508 is deposited in a thickness of approximately 5 to 20 nanometers. The semiconductor sub-layers 504, 506, 508 may be amorphous layers that are not crystallized. The semiconductor sub-layers 504, 506, 508 may be provided in order to manufacture a tandem photovoltaic cell, for example. A tandem photovoltaic module (also referred to as a cascade cell), may achieve a higher total conversion efficiency because the addition of the semiconductor sub-layers 504, 506, 508 may allow the combination of the two semiconductor layer stacks 116, 502 to capture a larger portion of the energy of the light emitted by the sun. If the semiconductor layer stack 502 is amorphous, the semiconductor sub-layers 504, 506, 508 of the semiconductor layer stack 502 may have larger energy bandgaps when compared to the semiconductor sub-layers 148, 150, 152 of the semiconductor layer stack 116. As the light emitted by the sun strikes the tandem PV cell 500, the light first strikes the semiconductor sub-layers 504, 506, 508. The higher energy photons in the light may be absorbed first by the semiconductor sub-layers 504, 506, 508 and can be converted to a higher voltage than if the photons were absorbed by the semiconductor sub-layers 148, 150, 152. As the remaining photons pass through the semiconductor sub-layers 504, 506, 508 to the semiconductor sub-layers 148, 150, 152, the semiconductor sub-layers 148, 150, 152 absorb all or a portion of the remaining photons. The efficiency of the tandem PV cell 500 may thus be improved by providing multiple stacks of sub semiconductor sub-layers 148, 150, 152, 504, 506, 508 to absorb different energies of the photons emitted by the sun.

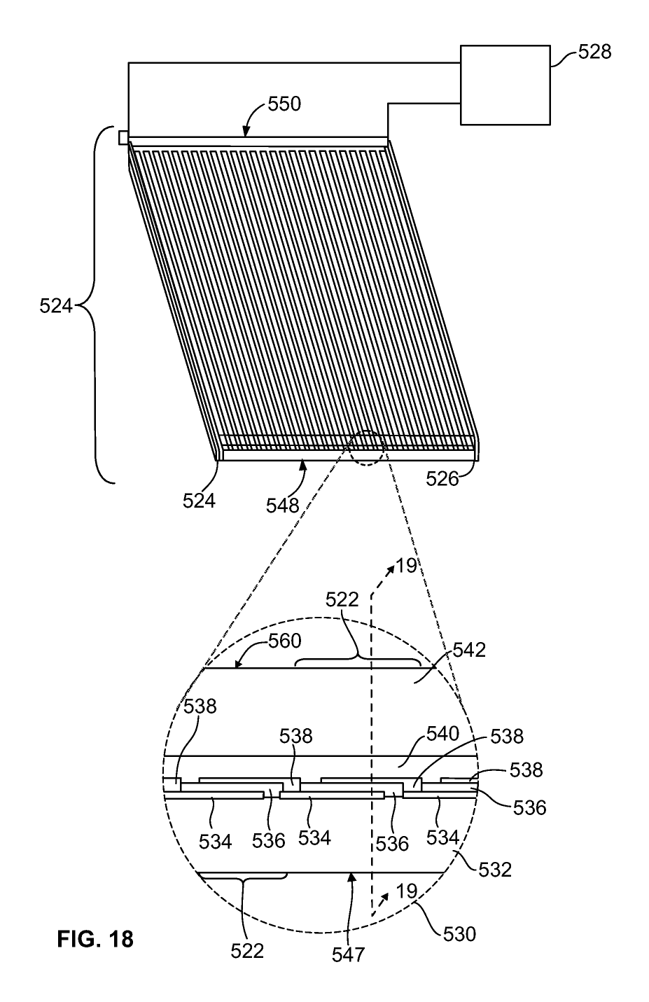

FIG. 18 is a perspective view of a schematic diagram of a PV device 520 and a magnified view 530 of a cross-sectional portion of the PV device 520 according to another embodiment. The PV device 520 may be similar to the PV device 100 shown in FIG. 1. The PV device 520 includes a plurality of PV cells 522 electrically connected in series with one another. Each of the outermost PV cells 522 also may be electrically connected with one of a plurality of leads 524, 526. The leads 524, 526 extend between opposing ends 548, 550 of the PV device 520. The leads 524, 526 may be connected with a circuit 528. The circuit 528 is a load through which the power generated by the PV device 520 is passed. Similar to the PV device 100, each of the PV cells 522 in the PV device 520 includes a stack of multiple layers. In some embodiments, each PV cell 522 includes a superstrate 532, a bottom electrode 534, a semiconductor layer stack 536, a top electrode 538, an adhesive 540 and a cover sheet 542. The top electrode 538 of one PV cell 522 is electrically connected with the bottom electrode 534 in a neighboring PV cell 522.

One difference between the PV device 520 and the PV device 100 is that the PV device 520 generates electric current from light that is incident on a bottom surface 547 of the PV device 520. The light passes through the superstrate 532 and/or the bottom electrode 534. The light is absorbed by the semiconductor layer stack 536. Some of the light may pass through the semiconductor layer stack 536. This light may be reflected back into the semiconductor layer stack 536 by the top electrode 538. The PV device 520 converts light into electric current in a manner similar to the PV device 100 (shown in FIG. 1).

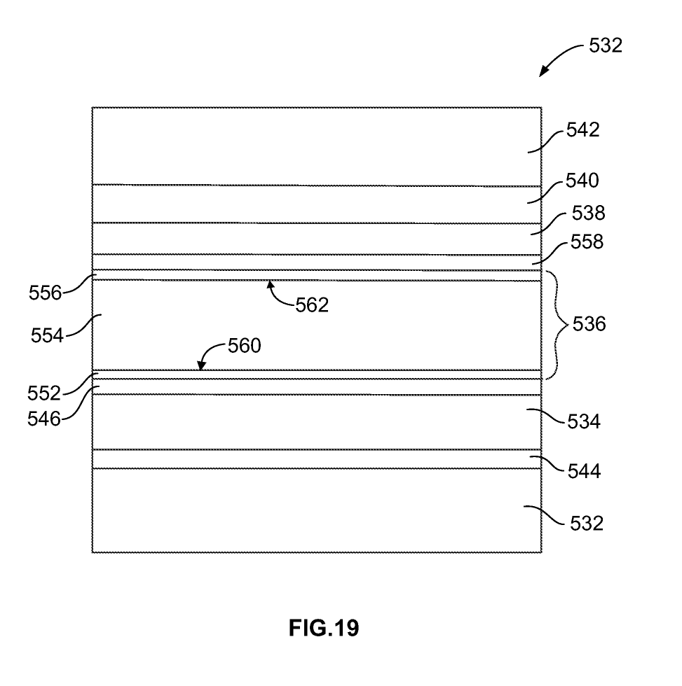

FIG. 19 is a cross-sectional view of the PV cell 522 taken along line 19-19 shown in FIG. 18. In some embodiments, the PV cell 522 includes layers in addition to those shown in FIG. 18. For example, the PV cell 522 may include a barrier layer 544, a buffer layer 546, and an optical spacer layer 558. The barrier layer 544 may be located on the superstrate 532. The buffer layer 546 is located between the bottom electrode 544 and the semiconductor layer stack 536. The optical spacer layer 558 may be located between the semiconductor layer stack 536 and the top electrode 538.

The superstrate 532 is located at the bottom of the PV cell 522 proximate to the bottom surface 547 of the PV device 520 (shown in FIG. 1). The superstrate 532 provides mechanical support to the other layers in the PV cell 522. For example, the superstrate 532 is a light transmissive supporting layer that supports the other layers in the PV cell 522 in one embodiment. The superstrate 532 may be continuous across the bottom of the PV device 520. For example, a single superstrate 532 may support the other layers in all of the PV cells 522 in the PV device 520. In some embodiments, the superstrate 532 has a surface area of at least approximately 5.72 square meters. In another embodiment, the superstrate 532 has a surface with dimensions of at least approximately 2.2 meters by approximately 2.6 meters. In another embodiment, the superstrate 532 has a surface area of at least approximately 4 square meters. In another embodiment, the superstrate 532 has a different surface area or a surface with different dimensions.

The superstrate 532 is formed from one or more light transmissive materials. In some embodiments, the superstrate 532 is formed from a dielectric material. For example, the superstrate 532 may be formed from a glass such as float glass or borosilicate glass. In another example, the superstrate 532 may be formed from soda-lime float glass, low iron float glass or a glass that includes at least 10 percent by weight of sodium oxide (Na₂O). In another embodiment, the superstrate 532 is formed from another ceramic such as silicon nitride (Si₃N₄) or aluminum oxide (alumina, or Al₂O₃). Alternatively, the superstrate 532 may include polyethylene terephthalate (“PET”), polyethylene naphthalate (“PEN”) or polymethylmetacrylat (“PMMA”). The superstrate 532 may be formed from materials having a relatively low softening point. In some embodiments, the superstrate 532 is formed from one or more materials having a softening point below about 750° C. The superstrate 532 may be provided in a variety of thicknesses. For example, the superstrate 532 may be any thickness sufficient to support the remaining layers of the PV cell 522 while providing mechanical and thermal stability to the PV cell 522 during manufacturing and handling of the PV cell 522. By way of example only, the superstrate 532 may be at least approximately 0.7 to 5.0 millimeters thick. In some embodiments, the superstrate 532 includes an approximately 1.1 millimeter thick layer of borosilicate glass. In another embodiment, the superstrate 532 includes an approximately 3.3 millimeter thick layer of low iron or standard float glass. Other thicknesses of the superstrate 532 also may be used.

The barrier layer 544 is deposited on the superstrate 532 between the superstrate 532 and the bottom electrode 534. The barrier layer 544 is similar to the barrier layer 140 (shown in FIG. 2) of the PV cell 102. The barrier layer 544 may be deposited directly on the superstrate 532 similar to the deposition of the barrier layer 140 described above. The bottom electrode 534 may be deposited on the barrier layer 544 and between the barrier layer 544 and the buffer layer 546. In some embodiments, the bottom electrode 534 is similar to the top electrode 118 of the PV cell 102 (shown in FIGS. 1 and 2). The bottom electrode 534 and top electrode 118 both include or are formed from conductive and light transmissive materials as light passes through the bottom electrode 534 and the top electrode 118 to reach the semiconductor layer stacks 536, 116 (shown in FIG. 2) of the respective PV cells 520, 102. The bottom electrode 536 may be provided similar to the top electrode 118, as described above.

In some embodiments, the buffer layer 546 is deposited on the bottom electrode 534 and between the bottom electrode 534 and the semiconductor layer stack 536. For example, the buffer layer 546 may be deposited directly on the bottom electrode 534. In one or more other embodiments, the buffer layer 546 is not included in the PV cell 522. Similar to the optical spacer layer 146 of the PV cell 102 (shown in FIG. 2), the buffer layer 546 may assist in stabilizing the bottom electrode 534 and assisting in preventing chemical attack on the bottom electrode 534 from the semiconductor layer stack 536.

The semiconductor layer stack 536 may be deposited on the buffer layer 546 in embodiments where the buffer layer 546 is included in the PV cell 522. The semiconductor layer stack 536 may be deposited on the bottom electrode 534 in embodiments where the buffer layer 546 is not included in the PV cell 522. In some embodiments, the semiconductor layer stack 536 is similar to the semiconductor layer stack 116 of the PV cell 102 (shown in FIGS. 1 and 2). For example, the semiconductor layer stack 536 also may include first, second and third semiconductor sub-layers 552, 554, 556. The sub-layers 552, 554, 556 may be provided in a substantially similar manner as the first, second and third sub-layers 148, 150, 152 of the semiconductor layer stack 116, as described above. For example, the second sub-layer 554 may be deposited and crystallized in one or more of the manners described above in conjunction with second sub-layer 150. In some embodiments, the first semiconductor sub-layer 552 includes or is formed of silicon carbide. For example, the first semiconductor sub-layer 552 may be formed of SiC, non-stoichiometric SiₓC₁₋ₓ, phosphorus-doped n+ SiC, phosphorus-doped SiₓC₁₋ₓ, boron-doped p+ SiC, boron-doped p+ SiₓC₁₋ₓ, unintentionally doped or intrinsic SiC, or unintentionally doped or intrinsic SiₓC₁₋ₓ. In such an embodiment, the first semiconductor sub-layer 552 may have a higher melting temperature than a similar sub-layer formed of silicon. For example, the first semiconductor sub-layer 552 may have a melting temperature of at least approximately 2000 degrees Celsius. In another example, the first semiconductor sub-layer 552 may have a melting temperature of at least approximately 2730 degrees Celsius. Dopant junctions may exist at first and/or second interfaces 560, 562. For example, a dopant junction may exist at the first interface 560 between the first and second semiconductor sub-layers 552, 554. A dopant junction also may exist at the second interface 562 between the second and third semiconductor sub-layers 554, 556, for example. In some embodiments, the dopant junctions at the first and/or second interfaces 560, 562 may be represented by the dopant profile 172 shown in FIG. 3.

The optical spacer layer 558 may be deposited on the semiconductor layer stack 536 in some embodiments. In one or more other embodiments, the optical spacer layer 558 is not included in the PV cell 522. The optical spacer layer 558 may be substantially similar to the optical spacer layer 146 of the PV cell 102 (shown in FIG. 2). For example, the optical spacer layer 558 may assist in stabilizing the top electrode 538 and assisting in preventing chemical attack on the semiconductor layer stack 536 by the top electrode 538. The optical spacer layer 558 may be similar to a buffer layer that impedes or prevents contamination of the semiconductor layer stack 536 by the top electrode 538 in some embodiments. The optical spacer layer 558 reduces plasmon absorption losses in the semiconductor layer stack 538 in some embodiments.

The top electrode 538 is deposited on the optical spacer layer 558 in one embodiment. The top electrode 538 is deposited on the semiconductor layer stack 536 in one or more embodiments where the optical spacer layer 558 is not included in the PV cell 522. The top electrode 538 may include or be formed from a reflective and conductive material in some embodiments. For example, the top electrode 538 may be substantially similar to the bottom electrode 114 of the PV cell 102 (shown in FIG. 2). In some embodiments, the adhesive 540 is deposited on the top electrode 538. Alternatively, the adhesive 540 is not included in the PV cell 522. The adhesive 540 may be provided to secure the top electrode 538 to the cover sheet 542. The adhesive 540 also may impede moisture ingress into the PV cell 522 from the edges of the PV device 520 (shown in FIG. 18). The adhesive 540 may include or be formed from a material such as PVB, surlyn, or EVA copolymer. The cover sheet 542 may be laminated on the adhesive 540 in some embodiments. Alternatively, the cover sheet 542 is laminated on the top electrode 538 in embodiments where the adhesive 540 is not included in the PV cell 522. The cover sheet 540 is substantially similar to the cover sheet 122 of the PV cell 102, as described above, in some embodiments.

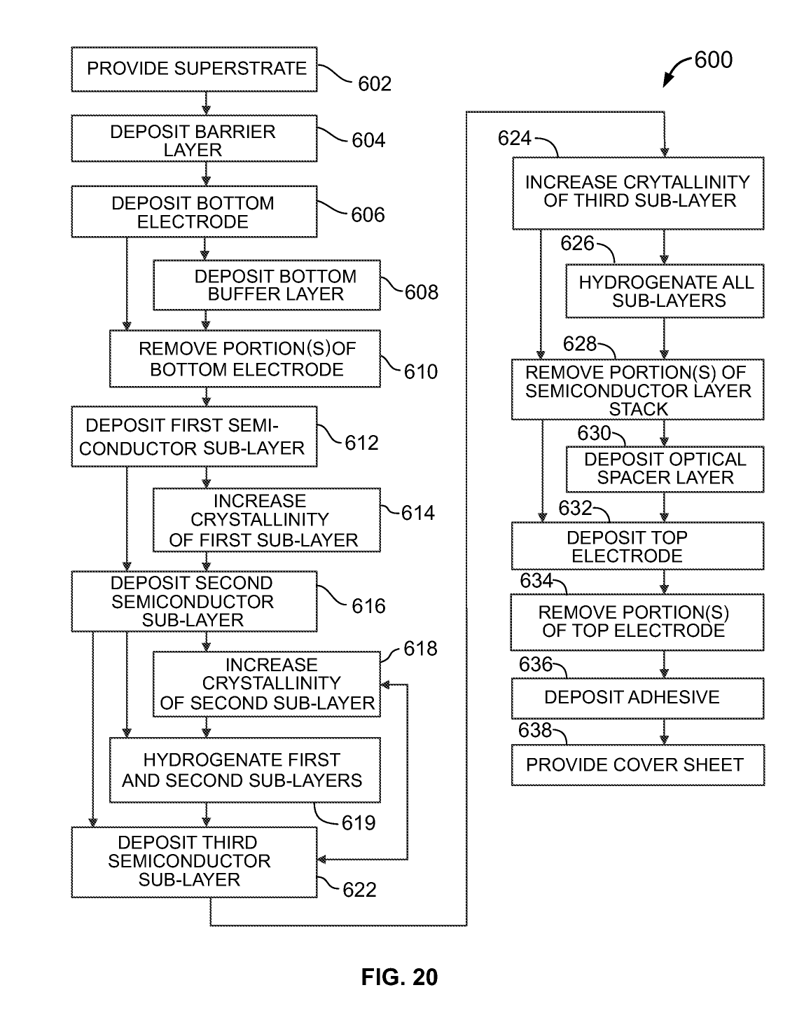

FIG. 20 illustrates a flowchart for a method 600 for manufacturing the PV device 520. At block 602, a superstrate is provided. For example, the superstrate 532 (shown in FIGS. 18 and 19) may be provided. At block 604, a barrier layer is deposited on the superstrate. For example, the barrier layer 544 can be deposited directly on the superstrate 532. The barrier layer can be deposited by sputtering the barrier layer material on the substrate or by using PECVD, for example. At block 606 a bottom electrode is deposited on the barrier layer. For example, the bottom electrode 534 may be deposited directly on the barrier layer 544. The bottom electrode can be deposited by sputtering the material of the bottom electrode onto the barrier layer, for example. Other methods of depositing the bottom electrode include but are not limited to chemical vapor deposition, low pressure chemical vapor deposition, or metal-organic chemical vapor deposition. Additionally, the bottom electrode can be deposited at an elevated temperature to roughen the surface of the bottom electrode. For example, the bottom electrode can be deposited at a temperature between 200 to 500 degrees Celsius in order to roughen the surface of the bottom electrode.

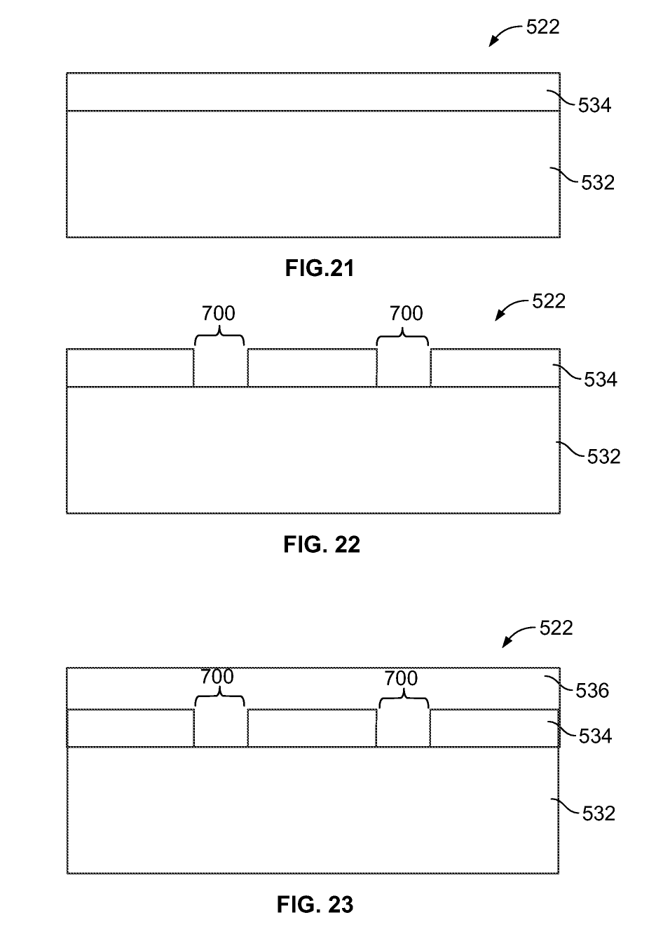

FIG. 21 is a schematic cross-sectional view of the PV cell 522 after block 606 of the method 600 according to some embodiments. As shown in FIG. 21, the PV cell 522 includes the superstrate 532 and the bottom electrode 534 after block 606 in some embodiments. While the barrier layer 544 is not shown in FIG. 21, the barrier layer 544 may be included between the superstrate 532 and the bottom electrode 534 as described above.

Returning to FIG. 20, in some embodiments the method 600 proceeds between blocks 606 and 608, and between blocks 608 and 610. In another embodiment, the method 600 proceeds between blocks 606 and 610. At block 608 a buffer layer is deposited on the bottom electrode. For example, the buffer layer 546 may be deposited on the bottom electrode 534. At block 610, one or more portions of the bottom electrode are removed. For example, one or more portions of the bottom electrode 534 may be removed similar to remove the portions of the bottom electrode 114 of the PV cell 102 (shown in FIG. 2) described above.

FIG. 22 is a schematic cross-sectional view of the PV cell 522 after block 610 of the method 600 according to some embodiments. At block 610, the bottom electrode 534 (and buffer layer 546 in embodiments where the buffer layer 546 is included) is removed in first areas 700 to expose corresponding areas of the superstrate 532. Although not shown in FIG. 22, removal of the bottom electrode 534 in the first areas 700 may expose corresponding areas of the barrier layer 544 in embodiments where the barrier layer 544 is included in the PV cell 522. In another embodiment, the barrier layer 544 also is removed in the first areas 700. The first areas 700 may extend between opposing ends 548, 550 of the PV device 520 (shown in FIG. 18).

Returning to FIG. 20, the method 600 proceeds between block 610 and block 612. A semiconductor layer stack is provided at blocks 612 through 622. For example, in embodiments where the buffer layer 546 is included in the PV cell 522, the semiconductor layer stack 536 may be deposited on buffer layer 546 in the areas where the buffer layer 546 and bottom electrode 534 were not removed at block 610 and on the barrier layer 544 in the areas where the buffer layer 546 and bottom electrode 534 were not removed at block 610. For example, in embodiments where the buffer layer 546 is not included in the PV cell 522, the semiconductor layer stack 536 may be deposited on the bottom electrode 534 in the areas where the bottom electrode 534 was not removed at block 610 and on the barrier layer 544 in the areas where the bottom electrode 534 were not removed at block 610.

FIG. 23 is a schematic cross-sectional view of the PV cell 522 following blocks 612 through 622 of the method 600 according to some embodiments. As shown in FIG. 23, the semiconductor layer stack 536 is deposited so as to cover the bottom electrode 534 and to fill the gaps in the first areas 700 shown in FIG. 22. Although not shown in FIG. 23, in embodiments where the buffer layer 546 (shown in FIG. 19) is included in the PV cell 522, the semiconductor layer stack 536 covers the buffer layer 546. In embodiments where the barrier layer 544 (shown in FIG. 19) is not removed from the bottom electrode 534, the semiconductor layer stack 536 is deposited on the barrier layer 544 in the first areas 700.

Returning to FIG. 20, at block 612 a first semiconductor sub-layer is deposited. For example, the first semiconductor sub-layer 552 may be deposited. In some embodiments, the method 600 proceeds between blocks 612, 614 and 616. In another embodiment, the method 600 proceeds between blocks 612 and 616. At block 614, a level of crystallinity in the first semiconductor sub-layer is increased. For example, the level of crystallinity in the first semiconductor sub-layer 552 may be increased similar to increasing the level of crystallinity in the first semiconductor sub-layer 148 of the PV cell 102, described above, in some embodiments. At block 616, a second semiconductor sub-layer is deposited on the first semiconductor sub-layer. For example, the second semiconductor sub-layer 554 can be deposited similar to the deposition of the second semiconductor sub-layer 150 of the PV cell 102, as described above, in some embodiments.

In one embodiment, the method 600 proceeds between blocks 616, 618, 619 and 622. In another embodiment, the method 600 proceeds between blocks 616, 618 and 622. In another embodiment, the method 600 proceeds between blocks 616, 619 and 622. In another embodiment, the method 600 proceeds between blocks 616 and 622. At block 618, a level of crystallinity in the second semiconductor sub-layer is increased. For example, the level of crystallinity in the second semiconductor sub-layer 554 may be increased similar to increasing the level of crystallinity in the second semiconductor sub-layer 150 of the PV cell 102, described above. Alternatively, a level of crystallinity in both the first and second semiconductor sub-layers is increased at block 618. For example, in one embodiment, a level of crystallinity in the first and second semiconductor sub-layers 552, 554 may be increased at block 618 if a level of crystallinity in the first semiconductor sub-layer 552 is not increased at block 614.

At block 619, the first and second sub-layers are hydrogenated, similar to as described above in the method 400. For example, the first and second semiconductor sub-layers 552, 554 may be exposed to an atomic source of hydrogen, as described above. At block 622, a third semiconductor sub-layer is deposited on the second semiconductor sub-layer. For example, the third semiconductor sub-layer 556 may be deposited in an amorphous state or may be directly-deposited in a microcrystalline state similar to the deposition of the third semiconductor sub-layer 152, as described above.

At block 624, a level of crystallinity in all of the first, second and third semiconductor sub-layers in increased in some embodiments. Alternatively, a level of crystallinity in the third semiconductor sub-layer is increased while the level of crystallinity in the first and second sub-layers does not increase or does not increase by a statistically significant amount. For example, the level of crystallinity in the first, second and/or third semiconductor sub-layers 552, 554, 556 may be increased similar to increasing the level of crystallinity in the first, second and/or third semiconductor sub-layers 148, 150, 152, as described above.

In one embodiment, the method 600 proceeds between blocks 624, 626 and 628. In another embodiment, the method 600 proceeds between blocks 624 and 628. At block 626, all three sub-layers 552, 554, 556 are hydrogenated, similar to as described above in the method 400. For example, if the first, second and third semiconductor sub-layers 552, 554, 556 are crystallized at block 624, then the first, second and third semiconductor sub-layers 552, 554, 556 are hydrogenated after block 624.

At block 628, one or more portions of the semiconductor layer stack is removed to expose corresponding areas of the buffer layer. Alternatively, one or more portions of the semiconductor layer stack and the buffer layer are removed to expose corresponding areas of the bottom electrode. For example, the semiconductor layer stack 536 or the semiconductor layer stack 536 and the buffer layer 546 can be laser or mechanically scribed to remove these layers in selected areas, similar to the removal of the semiconductor layer stack 116, the buffer layer 146 and/or the passivation layer 144 (shown in FIG. 2), as described above.

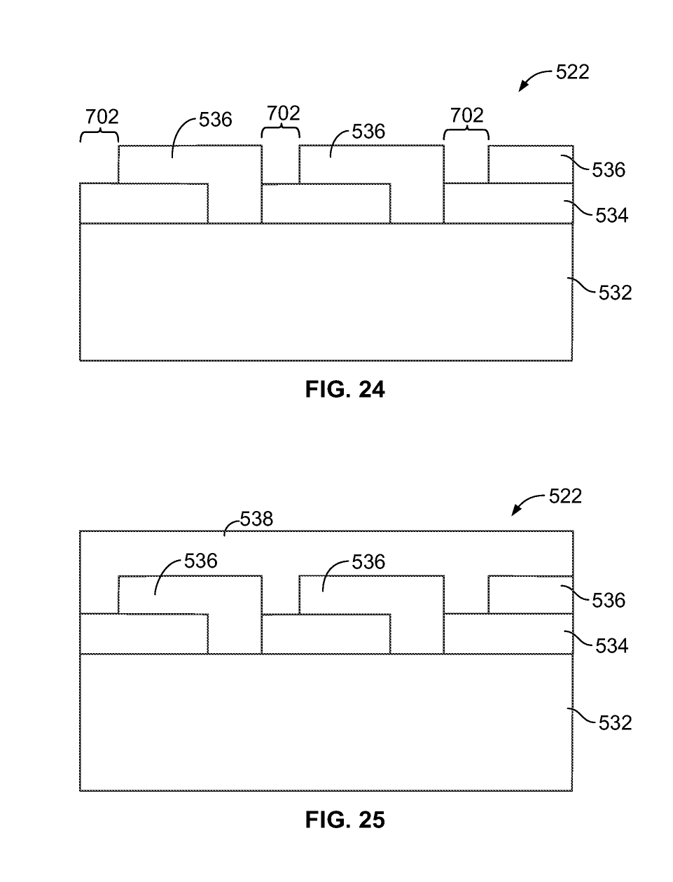

FIG. 24 is a schematic cross-sectional view of the PV cell 522 after block 628 according to some embodiments. As shown in FIG. 24, selected areas of the semiconductor layer stack 536 are removed at block 628. Although not shown in FIG. 24, in another embodiment, selected areas of the semiconductor layer stack 536 and the buffer layer 546 (shown in FIG. 19) are removed at block 628. The semiconductor layer stack 536 or the semiconductor layer stack 536 and the buffer layer 546 are removed at second areas 702. Removing the semiconductor layer stack 536 may expose the buffer layer 546 in corresponding areas. Removing the semiconductor layer stack 536 and the buffer layer 546 may expose the bottom electrode 534 in corresponding areas. The second areas 702 may extend between the opposing ends 548, 550 of the PV device 520 (shown in FIG. 19). Removal of the semiconductor layer stack 536 in the second areas 702 may cause the cross-section of the semiconductor layer stack 536 to have a stair-step, or “L” shape in the cross-sectional view shown in FIG. 18.

Returning to FIG. 20, the method 600 proceeds between blocks 628, 630 and 632 in one embodiment. In another embodiment, the method 600 proceeds between blocks 628 and 632. At block 630, an optical spacer layer is deposited. For example, the optical spacer layer 558 may be deposited on the semiconductor layer stack 536 in the areas where the semiconductor layer stack 536 was not removed at block 628. In some embodiments, the optical spacer layer 558 also is deposited on the buffer layer 546 in the second areas 702 where the semiconductor layer stack 536 was removed at block 628. In another embodiment, the optical spacer layer 558 also is deposited on the bottom electrode 534 in the second areas 702 where the semiconductor layer stack 536 and the buffer layer 546 were removed at block 628.

Next, at block 632 the top electrode is deposited. For example, the top electrode 538 may be deposited at block 632. The top electrode is deposited on the semiconductor layer stack in the areas where the semiconductor layer stack was not removed at block 628. In some embodiments, the top electrode also is deposited on the buffer layer in the areas where the semiconductor layer stack was removed at block 628. In another embodiment, the top electrode is also deposited on the bottom electrode if the buffer layer was removed at block 628. The top electrode is electrically connected to the bottom electrode after block 632.

FIG. 25 is a schematic cross-sectional view of the PV cell 522 after block 632 according to some embodiments. The top electrode 538 is deposited over the semiconductor layer stack 536 and the optical spacer layer 558 (shown in FIG. 19) in the areas where the semiconductor layer stack 536 was not removed at block 628. In embodiments where the buffer layer 546 is not removed in the second areas 702 at block 628, the top electrode 538 also is deposited on the buffer layer 546 in the second areas 702. In embodiments where the buffer layer 546 is removed in the second areas 702 at block 628, the top electrode 538 also is deposited on the bottom electrode 534 in the second areas 702. In some embodiments, the top electrode 538 and bottom electrode 534 are electrically connected in the second areas 702 after block 632. The top electrode can be deposited in a manner that is similar to the deposition of the bottom electrode 114, as described above.

At block 634, one or more portions of the top electrode are removed. For example, one or more portions of the top electrode 538 can be removed using laser or mechanical scribing, similar to the removal of the top electrode 118 (shown in FIG. 2), as described above.

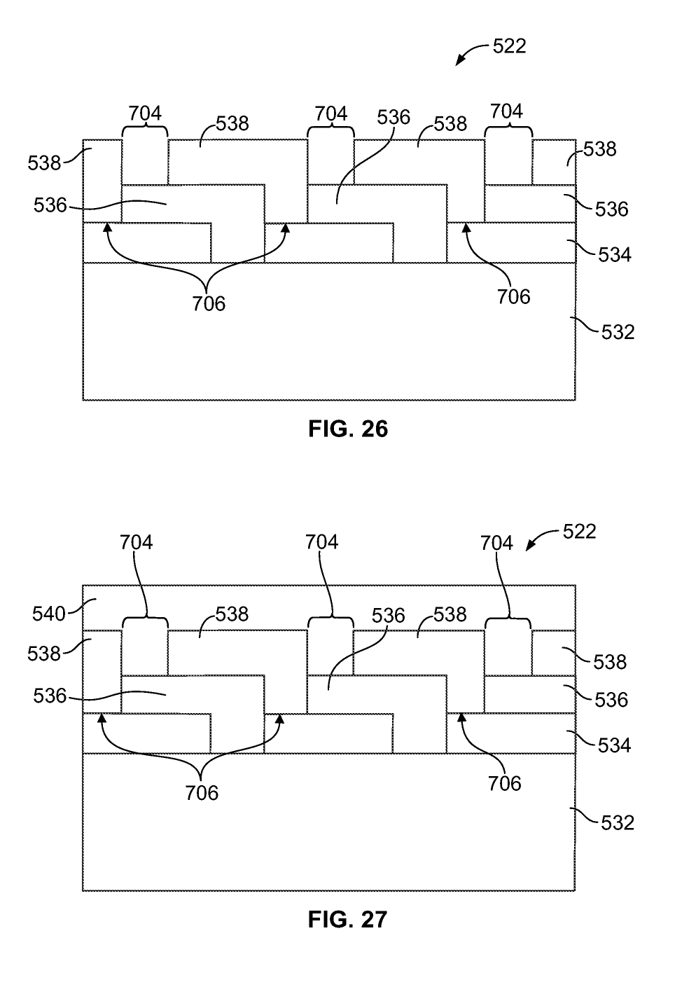

FIG. 26 is a schematic cross-sectional view of the PV cell 522 after block 634 according to some embodiments. As shown in FIG. 26, the top electrode 538 is removed at one or more areas. The areas can include a plurality of third areas 704. The third areas 704 may extend between opposing ends 548, 550 of the PV device 520 (shown in FIG. 19). In such an embodiment, the top electrode 538 extends as strips of material that extend between opposing ends 548, 550 of the PV device 520. Corresponding areas of the semiconductor layer stack 536 and the optical spacer layer 558 (shown in FIG. 19) are exposed when the top electrode 538 is removed at the third areas 704. The top electrode 538 may be electrically connected to the bottom electrode 534 at a plurality of interfaces 706. The interfaces 706 may correspond to the third areas 704.

Returning to FIG. 20, the method 600 proceeds between blocks 634 and 636. At block 636, a top adhesive is deposited. For example, the adhesive 540 may be deposited on the top electrode 538 in areas where the top electrode 538 is not removed at block 634. The adhesive 540 also may be deposited on the optical spacer layer 558 in the third areas 704 where the top electrode 538 was removed at block 634.

FIG. 27 is a schematic cross-sectional view of the PV cell 522 after block 634 according to some embodiments. As shown in FIG. 27, the adhesive 540 may be deposited on the top electrode 538 in areas where the top electrode 538 was not removed and above the optical spacer layer 558 (shown in FIG. 19) and the semiconductor layer stack 536 in the third areas 704.

Returning to FIG. 20, the method 600 proceeds between blocks 636 and block 638. At block 638, a cover sheet is provided on the top adhesive. For example, the cover sheet 542 may be laminated over the adhesive 540. The adhesive 540 may assist in securing the cover sheet 542 to the PV device 520 (shown in FIG. 18).

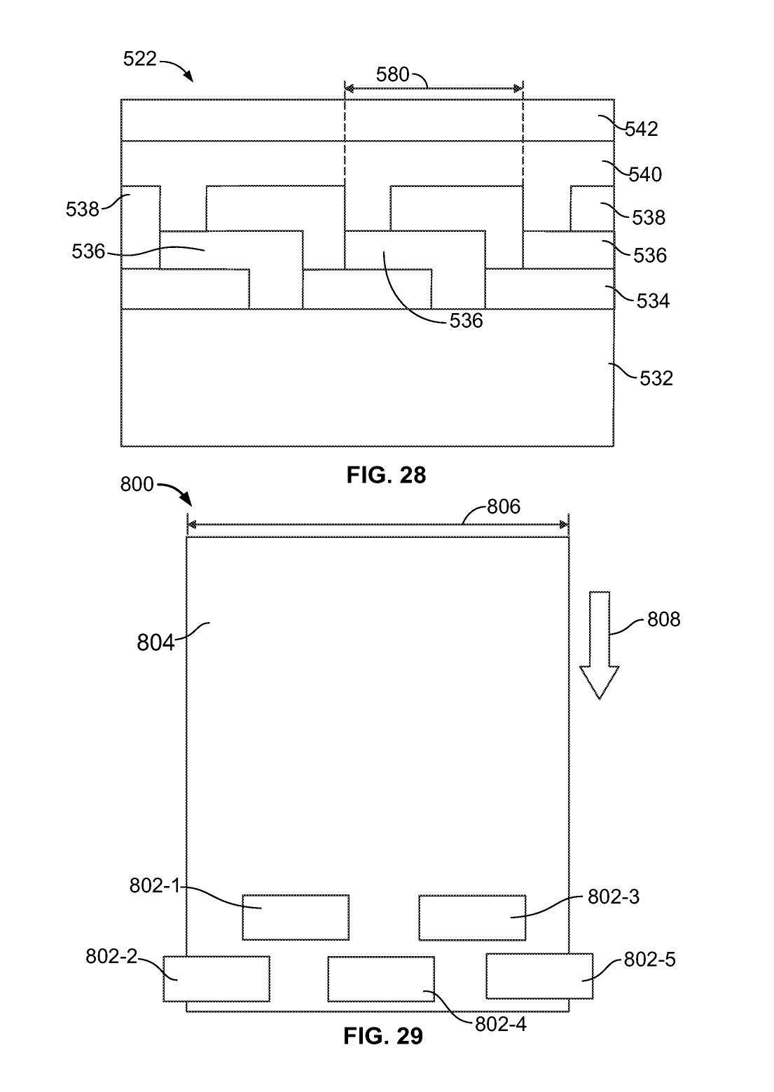

FIG. 28 is a schematic cross-sectional view of the PV cell 522 after block 638 according to some embodiments. As shown in FIG. 28, the cover sheet 542 may be placed over the adhesive 540 to complete the manufacture of the PV cells 522.

After block 638, several PV cells 522 of the PV device 520 (shown in FIG. 18) are completed. In some embodiments, the lead 524 (shown in FIG. 18) may be electrically connected to the top electrode layer 538 in the left-most PV cell 522 in the PV device 520 while the other lead 526 (shown in FIG. 18) may be electrically connected to the bottom electrode 534 in the right-most PV cell 522 in the PV device 520. Light that is incident on the PV cells 520 through the superstrate 532 may be converted into electricity by the PV cells 522, as described above.

As described above, the PV cells 522 may be formed in a wide variety of embodiments using a variety of methods. In one embodiment, the PV cell 522 includes low-iron soda-lime glass as the superstrate 532. An approximately 70 nanometer thick layer of SiO₂ is deposited on the superstrate 532 as the barrier layer 544. Next, a layer of SnO₂:F that is approximately 1 micrometer thick is provided on the barrier layer 544 as the bottom electrode 534. An approximately 100 nanometer thick layer of Al:ZnO is deposited on the bottom electrode 534 as the buffer layer 546. Next, one or more portions of the bottom electrode 534 and the buffer layer 546 are laser scribed to expose one or more areas of the barrier layer 544. An approximately 10 nanometer thick layer of amorphous silicon is then deposited as the first semiconductor sub-layer 552 of the semiconductor layer stack 554. The first semiconductor sub-layer 552 is doped so as to be an n+ type amorphous silicon layer. The second semiconductor sub-layer 554 is deposited on the first semiconductor sub-layer 552 as an approximately 2 micrometer thick amorphous silicon layer. The second semiconductor sub-layer 554 is an intrinsic layer of silicon. Next, the first and second semiconductor sub-layers 552, 554 are crystallized and hydrogenated. An approximately 20 nanometer thick silicon layer is deposited as the third semiconductor sub-layer 556 on the second semiconductor sub-layer 554. The third semiconductor sub-layer 556 is directly deposited as a microcrystalline layer of silicon. The third semiconductor sub-layer 556 is doped so that the silicon is a p+ silicon layer. One or more portions of the semiconductor layer stack 536 are laser scribed to expose one or more areas of the bottom electrode 534. An approximately 90 nanometer thick layer of Al:ZnO is then deposited as the optical spacer layer 558 on the semiconductor layer stack 536. Next, the top electrode 538 is deposited as an approximately 150 nanometer thick layer of Ag. As described above, Ag can provide a reflective surface for the top electrode 538. The top electrode 538 and the optical spacer layer 558 are then laser scribed to remove one or more portions of the top electrode 538 and the optical spacer layer 558. The adhesive layer 540 is then deposited, followed by lamination of a tempered glass cover sheet as the cover sheet 542. While the above description provides some embodiments, various other embodiments are within the scope of the presently described subject matter.

As described above, a level of crystallinity in the semiconductor layer stacks 116, 536 may be increased by exposing the semiconductor layer stacks 116, 536 or portions of the semiconductor layer stacks 116, 536 to e-beams. For example, where a semiconductor sub-layer in the semiconductor layer stacks 116, 536 is an amorphous layer, crystalline grains can be created and/or increased in average grain size by exposing the sub-layer to e-beams. In another example, where a semiconductor sub-layer is a directly deposited microcrystalline layer, the average size of the crystalline grains in the sub-layer can be increased by exposing the sub-layer to e-beams. In either scenario, the volume fraction of crystalline grains in the sub-layer(s) can be increased.

In some embodiments, the semiconductor sub-layers of the semiconductor layer stacks 116, 536 can be placed into a chamber of a system to increase the level of crystallinity in one or more of the semiconductor sub-layers in the semiconductor layer stacks 116, 536. Such a system can be used to controllably heat the semiconductor sub-layer(s) by using a scanned or pulsed focused beam of energy with or without melting and/or liquefying the material therein.

In some embodiments, the system is designed to provide, either through continuous scanning or through pulsed mode operation, annealing of the semiconductor sub-layers for controlled dwell times. For example, the system may expose the semiconductor sub-layers sought to be crystallized to an e-beam for a time period of at least approximately 10 microseconds to 1 second. During this dwell time period, the level of crystallinity in the semiconductor sub-layers of the semiconductor layer stacks 116, 536 may be increased. The temperature of the semiconductor sub-layers in the semiconductor layer stacks 116, 536 may be increased to a level sufficient to increase a level of crystallinity in one or more of the sub-layers, but low enough to avoid melting or liquefying the sub-layers.

The semiconductor sub-layers of the semiconductor layer stacks 116, 536 may be exposed to multiple exposures of the e-beams for multiple dwell time periods. In some embodiments, the dwell time periods are of short enough duration to avoid melting or liquefying the semiconductor sub-layers in the semiconductor layer stacks 116, 536. In another embodiment, the dwell time periods are of short enough duration so that dopants in one sub-layer do not diffuse more than approximately 250 nanometers across a dopant junction between the sub-layer and an adjacent sub-layer, as described above. In another embodiment, the dwell time periods are short enough so that the dopants do not diffuse more than approximately 100 nanometers across the dopant junction, also as described above. In another embodiment, the dwell time periods are short enough so that the dopants do not diffuse more than approximately 50 nanometers across the dopant junction, also as described above. In another embodiment, the dwell time periods are short enough so that the dopants do not diffuse more than approximately 25 nanometers across the dopant junction, also as described above. In another embodiment, the dwell time periods are of short enough duration so that the junction width of the junction between adjacent sub-layers in a semiconductor layer stack 116, 536 does not increase by more than approximately 250 nanometers, as described above. In another embodiment, the dwell time periods are short enough so that the junction width does not increase by more than approximately 100 nanometers. In another embodiment, the dwell time periods are short enough so that the dopants do not diffuse more than approximately 50 nanometers across the dopant junction, also as described above. In another embodiment, the dwell time periods are short enough so that the junction width does not increase by more than approximately 25 nanometers.

The level of crystallinity of the sub-layers in the semiconductor layer stacks 116, 536 may be increased while the sub-layers are in a vacuum. For example, the sub-layers may be in a chamber at a pressure that is no greater than approximately 10 to 10⁻⁶ ton.

FIG. 29 is a top schematic view of a system 800 in which a plurality of e-beam sources 802 scans a large area panel 804 in accordance with some embodiments. While the discussion here addresses the length of an emitted e-beam line, the discussion applies equally well to the width of a rastered point e-beam. Additionally, while five e-beam sources 802 are shown in FIG. 29, a different number of e-beam sources 802 can be used.

The system 800 includes a plurality of e-beam sources 802 spatially offset from one another in two directions. The sources 802 may be offset from one another in two orthogonal directions, for example. In some embodiments, each source is a Pierce reflector system that includes a plurality of reflectors and a filament. The filament can comprise a wire, a ground-flat wire, or a rectangular block of emitting material. Other electronic or magnetic components may be included in the Pierce system such as focusing grids and anodes. These components may be used to shape the e-beam into a desired shape such as a Gaussian or square-shaped cross-section. Alternatively, each source 802 includes a point source e-beam that is focused and rastered using magnetic fields. While the e-beam sources 802 are described as comprising a Pierce reflector that includes a plurality of reflectors and a filament, other e-beam sources can be used. As shown in FIG. 29, the reference number for each of the sources 520 includes an additional number such as −1, −2, −3, −4 or −5. This additional number is used to clarify which source 520 is referred to in the specification.

The panel 804 may include a portion of the PV device 100 or the PV device 520. For example, the panel 804 may include the substrate 112, the barrier layer 140, the bottom adhesion layer 142, the bottom electrode 114, the passivation layer 144, the buffer layer 146 and one or more of the sub-layers 148, 150, 152 of the semiconductor layer stack 116 of the PV device 100. Alternatively, the panel 804 may include the superstrate 532, the barrier layer 544, the bottom electrode 534, the buffer layer 546 and one or more sub-layers 552, 554, 556 of the semiconductor layer stack 536.

In some embodiments, the panel 804 is of sufficient size or area that a single e-beam source 802 cannot emit an e-beam that exposes or covers all of the panel 804 or all of the width of the panel 804 at once. For example, the panel 804 may be wider than the length of a line e-beam or the raster pattern of a point-e-beam emitted by each e-beam source 802. For example, if the length of a line e-beam is 2 to 100 centimeters, then the panel 804 can have a width that is greater than 100 centimeters and/or a total surface area that is greater than approximately 1 square meter. In another example, the length of a line e-beam can be a fraction of the width of the panel 804. For example, each line e-beam can have a length that is approximately one-fifth, one-quarter, one-third or one-fourth of the width of the panel 804.

In another example, the length of a line e-beam can be approximately the same as the width of a single solar cell in the module. For example, the length of a line e-beam emitted by a source 802 may be approximately the same as a width 160 of a PV cell 102 (shown in FIG. 16) or a width 580 of a PV cell 522 (shown in FIG. 28). In some embodiments, the width 160 of the PV cell 102 or the width 580 of the PV cell 522 is at least approximately 0.4 to 1 centimeters. Alternatively, the line e-beam can have a length that is greater than the width 160 of a PV cell 102 or the width 544 of a PV cell 522. For example, the line e-beam can have a length of at least approximately 20 to 100 centimeters.

In order to cover a large-area panel 804, a plurality of e-beam sources 802 are offset in at least two directions from one another. For example, the e-beam sources 802 can be spatially offset from one another in two orthogonal or approximately orthogonal directions in a plane parallel to the panel 804. With respect to the embodiment illustrated in FIG. 29, the e-beam sources 802 are offset in a left/right direction and an up/down direction. In such an embodiment, the total e-beams produced by the sources 802 may cover a larger area, if not all, of a width 806 of the panel 804. For example, a line e-beam from a first source 802-1 can cover a portion of a width 806 of the panel 804. Another source 802-2 can emit a line e-beam that covers an adjacent and/or overlapping portion of the width 806 of the panel 804. Continuing in this manner, each of the sources 802-1, 802-2, 802-3, 802-4 and 802-5 can emit an e-beam line that covers less than the entire width 806 of the panel 804 and a different portion of this width 806 than each other. The sum total of e-beams transmitted by each of the sources 802-1, 802-2, 802-3, 802-4 and 802-5 can be as great as or greater than the total width 806 of the panel 804.

While some of the sources 802 are offset with respect to one another in a direction indicated by the arrow 806 (specifically, the sources 802-2 and 802-4), the panel 804 and/or sources 802 can move relative to one another to enable the panel 804 to be uniformly exposed to e-beams. In some embodiments, the sources 802 remain stationary while the panel 804 moves relative to the sources 802. For example, the panel 804 can move in the direction of the arrow 808 (or in a direction opposite of the arrow 808). Alternatively, the sources 802 can move relative to the panel 804 while the panel 804 remains stationary. In addition, the panel 804 and/or sources 802 can move in directions other than that of the arrow 808 in order to ensure that a greater area of the panel 804 is exposed to e-beams, if necessary.

In some embodiments, the sum total of the e-beam lines emitted by the sources 802 or rastered e-beam points can cover the entire width of the panel 804 so that a single pass of the panel 804 moving relative to the sources 802 is all that is necessary to expose the semiconductor sub-layers of the module 100 to an e-beam. For example, once the panel 804 moves relative to the sources 802 so that the sources 802 pass over an entire length of the panel 804, the entire area of the panel 804 has been exposed to an e-beam emitted by at least one of the sources 802. The motion of the panel 804 during a scan may include continuous relative motion with a continuously emitted electron beam. For example, the panel 804 and sources 802 may move relative to one another continually while the sources 802 emit e-beams. Alternatively, the panel 804 and/or sources 802 may move relative to the other, stop, and expose a portion of the panel 804 to e-beams emitted from the sources 802 for a dwell time. The panel 804 and/or sources 802 may then again move relative to the other, stop, and expose another portion of the panel 804 to e-beams emitted from the sources 802 for the same or different dwell time.

The distance moved by the panel 804 and/or sources 802 may be approximately the same for each movement of the panel 804 and/or sources 802. Alternatively, the distance moved by the panel 804 and/or sources 802 may differ for one or more movements of the panel 804 and/or sources 802. The dwell time for each exposure of a portion of the panel 804 to e-beams emitted by the sources 802 may be the same for each exposure of the panel 804. Alternatively, the dwell time may be different for one or more exposures of the panel 804 to e-beams emitted by the sources 802.

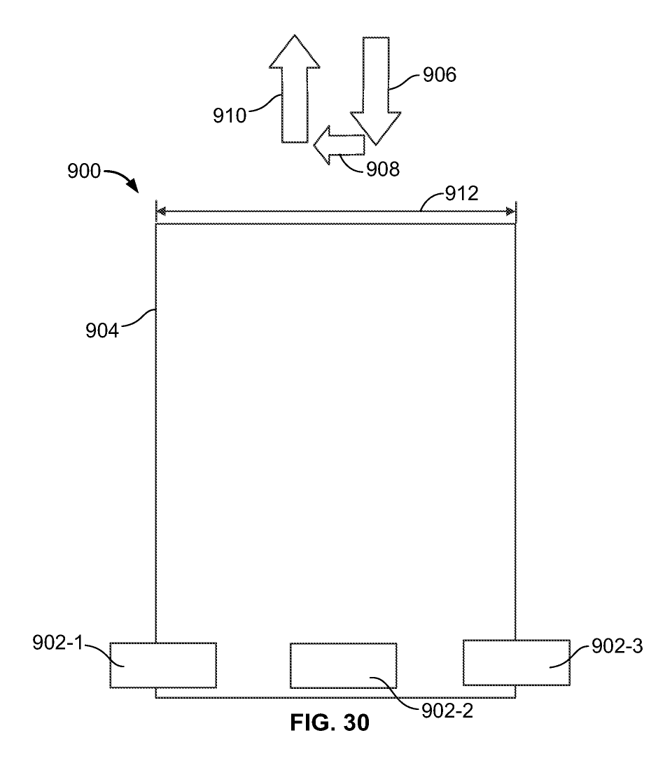

FIG. 30 is a top schematic view of a system 900 in which one or more offset e-beam sources 902 scan a large area panel 904 in accordance with another embodiment. In an embodiment, each source 902 includes is a Pierce reflector that includes a plurality of reflectors, a filament, and other electronic components such as a focusing grid and anode. In alternative embodiments, each source 902 includes a point source e-beam that is focused using magnetic fields. While three e-beam sources 902 are shown in FIG. 30, a different number of sources may be included. As shown in FIG. 30, the reference number for each of the sources 902 includes an additional number such as −1, −2, −3, −4 or −5. This additional number is used to clarify which source 902 is referred to in this discussion.

Similar to the panel 804, the panel 904 may include at least a portion of the PV device 100 or the PV device 520. For example, the panel 904 may include the substrate 112, the barrier layer 140, the bottom adhesion layer 142, the bottom electrode 114, the passivation layer 144, the buffer layer 146 and one or more of the sub-layers 148, 150, 152 of the semiconductor layer stack 116 of the PV device 100. Alternatively, the panel 904 may include the superstrate 532, the barrier layer 544, the bottom electrode 534, the buffer layer 546 and one or more sub-layers 552, 554, 556 of the semiconductor layer stack 536.

In some embodiments, the panel 904 is of sufficient size or area that a single e-beam source 902 cannot emit an e-beam that exposes or covers all of the panel 904 or all of the width of the panel 904 at once. For example, the panel 904 may be wider than the length of a line e-beam or the raster pattern of a point-e-beam emitted by each e-beam source 902. For example, if the length of a line e-beam is approximately 2 to 100 centimeters, then the panel 904 can have a width that is greater than approximately 100 centimeters and/or a total surface area that is greater than approximately 1 square meter. In another example, the length of a line e-beam can be a fraction of the width of the panel 904. For example, each line e-beam can have a length that is approximately one-fifth, one-quarter, one-third or one-fourth of the width 912 of the panel 904.

In another example, the length of a line e-beam can be approximately the same as the width of a single solar cell in the module. For example, the length of a line e-beam emitted by a source 902 may be approximately the same as a width 160 of a PV cell 102 (shown in FIG. 16) or a width 580 of a PV cell 522 (shown in FIG. 28). In some embodiments, the width 160 of the PV cell 102 or the width 580 of the PV cell 522 is at least approximately 0.4 to 1 centimeters. Alternatively, the line e-beam can have a length that is greater than the width 160 of a PV cell 102 or the width 544 of a PV cell 522. For example, the line e-beam can have a length of at least approximately 20 to 100 centimeters.

In order to cover a large-area panel 904, the e-beam sources 902 are offset from one another. For example, the e-beam sources 902 can be spatially offset from one another in a single direction. With respect to the page of FIG. 30, the e-beam sources are offset in a left/right direction. In such an embodiment, the total of e-beams produced by the sources can cover a larger area, if not all, of the width 912 of the panel 904.

In one example embodiment, the sources 902 each emit an e-beam that does not overlap with an e-beam emitted by an adjacent source 902. For example, the source 902-1 may emit an e-beam line that does not overlap with the e-beam line emitted by the source 902-2. Similarly, the e-beam line that is emitted by the source 902-2 may not overlap the e-beam emitted by the source 902-3. In order to enable the system 900 to expose the entire width and/or area of the panel 904 to e-beams, the panel 904 and/or sources 902 move relative to one another. In some embodiments, the sources 902 remain stationary while the panel 904 moves relative to the sources 902. In another embodiment, the panel 904 remains stationary while the sources 902 move. In another embodiment, both the panel 904 and the sources 902 move relative to one another.

In some embodiments, one or more of the panel 904 and e-beam sources 902 move relative to each other in at least two directions to expose the panel 904 to e-beams. For example, the panel 904 can be moved in a first direction indicated by the arrow 906 while the e-beams emitted by the sources 902 strike the panel 904. The panel 904 is then moved laterally with respect to the arrow 906, or in a direction that is perpendicular to arrow 906, as indicated by the arrow 908. The panel 904 is then moved in a direction opposite the arrow 906, or in a direction indicated by the arrow 910.

In another embodiment, the sources 902 are moved while the panel 904 remains stationary. This process may be continued until all of or a desired area of the panel 904 has been exposed to e-beams. During movements indicated by arrows 906, 908, 910, the motion of the panel 904 and/or sources 902 may include either a continuous relative motion with a continuously emitted electron beam, or stepped motion in synch with a pulsed electron beam, for example. For example, the sources 902 may emit e-beams towards the panel 904. The sources 902 may continue to emit e-beams towards the panel 904 while the panel 904 moves relative to the sources 902 in the directions indicated by the arrows 906, 908, 910 until substantially all of the panel 904 has been exposed to an e-beam.

Alternatively, the sources 902 may emit e-beams towards the panel 904 while the panel 904 is stationary with respect to the sources 902. The sources 902 may emit the e-beams for a first dwell time. The sources 902 may then stop emitting e-beams while the panel 904 moves relative to the sources 902 in the direction indicated by the arrow 906. The panel 904 then stops after being moved a predetermined distance in the direction indicated by the arrow 906. The sources 902 then emit e-beams towards the panel 904 for a second dwell time. The sources 902 stop emitting e-beams towards the panel 904 and the panel 904 moves in the direction indicated by the arrow 908. The panel 904 then stops after being moved a predetermined distance in the direction indicated by the arrow 908. The sources 902 then emit e-beams towards the panel 904 for a third dwell time. The sources 902 stop emitting e-beams towards the panel 904 and the panel 904 moves in the direction indicated by the arrow 910. The panel 904 then stops after being moved a predetermined distance in the direction indicated by the arrow 910. The sources 902 then emit e-beams towards the panel 904 for a fourth dwell time. One or more of the first through fourth dwell times may be approximately the same. The distance moved by the panel 904 and/or sources 902 may be approximately the same for each movement of the panel 904 and/or sources 902. Alternatively, the distance moved by the panel 904 and/or sources 902 may differ for one or more movements of the panel 904 and/or sources 902. This stepped motion may be continued until substantially all of the panel 904 is exposed to e-beams, for example.

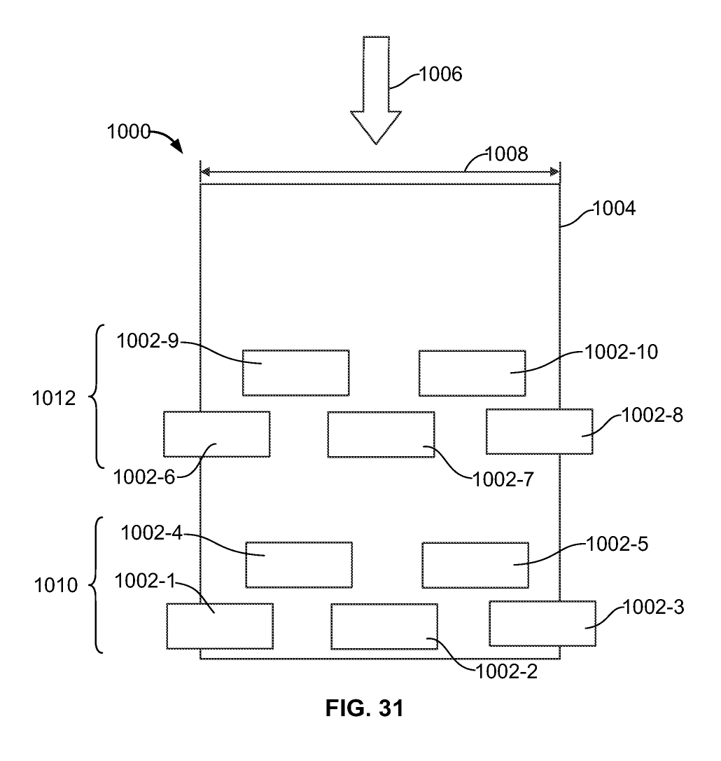

FIG. 31 is a top schematic view of a system 1000 in which a plurality of e-beam sources 1002 scans a large area panel 1004 in accordance with an embodiment. The system 1000 includes a plurality of e-beam sources 1002 spatially offset from one another. In some embodiments, each source 1002 is a Pierce reflector that includes a plurality of reflectors and a filament. In an alternative embodiment, each source includes a point source e-beam that is focused using magnetic fields. The reference number for each of the sources 1002 includes an additional number such as −1, −2, −3, −4 or −5, up through −10. While ten sources 1002 are shown in FIG. 31, a different number of sources 1002 may be used.

Similar to the panels 804 and 904, the panel 1004 may include a portion of the PV device 100 or the PV device 520. For example, the panel 904 may include the substrate 112, the barrier layer 140, the bottom adhesion layer 142, the bottom electrode 114, the passivation layer 144, the buffer layer 146 and one or more of the sub-layers 148, 150, 152 of the semiconductor layer stack 116 of the PV device 100. Alternatively, the panel 904 may include the superstrate 532, the barrier layer 544, the bottom electrode 534, the buffer layer 546 and one or more sub-layers 552, 554, 556 of the semiconductor layer stack 536.

The panel 1004 may be of sufficient size or area that a single e-beam source 1002 cannot emit an e-beam so as to cover the entire panel 1004 or all of a width 1008 of the panel 1004 at once. In order to expose the entire panel 1004, at least two sets 1010, 1012 of e-beam sources 1002 are provided. Each of the e-beam sources 1002 in each set 1010, 1012 are spatially offset from one another in at least two directions in some embodiments. In the illustrated embodiment, the e-beam sources 1002 in each set 1010, 1012 are offset from one another in two perpendicular directions. In such an embodiment, the total e-beams produced by the sources 1002 may cover a larger area, if not all, of the width 1008 of the panel 1004.

With multiple sets 1010, 1012 of sources 1002, a portion or all of the panel 1004 may be exposed to e-beams in less time that is required for the systems 800, 900 to do the same. The addition of multiple sets 1010, 1012 of e-beam sources 1002 may expose more of the panel 1004 than those in the systems 800, 900. The system 1000 may be useful when relatively low scan speeds are used as a greater portion of the panel 1004 by the sources 1002 may be exposed to e-beams than the panels 804, 904 by the sources 802, 902 within a given time period.

The panel 1004 can move relative to the e-beam sources 1002 in the direction indicated by the arrow 1006. In another embodiment, the panel 1004 can move in a direction opposite that, or different from the direction indicated by the arrow 1006. In another embodiment, the e-beam sources 1002 move relative to the panel 1004. The motion of the panel 1004 relative to the sources 1002 may be continuous motion with a continuously emitted electron beam, or stepped motion in synch with a pulsed electron beam, for example. As described above, the sources 1002 can emit e-beams while the panel 1004 moves relative to the sources 1002, or the sources 1002 can emit e-beams while the panel 1004 is stopped between movements relative to the sources 1002. The sources 1002 can emit e-beams for the same or different dwell times each time the panel 1004 stops moving relative to the sources 1002.

The settings for the e-beam sources 802, 902, 1002 used to increase the crystallinity of the sub-layers in the semiconductor layer stacks 116, 536 included in the panels 804, 904, 1004 may be varied based on one or more factors. In some embodiments, these factors include the desired heating temperature, the thickness of the sub-layers sought to be crystallized, and the desired speed at which the sub-layers in the semiconductor layer stacks 116, 536 are heated. For example, by varying the voltage supplied to e-beam sources 802, 902, 1002, the depth of penetration of the emitted e-beams into the sub-layers in the semiconductor layer stacks 116, 536 can vary. As the voltage is increased, the emitted e-beams can penetrate deeper into the target sub-layers. Thus, where relatively thick sub-layers in the semiconductor layer stacks 116, 536 are utilized, a higher voltage can be necessary to achieve the desired level of crystallinity. In another example, by varying the current supplied to the e-beam sources 520, 902, 1002, the power of the e-beams, and therefore the rate at which the target sub-layers are heated and the temperature to which the target sub-layers are heated, varies. As the current is increased, the target sub-layers can heat at a greater rate and/or to a greater temperature.

In some embodiments, systems 800, 900 and 1000 include a conveyor or other mechanical devices for moving panels 804, 904 and 1004 and/or the e-beam sources 802, 902, 1002 relative to one another. In an embodiment, panels 804, 904 and 1004 move relative to the e-beam sources 802, 902, 1002 at a rate of at least approximately 0.25 centimeters per second. In another embodiment, panels 804, 904 and 1004 move relative to the e-beam sources 802 902, 1002 at a rate of at least approximately 1 centimeter per second.

In addition, an aperture can be placed between one or more e-beam sources 802, 902, 1002 and panels 804, 904 or 1004 to reduce or minimize any overlap of e-beams produced by adjacent e-beam sources. In another example, one or more of the e-beam sources 802, 902, 1002 in the systems 800, 900 and 1000 can be housed in a chamber separate from the chamber that includes the panels 804, 904 and 1004. For example, the filaments of an e-beam source 802, 902, 1002 can be housed in a second vacuum chamber that maintains a lower base pressure near the filament (for example, less than 10⁻⁴ to 10⁻⁸ torr). The chamber housing the panels 804, 904 and 1004 and can be maintained at a higher pressure than the second chamber (for example, 10⁰ to 10⁻⁶ ton). The two chambers can be connected by a narrow slit through which e-beams emitted by the filament in the second chamber pass. In some cases, the slit can be covered by a thin piece of material that is penetrable by the emitted e-beam. The time required to pump down the chamber the houses the panels 804, 904 and 1004 may be reduced in this embodiment while increasing the overall stability of the e-beam. In another embodiment, the chambers containing the e-beam sources 802, 902, 1002 and the panel 804, 904, 1004 can be intentionally filled with a partial pressure of argon, hydrogen, or another ionizable gas in the pressure range 10⁻⁶ to 10⁻² ton to stabilize the e-beam against ion focusing effects caused by outgassing of volatile molecules from the panel during e-beam irradiation.

Alternatively, the level(s) of crystallinity in the semiconductor layer stacks 116, 536 or one or more of the sub-layers 148, 150, 152 in the semiconductor layer stack 116 or one or more of the sub-layers 552, 554, 556 in the semiconductor layer stack 536 may be increased by exposing the semiconductor layer stacks 116, 536 or one or more of the sub-layers 148, 150, 152, 552, 554, 556 to a line shaped CW laser beam. For example, the first semiconductor sub-layer 148 may be crystallized by exposing the first semiconductor sub-layer 148 to a line-shaped CW laser beam that is electronically or mechanically pulsed. Alternatively, the first semiconductor sub-layer 148 may be exposed to a CW laser beam that is rapidly scanned across the first semiconductor sub-layer 148. The laser beam may have a wavelength that is approximately the same as the absorption coefficient of the semiconductor material in the first semiconductor sub-layer 148. In some embodiments, the laser beam has a wavelength that is matched to the absorption spectrum of the semiconductor material in the first semiconductor sub-layer 148. In another example, the wavelength of the laser beam may have a depth of penetration into the first semiconductor sub-layer 148 that is within the same order of magnitude of the thickness of the first semiconductor sub-layer 148. For example, the laser beam may have a wavelength of approximately 400 to 800 nanometers when the first semiconductor sub-layer 148 is formed from amorphous silicon. In another example, the laser beam may have a wavelength of approximately 500 to 650 nanometers.

In some embodiments, the semiconductor layer stacks 116, 536 or one or more of the sub-layers 148, 150, 152 in the semiconductor layer stack 116 or one or more of the sub-layers 552, 554, 556 in the semiconductor layer stack 536 is crystallized by the CW laser beam by exposing portions of the semiconductor layer stacks 116, 536 or one or more of the sub-layers 148, 150, 152 in the semiconductor layer stack 116 or one or more of the sub-layers 552, 554, 556 in the semiconductor layer stack 536 to the laser beam one at a time until all of semiconductor layer stack 116, 536 or sub-layer(s) 148, 150, 152, 552, 554, 556 is crystallized. For example, the CW laser beam may be focused into an approximately 100 micrometer wide beam that is rapidly scanned over the portion of the semiconductor layer stack 116, 536 or sub-layer(s) 148, 150, 152, 552, 554, 556 for a predetermined dwell time. In some embodiments, the CW laser beam is scanned over the semiconductor layer stack 116, 536 or sub-layer(s) 148, 150, 152, 552, 554, 556 at a speed of approximately 10 centimeters per second so that the portion of the semiconductor layer stack 116, 536 or sub-layer(s) 148, 150, 152, 552, 554, 556 is exposed to the laser beam for a dwell time of approximately 1 millisecond.

The semiconductor layer stack 116, 536 or sub-layer(s) 148, 150, 152, 552, 554, 556 may be heated by the laser beam to a high enough temperature to induce crystallization of the semiconductor layer stack 116, 536 or sub-layer(s) 148, 150, 152, 552, 554, 556 while remaining below the melting temperature of the semiconductor layer stack 116, 536 or sub-layer(s) 148, 150, 152, 552, 554, 556. The CW laser beam line can be rastered across the semiconductor layer stack 116, 536 or sub-layer(s) 148, 150, 152, 552, 554, 556 so that only a portion of the semiconductor layer stack 116, 536 or sub-layer(s) 148, 150, 152, 552, 554, 556 is heated and crystallized at a time before the laser beam line is advanced along a panel that includes the semiconductor layer stack 116, 536 or sub-layer(s) 148, 150, 152, 552, 554, 556.

In another embodiment, a level of crystallinity may be increased in one or more of the semiconductor layer stack 116, 536 or sub-layer(s) 148, 150, 152, 552, 554, 556 by heating the semiconductor layer stack 116, 536 or sub-layer(s) 148, 150, 152, 552, 554, 556 in a flash anneal system. Such a system may include a chamber into which the semiconductor layer stack 116, 536 or sub-layer(s) 148, 150, 152, 552, 554, 556 is placed and then rapidly heated by a flash lamp. The flash lamp may include, for example, a high ramp rate arc lamp. An optical diffuser may be placed between the lamp and the semiconductor layer stack 116, 536 or sub-layer(s) 148, 150, 152, 552, 554, 556 to diffuse and more evenly distribute the heat emanating from the lamp over the entirety of the semiconductor layer stack 116, 536 or sub-layer(s) 148, 150, 152, 552, 554, 556. The flash lamp may rapidly increase the temperature in the chamber. For example, the flash lamp may increase the temperature in the chamber at a rate of approximately 400 degrees Celsius per second or more. The flash lamp may continue to heat the chamber and the semiconductor layer stack 116, 536 or sub-layer(s) 148, 150, 152, 552, 554, 556 for a predetermined dwell time. In some embodiments, the dwell time is short enough to avoid melting the semiconductor layer stack 116, 536 or sub-layer(s) 148, 150, 152, 552, 554, 556. For example, the dwell time may be 10 seconds or less.

In accordance with one or more embodiments of the subject matter described herein, a greater uniformity in the level of crystallinity of one or more of the semiconductor sub-layers in the semiconductor layer stacks 116, 536 may be obtained by using several identical or similar electron beams to expose these sub-layers rather than a single electron beam that spans the entire substrate. For example, existing line- or point-source electron beams may encounter difficulties in maintaining the uniformity of the beams indefinitely in a direction perpendicular to the scan direction. Therefore, in order to obtain highly uniform large-area semiconductor films and achieve high throughput, a plurality of e-beams and e-beam sources may be used. In addition, for a given scan speed, the time needed to expose an entire panel 804, 904 or 1004 may be reduced by a factor of n when n electron beams are used.

Additionally, the grain size and level of crystallinity in the semiconductor sub-layers in the semiconductor layer stacks 116, 536 may be able to be better controlled than the grain size and level of crystallinity in modules that include directly-deposited microcrystalline semiconductor layers. By depositing the semiconductor sub-layers in the semiconductor layer stacks 116, 536 in an amorphous state and then crystallizing one or more of the semiconductor sub-layers in the semiconductor layer stacks 116, 536 without melting the semiconductor sub-layers in the semiconductor layer stacks 116, 536, a greater level of crystallinity in the semiconductor material in the semiconductor sub-layers in the semiconductor layer stacks 116, 536 may be obtained. Similarly, by depositing the semiconductor sub-layers in the semiconductor layer stacks 116, 536 in an amorphous state and then crystallizing one or more of the semiconductor sub-layers in the semiconductor layer stacks 116, 536 without melting the semiconductor sub-layers in the semiconductor layer stacks 116, 536, larger grains of semiconductor material in the semiconductor sub-layers in the semiconductor layer stacks 116, 536 may be obtained. As the crystalline grain size is increased in the semiconductor sub-layers in the semiconductor layer stacks 116, 536, the grain boundary surface area per unit volume may decrease. As the grain boundary surface area per volume is decreased, the voltage-generating potential of the PV cells 102, 522 and of the PV devices 100, 520 (shown in FIGS. 1 and 19) may increase. Moreover, the deposition of amorphous semiconductor sub-layers in the semiconductor layer stacks 116, 536 followed by crystallization of the semiconductor sub-layers in the semiconductor layer stacks 116, 536 without melting the semiconductor sub-layers in the semiconductor layer stacks 116, 536 also may permit crystallization of the sub-layers without introducing microcracks in the sub-layers. This may improve the environmental stability in the films.

Moreover, one or more embodiments may provide the ability to more easily scale application of one or more embodiments described herein to large area substrates. For example, the levels of crystallinity of the semiconductor sub-layers in the semiconductor layer stacks 116, 536 in generation 8.5 panels (or panels that are approximately 2.2 meters by 2.6 meters, or 5.72 square meters) may be more easily increased uniformly across the panel using one or more embodiments of the subject matter described herein. Existing methods and systems that rely on directly-deposited microcrystalline silicon may encounter difficulties in applying the methods and systems to a generation 8.5 panel manufacturing environment. These difficulties may arise due to the deposition time required in order to get high-quality microcrystalline silicon material, the very relatively large tool costs and the difficulty in making the deposition uniform over such a large area (due to non-uniform gas flow or a non-uniform plasma power distribution across the panel or substrate, for example).

In some embodiments, the speed at which the semiconductor sub-layers in the semiconductor layer stacks 116, 536 is exposed to e-beams may be increased over existing methods and systems. For example, the panels 804, 904 and 1004 can move relative to the e-beam sources 802, 902, 1002 at a speed of at least 0.25 centimeters per second. At this and increasing rates of speed, the panels 804, 904 and 1004 having a surface area of approximately 1.0 square meter or more may move relative to the e-beam sources 802, 902, 1002 at a speed sufficient to increase the level of crystallinity in the semiconductor sub-layers in the semiconductor layer stacks 116, 536 in a time of 10 minutes or less in some embodiments. In another embodiment, the level of crystallinity in the semiconductor sub-layers in the semiconductor layer stacks 116, 536 of a panel 804, 904, 1004 having a surface area of approximately 1.0 square meter or more can be increased in 3 minutes or less.

In some embodiments, the level of crystallinity is increased when the average crystalline grain size in one or more sub-layers of the semiconductor layer stacks 116, 536 of a panel 804, 904, 1004 having a surface area of approximately 1.0 square meter or more may be increased to approximately 100 nanometers or more in 10 minutes or less. In another example, the level of crystallinity is increased when the average crystalline grain size is increased to approximately 100 nanometers or more in 3 minutes or less. In another example, the level of crystallinity is increased when the crystalline fraction of one or more of the sub-layers in the semiconductor layer stacks 116, 536 of a panel 804, 904, 1004 having a surface area of approximately 1.0 square meter or more does not vary by more than approximately 15% through the thickness of the sub-layer(s), as described above. In another example, the level of crystallinity is increased when the crystalline fraction does not vary by more than approximately 10% through the thickness of the sub-layer(s). In another example, the level of crystallinity is increased when the crystalline fraction does not vary by more than approximately 5% through the thickness of the sub-layer(s). In another example, the level of crystallinity is increased when the crystalline fraction in the sub-layer(s) of the semiconductor layer stacks 116, 536 of a panel 804, 904, 1004 having a surface area of approximately 1.0 square meter or more is increased to at least approximately 98%. In another example, the level of crystallinity is increased when the crystalline fraction in the sub-layer(s) of the semiconductor layer stacks 116, 536 is increased to at least approximately 95%. In another example, the level of crystallinity is increased when the crystalline fraction in the sub-layer(s) of the semiconductor layer stacks 116, 536 is increased to at least approximately 85%.

In another embodiment, the level of crystallinity is increased when the average crystalline grain size in one or more sub-layers of the semiconductor layer stacks 116, 536 of a panel 804, 904, 1004 having a surface area of approximately 5.72 square meters or more may be increased to approximately 100 nanometers or more in 10 minutes or less. In another example, the level of crystallinity is increased when the average crystalline grain size is increased to approximately 100 nanometers or more in 3 minutes or less. In another example, the level of crystallinity is increased when the crystalline fraction of one or more of the sub-layers in the semiconductor layer stacks 116, 536 of a panel 804, 904, 1004 having a surface area of approximately 5.72 square meters or more does not vary by more than approximately 15% through the thickness of the sub-layer(s), as described above. In another example, the level of crystallinity is increased when the crystalline fraction does not vary by more than approximately 10% through the thickness of the sub-layer(s). In another example, the level of crystallinity is increased when the crystalline fraction does not vary by more than approximately 5% through the thickness of the sub-layer(s). In another example, the level of crystallinity is increased when the crystalline fraction in the sub-layer(s) of the semiconductor layer stacks 116, 536 of a panel 804, 904, 1004 having a surface area of approximately 5.72 square meters or more is increased to at least approximately 98%. In another example, the level of crystallinity is increased when the crystalline fraction in the sub-layer(s) of the semiconductor layer stacks 116, 536 is increased to at least approximately 95%. In another example, the level of crystallinity is increased when the crystalline fraction in the sub-layer(s) of the semiconductor layer stacks 116, 536 is increased to at least approximately 85%.

In one embodiment, PV cells 102, 522 and/or PV devices 100, 520 may have improved conversion efficiencies over known PV cells and PV devices. For example, one or more of the PV cells 102, 522 and the PV devices 100, 520 may be fabricated using a generation 8.5 sized or larger substrate 112 or superstrate 532. In such an example, the substrate 112 or superstrate 532 of the PV cell 102, 522 or PV device 100, 520 may have a surface area of approximately 5.72 square meters or more. In one embodiment, the substrate 112 or superstrate 532 has surface area dimensions of 2.2 meters by 2.6 meters. The PV cells 102, 522 and/or PV devices 100, 520 may have a conversion efficiency of approximately 8% or more in one embodiment. In another embodiment, the conversion efficiency is approximately 10% or more.

In another embodiment, the conversion efficiency is approximately 12% or more. For example, the PV cells 102, 522 and PV devices 100, 520 may convert 10% or more of the power of incident light received by the PV cells 102, 522 and PV devices 100, 520 into electric power.

The efficiencies of the PV cells 102, 522 and PV devices 100, 520 may be measured using a variety of methods and systems. For example, the conversion efficiency of the PV cells 102, 522 and PV devices 100, 520 may be measured by exposing the PV cell 102 or 522 or PV device 100 or 520 to sunlight. The power of the sunlight incident on the PV cell 102 or 522 or PV device 100 or 520 may be measured using a pyrometer. Alternatively, a solar simulator device may be used to expose the PV cell 102 or 522, or PV device 100 or 520 to a known spectrum of light. For example, a solar simulator may expose the PV cell 102 to the simulated Air Mass (“AM”) 1.5 Global spectrum. A variable resistor may be electrically connected to the two electrodes of the PV cell 102, 522 or PV device 100, 520. For example a variable resistor may be connected to the top and bottom electrodes 118, 114 in the PV cell 102. The resistance of the variable resistor may be varied while the output power of the PV cell 102 or 522 or the PV device 100, 520 is measured. A maximum output power may be measured at a particular resistance. This maximum output power may then be divided by the power of the incident light on the PV cell 102 or 522, or the PV device 100, 520. For example, if the input power of the incident light is 1000 watts per square meter and the measured output power of the PV cell 102 is 80 watts per square meter, then the efficiency of the PV cell 102 is 8.0%.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the invention without departing from its scope. Dimensions, types of materials, orientations of the various components, and the number and positions of the various components described herein are intended to define parameters of certain embodiments, and are by no means limiting and merely are example embodiments. For example, the layers and components of the PV devices and cells described herein are described as being deposited or provided on or above another layer or component. In some embodiments, depositing one layer or component on or above another layer or component may include depositing the layer or component directly on top of the other layer or component. In other embodiments, one or more intervening layers may be provided between the two layers. Many other embodiments and modifications within the spirit and scope of the claims will be apparent to those of skill in the art upon reviewing the above description. The scope of the invention should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects.

1. A method for manufacturing a photovoltaic device, the method comprising:
providing a supporting layer proximate to a bottom surface of the device;
depositing a conductive and light transmissive layer above the supporting layer;
depositing a semiconductor layer stack in an amorphous state above the conductive and light transmissive layer, the semiconductor layer stack comprising first and second sub-layers; and
increasing a level of crystallinity in the second sub-layer, the second sub-layer having a crystalline fraction of at least approximately 85% after increasing the level of crystallinity.

2. The method of claim 1, wherein the semiconductor layer stack comprises a third sub-layer, the second sub-layer disposed between the first and third sub-layers, the first and third sub-layers each doped with different types of dopants.

3. The method of claim 2, wherein a first dopant junction exists between the first and second sub-layers and a second dopant junction exists between the second and third sub-layers, and a junction diffusion width of each of the first and second dopant junctions is 100 nanometers or less after increasing the level of crystallinity in the second sub-layer.

4. The method of claim 2, wherein a dopant junction exists between the first and second sub-layers, the dopant junction having a junction diffusion width that does not increase by more than approximately 50 nanometers during increasing the crystallinity of the second sub-layer.

5. The method of claim 1, wherein increasing the level of crystallinity occurs after depositing the conductive and light transmissive layer.

6. The method of claim 1, wherein the supporting layer has a softening point below 750 degrees Celsius.

7. The method of claim 1, wherein the semiconductor layer stack remains in a solid state during increasing the level of crystallinity in the second sub-layer.

8. The method of claim 1, wherein increasing the level of crystallinity comprises exposing the second sub-layer to one or more electron beams or one or more continuous-wave laser beams.

9. A method for manufacturing a photovoltaic device, the method comprising:
providing a substrate;
depositing a reflective electrode above the substrate;
depositing an optical spacer layer above the reflective electrode, the optical spacer layer comprising a conductive and light transmissive material;
depositing a semiconductor layer stack above the optical spacer layer, the semiconductor layer stack deposited in an amorphous state, the semiconductor layer stack comprising first and second sub-layers;
increasing a level of crystallinity in the second sub-layer, the second sub-layer having a crystalline fraction of at least 85% after increasing the level of crystallinity; and
depositing a light transmissive electrode above the semiconductor layer stack.

10. The method of claim 9, wherein the semiconductor layer stack remains in a solid state during increasing the level of crystallinity in the second sub-layer.

11. The method of claim 9, wherein increasing the level of crystallinity comprises exposing the second sub-layer to one or more electron beams.

12. The method of claim 9, wherein increasing the level of crystallinity comprises heating the second sub-layer at a rate of at least approximately 400 degrees Celsius per second.

13. The method of claim 9, wherein increasing the level of crystallinity comprises exposing the second sub-layer to one or more continuous-wave laser beams.

14. A method for manufacturing a photovoltaic device, the method comprising:
providing a light transmissive superstrate;
depositing a light transmissive electrode above the superstrate;
depositing a semiconductor layer stack above the light transmissive electrode, the semiconductor layer stack deposited in an amorphous state, the semiconductor layer stack comprising first and second sub-layers;
increasing a level of crystallinity in the second sub-layer, the second sub-layer having a crystalline fraction of at least 85% after increasing the level of crystallinity;
depositing an optical spacer layer above the semiconductor layer stack, the optical spacer layer comprising a conductive and light transmissive material; and
depositing a reflective electrode above the optical spacer layer.

15. The method of claim 14, wherein an Ohmic contact exists between the semiconductor layer stack and the optical spacer layer.

16. The method of claim 14, wherein increasing the level of crystallinity occurs after depositing the light transmissive electrode.

17. The method of claim 14, wherein the superstrate has a softening point below 750 degrees Celsius.

18. The method of claim 14, wherein increasing the level of crystallinity comprises exposing the second sub-layer to one or more electron beams.

19. The method of claim 14, wherein increasing the level of crystallinity comprises heating the second sub-layer at a rate of at least approximately 400 degrees Celsius per second.

20. The method of claim 14, wherein increasing the level of crystallinity comprises exposing the second sub-layer to one or more continuous-wave laser beams.
